(19) United States
(12) Patent Application Publication
(10) Pub. No.: US 2007/0020918 A1
(43) Pub. Date: Jan. 25, 2007

(54) Substrate processing method and substrate processing apparatus

(75) Inventors: Kazuto Hirokawa, Tokyo (JP); Manabu Tsujimura, Tokyo (JP)

Correspondence Address: WENDEROTH, LIND & PONACK, L.L.P., 2033 K STREET N. W., SUITE 800, WASHINGTON, DC, 20006-1021, US

(73) Assignee: EBARA CORPORATION, TOKYO (JP)

(21) Appl. No.: 10/553,903

(22) PCT Filed: Apr. 20, 2004
(86) PCT No.: PCT/JP04/05637

§ 371 Date: Oct. 21, 2005

(30) Foreign Application Priority Data
Apr. 22, 2003 (JP) 2003-117667

(51) Int. Cl. H01L 21/4763; H01L 21/311

(52) U.S. Cl. 438/626; 438/645; 438/697

(57) ABSTRACT

The present invention provides a substrate processing method that can perform improved flattening and processing upon the formation of interconnects. The a substrate processing method includes a step of eliminating a level difference in a surface of a interconnect material to flatten a surface, a step of removing the interconnect material until the interconnect material present in the non-interconnect region of the substrate becomes a thin film or remains partly on a barrier material, a step of removing the interconnect material in the form of the thin film or remaining partly on the barrier material, a step of simultaneously removing the unnecessary interconnect material and the barrier material until the barrier material present in the non-interconnect region becomes a thin film or remains partly, and a step of removing the unnecessary interconnect material and the barrier material in the form of the thin film.

### TECHNICAL FIELD

The present invention relates to a substrate processing method and a substrate processing apparatus, and more particularly to a substrate processing method and a substrate processing apparatus useful for flattening a surface of an electrical conductive material (interconnect material), such as copper, embedded in interconnect recesses, such as interconnect trenches and connecting holes (via holes) provided in a surface of a substrate, in particular a semiconductor wafer, thereby forming embedded interconnects.

### BACKGROUND ART

From the viewpoints of processibility, productivity, etc., aluminum or an aluminum alloy has conventionally been used as an interconnect material for forming interconnect circuits on a semiconductor substrate. On the other hand, with the recent progress toward finer and higher speed semiconductor devices, there is an eminent movement toward using copper as an interconnect material. This is because the electric conductivity of copper is 1.72 μΩcm, which is about 40% lower than the electric conductivity of aluminum. Therefore, the use of copper is advantageous in terms of signal delay phenomenon. In addition, copper has a considerably higher resistance to electromigration than aluminum. Electromigration refers to migration of atoms upon application of electric current, which could cause disconnection of interconnects.

When a chemical etching method, a conventional processing method, is employed in a process of forming copper interconnects, the vapor pressure of a CuCl compound produced upon processing is very low. In order to enhance the processing rate, it is necessary to raise the temperature of the system to 250-300° C. In view of the productivity, therefore, it is difficult to chemically deposit copper, or remove copper by chemical etching. Thus, a sputtering method, which is a film-forming method widely used in forming aluminum interconnects, and conventional etching techniques for aluminum interconnects cannot be suitably employed for copper interconnects. Further, conventional processing techniques could cause metal contamination that may bring about a fetal short-circuit problem.

Further, a copper material easily diffuses into an adjacent insulating material. It is therefore necessary to provide a diffusion preventive layer (generally called barrier metal (BM) in the case of a copper-interconnects formation process) for preventing the diffusion of copper.

Accordingly, for the formation of copper interconnects, a so-called dual damascene process has been employed which comprises film formation (deposition) of a barrier metal (barrier material) on surfaces of trenches and via holes formed in a surface of an insulating material, embedding of copper as an interconnect material in the trenches and via holes, followed by removal of an extra metal by a chemical mechanical polishing method (CMP method).

From the viewpoint of speeding up, it is desirable to use as the insulating material, adjacent to the interconnect material, a low-dielectric constant material which hardly leaks electricity and hardly forms an unnecessary circuit due to the device structure. In particular, a low-k film or an ultra low-k (ULK) film is currently attracting attention. In this regard, a SiO₂ film has been generally employed as an insulating material for a conventional aluminum interconnect device. For copper interconnects, however, it is desirable to use an insulating film having a lower dielectric constant than that of SiO₂, i.e. 4.1. A low-k film generally has a dielectric constant of not more than 3.0.

Inorganic materials and organic materials have been developed as low-dielectric constant materials. Among them, a SiOF-based FSG, a SiOC-based black diamond, BD, Aulora, etc, as inorganic materials, and SiLK, etc. as organic materials, have been put into practical use. Further, for the purpose of obtaining a lower dielectric constant material, a study has begun to make such materials porous.

An example of the formation of copper interconnects by a dual damascene process will now be described with reference to FIG. 1A through 1F. First, as shown in FIG. 1A, an insulating film (insulating material) 14, such as an oxide film of SiO₂ or a low-k material (ULK material) film of e.g. SiF, SiOH or porous silica, is deposited on a conductive layer 12 superimposed on the underlying completed interconnects 10. Next, as shown in FIG. 1B, interconnect recesses (interconnect pattern) 16, such as trenches and via holes, are formed in the insulating film 14 by an etching method, such as lithography and RIE. Thereafter, as shown in FIG. 1C, a resist 18 is removed, followed by cleaning.

Next, as shown in FIG. 1D, a barrier metal (barrier material) 20, as a diffusion preventive film for preventing diffusion of copper into the insulating film 14, is formed e.g. by sputtering on the surfaces of the interconnect recesses 16 such as trenches and via holes. Thereafter, as shown in FIG. 1E, copper plating is carried out by electroplating or electroless plating (a copper plating method) until the plated film reaches such a thickness that all the interconnect recesses 16 are embedded in the plated film, thereby filling the interconnect recesses 16 with copper. 22 as an interconnect material and depositing copper 22 on the insulating film 14. Thereafter, the copper 22 and the barrier metal 20 on the insulating film 14 are removed by chemical mechanical polishing (CMP) so as to make the surfaces of copper 22 filled in the interconnect recesses 16 almost flush with the surface of the insulating film 14. Interconnects (copper interconnects) 24 composed of copper 22 are thus formed, as shown in FIG. 1F.

With the movement toward higher performance (higher integration and speeding up) of semiconductor devices, there is a demand for a finer device structure. It is therefore requested to design and manufacture a semiconductor device with a smaller technology node. This requires that the processed surface and its vicinity after the formation of copper interconnects be free from defects. In addition, a highly flat processed surface is required for the formation of an upper interconnect layer. In view of this, it has been proposed to carry out two types of CMP steps for the formation of copper interconnects, since a single CMP step can hardly effect the intended processing. In particular, a CMP process may be carried out in the following two divided steps: a first polishing step of removing unnecessary copper; and a second polishing (finish polishing) step of mainly removing unnecessary barrier metal. This makes it possible to carry out polishing by using specific chemicals suited for the respective materials to be polished.

However, with the use of a low-k material, having a poor mechanical strength, as an insulating material or with the next-generation technology node that requires more than the current level, it is difficult to meet the above-described requirements for the processed surface and its vicinity after the formation of copper interconnects. When carrying out the above-described two types of CMP steps, i.e. the first polishing step and the second polishing (finish polishing) step, measures are taken for maintaining the flat surface obtained in the first polishing, such as a change in the relative speed or the processing pressure between a surface to be processed and processing tools, a change of a slurry, cleaning of a substrate, cleaning or change of tools, etc. Because of the sole use of CMP as a processing method, however, such a two-step CMP process, though having a merit of fewer defects for a CMP processing, has demerits in terms of flattening (elimination of a level difference) and processing rate.

### DISCLOSURE OF INVENTION

The present invention has been made in view of the above situation in the background art. It is therefore an object of the present invention to provide a substrate processing method and a substrate processing apparatus which, by utilizing the features of the structure of a semiconductor device as well as the features of chemical mechanical polishing (CMP) and other specific processing methods, can perform improved flattening and processing upon the formation of interconnects and can provide a defect-free embedded interconnect structure having a high flatness.

In order to achieve the above object, the present invention provides a substrate processing method for removing unnecessary interconnect material and barrier material on a substrate and flattening a surface of the substrate, wherein the interconnect material is embedded in interconnect recesses, the interconnect recesses being formed on a surface of an insulating material and having a film of the barrier material formed on the surface of an insulating material, the method comprising: eliminating a level difference in the surface of the interconnect material to flatten the surface; removing the interconnect material until the interconnect material present in the non-interconnect region of the substrate becomes a thin film or remains partly on the barrier material; removing the interconnect material in the form of the thin film or remaining partly on the barrier material, thereby exposing the barrier material or further processing the barrier material; simultaneously removing the unnecessary interconnect material and the barrier material until the barrier material present in the non-interconnect region becomes a thin film or remains partly; and removing the unnecessary interconnect material and the barrier material present in the non-interconnect region, thereby exposing the insulating material in the non-interconnect region or further processing the insulating material.

The barrier material, e.g. a barrier metal, is the material of a thin layer which is used for the purpose of preventing diffusion of the interconnect material, composed of an electrically conductive material, into the insulating portion and which is deposited on the surface of interconnect recesses, such as trenches and via holes. The barrier material is composed of a single or plurality of electrically conductive materials or of a single or plurality of electrically conductive materials and an insulating material. For example, when copper is used as the interconnect material, a Ta-based materials is generally used as the barrier material from the viewpoint of prevention of electrical, dynamic or thermal diffusion of copper. In the future, not only from the viewpoint of prevention of electrical, dynamic or thermal diffusion of copper, but also from the viewpoint of lower resistance, prevention of leakage of electric current between adjacent interconnects (interfacial leakage) and shape preservation upon the formation of interconnects, adhesion of a barrier material to a different material will be of importance. In view of this, applicability of W-based materials, Ru-based materials, and insulating materials such as ceramics, for example zirconia, is now being studied.

The interconnect material and the barrier material generally have different electrical and mechanical properties. Accordingly, from the viewpoint of flattening, the demand for which is becoming severer, it is desired to employ a processing method and processing conditions suited for the respective materials.

In particular, when processing the interconnect material at the topmost layer having a level difference, it is desirable, in the light of eliminating the level difference to create a flat surface and of the processing rate, to carry out processing by using a processing method and processing conditions suited for the interconnect material. However, as the processing of the interconnect material proceeds, the barrier material becomes exposed. If the processing is further continued with the processing method and processing conditions suited for the interconnect material of the surface layer, the processing will be an abnormal processing or non-effective processing for the barrier material, whereby the flatness of the previously processed surface will be lost and the final surface configuration upon completion of the processing will be an undesirable one with irregularities or surface roughness. Such drawbacks can be obviated by carrying out the processing in the following manner: In processing the interconnect material to eliminate a level difference in the surface, the processing is carried out at a high processing rate under such processing conditions as to effect uniform processing, and the processing is stopped before the barrier material becomes exposed. Thereafter, processing is carried out under different processing conditions that can maintain the flattened surface even after the barrier material is exposed. By employing such divided process steps, it becomes possible to maintain the high-quality flat surface after the level difference elimination step.

Copper material, which has been used as an interconnect material in these days, is characterized by its fast corrosion speed, and therefore, the surface of copper interconnects right after processing is unstable. Accordingly, for the purpose of preventing corrosion of copper interconnects, it is practiced to protect the surface of copper interconnects after flattening processing with a protective film (cap film). Such a protective film is generally formed by depositing SiC, SiN, SiCN, or the like onto the entire processed surface by plasma CVD or the like to a film thickness of several tens nm. It is particularly effective to form a protective film immediately after flattening processing, for example, after cleaning that follows the polishing, without returning the substrate to a cassette. Thus, it is an effective measure to provide a CMP apparatus, other flattening processing apparatus (es) as will be described later, and a cap film-forming apparatus in one substrate processing apparatus. It is also possible to return the substrate to a cassette, but take the substrate out of the cassette shortly thereafter and carry out the formation of protective film.

Further, in order to prevent a change in quality of the copper surface or contamination of the copper surface with e.g. particles, it is also effective to carry out the process steps according to the present invention successively with varying processing conditions and without drying copper between the respective steps.

When various processing methods are employed, it is desirable that processing units for carrying out the various processing methods be installed in the same apparatus. It is preferred to transfer a substrate from one process step to the next process step while holding the substrate with a holding member used in the former step. It is also preferred to make an exchange of processing tools in place. Further, for preventing copper from being dried between the process steps according to the present invention or during transfer of a substrate between the processing units, it is effective to enhance the water retention of the copper surface by using, for example, a chemical liquid containing a polymer material, in particular a hydrophilic polymer material. The exchange of processing tools may be exemplified by an exchange on the same processing table (polishing table) of a fixed abrasive for an electrolytic processing tool provided with an ion exchange membrane. The chemical liquid containing a polymer may be used as a cleaning liquid in cleaning of a substrate carried out between the process steps, or added upon water polishing carried out as a finish of CMP processing by supplying water onto a processing table to remove foreign matter at a low pressure. It is also effective to send the substrate after such processings to the next step while keeping the substrate chucked to a top ring (common use of top ring).

When the same tool is commonly used, from the viewpoints of preventing cross-contamination and preventing it from impeding the process, it is effective to carry out, according to necessity, cleaning of a substrate and the tool for replacement of chemical liquids between the process steps. Also after the cleaning, it is desirable to keep the substrate in a wet condition without letting it dry. In particular, when carrying out various steps of CMP, it is very effective as a means for replacement on a substrate or a polishing table with pure water to stop supplying a chemical liquid or a slurry to the polishing table and supply only pure water to the polishing table for pure water polishing. Carrying out such pure water polishing between the process steps according to the present invention contributes much to increasing the throughput.

The above-described substrate processing method according to the present invention is characterized by its inclusion of the process steps, while the order of the process steps is not particularly limited. For example, when the initial level difference in the surface of the interconnect material formed on a substrate as a processing object is small and the thickness of the interconnect material is large, it is also possible to first remove a certain thickness of the interconnect material at a high rate and then simultaneously carry out the elimination of a level difference of the interconnect material and the removal of the interconnect material into a thin film.

The substrate processing method may further include a step of simultaneously removing the unnecessary interconnect material, the barrier material and the insulating material.

The present invention also provides another substrate processing method for removing unnecessary interconnect material and barrier material on a substrate and flattening a surface of the substrate, wherein the interconnect material is embedded in interconnect recesses, the interconnect recesses being formed on a surface of an insulating material and having a film of the barrier material formed on the surface of an insulating material, the method comprising: a first step of eliminating a level difference in the surface of the interconnect material to flatten the surface; a second step of removing the interconnect material until the interconnect material present in the non-interconnect region of the substrate becomes a thin film or remains partly on the barrier material; a third step of removing the interconnect material in the form of the thin film or remaining partly on the barrier material, thereby exposing the barrier material or further processing the barrier material; a fourth step of simultaneously removing the unnecessary interconnect material and the barrier material until the barrier material present in the non-interconnect region becomes a thin film or remains partly; and a fifth step of removing the unnecessary interconnect material and the barrier material present in the non-interconnect region, thereby exposing the insulating material in the non-interconnect region or further processing the insulating material.

The first step (step of eliminating a level difference) is preferably carried out by transferring the processing surface or moving surface of a tool to a substrate, preferably using a tool having a high Young's modules or a chemical liquid having a strong chemical action. Such a processing is likely to cause physical or chemical damage to the processing surface of a substrate. Thus, though elimination of level difference is possible, it is difficult to obtain a high-quality processed surface without damage. It is therefore desirable that the level difference elimination step be carried out in an early stage, especially at the initial stage, i.e. as the first step, of the combination of the process steps according to the present invention. This broadens the range of choices of processing methods for the later process steps, enabling a choice of processing method on account not only of the performance of processing, but also of the cost and throughput.

The second step (step of leaving part of interconnect material (copper)) is directed to processing of the interconnect material as a sole processing object. Accordingly, a processing method that can effect uniform and high-speed processing may be selected without the necessity of considering the barrier material. In the third step, on the other hand, the barrier material becomes exposed during processing. Accordingly, it is necessary to carry out the processing in consideration of both of the interconnect material and the barrier material. In order to process the two different materials (interconnect material and barrier material) while maintaining the flatness obtained in the first step, it is necessary to make electrical (or magnetic or electrostatic), chemical or mechanical adjustments and select a process method and processing conditions which can make the processing rates of the two materials almost equal.

The fourth step (step of simultaneously removing interconnect material and barrier material) effects simultaneous processing of two materials, i.e. the interconnect material and the barrier material, and the fifth steps effects simultaneous processing of three materials, i.e. the insulating material in addition to the two materials. Accordingly, as with the second and third steps, it is necessary to carefully select a processing method and processing condition from the viewpoint of maintenance of flatness.

The substrate processing method may further include a sixth step of simultaneously removing the unnecessary interconnect material, the barrier material and the insulating material.

The step of eliminating a level difference in the surface of the interconnect material to flatten the surface (first step) is illustrated in FIGS. 6A and 6B. It is desirable that this step be carried out by at least one of the following processing methods: \textcircled{1} cutting or grinding, \textcircled{2} CMP, \textcircled{3} composite electrolytic processing, \textcircled{4} a common electrolytic processing, \textcircled{5} abrasive processing utilizing an electrostatic or magnetic force, and \textcircled{6} electrolytic processing utilizing a catalyst. For end point detection (EPD) of this step, an eddy current method or an optical method, which can measure the film thickness of an interconnect material (electrical conductive material), may be employed.

The \textcircled{1} cutting or grinding is a processing method in which the processing surface or moving surface of a tool is transferred to a substrate. The \textcircled{2} CMP includes, besides a common CMP with a combination of a polishing pad and a slurry containing abrasive grains, fixed-abrasive CMP and CMP with an abrasive-free chemical liquid. The fixed-abrasive CMP is a processing method which effects removal processing by supplying a polishing liquid, such as a slurry or a chemical liquid, onto a polishing pad of e.g. a resin containing resin particles or abrasive grains while pressing a substrate against the polishing pad. The CMP with an abrasive-free chemical liquid is a processing method which effects removal processing by oxidizing and complexing a processing object with a chemical liquid, and then bringing the complex into contact with a polishing pad (application of mechanical force) to remove the complex. As with the fixed-abrasive CMP, the CMP with an abrasive-free chemical liquid uses a hard pad and removes a contact point with a flat surface without a big elastic deformation. By thus limiting the portion that exerts mechanical action to a plane, it is possible to selectively process and remove only raised portion of a processing object. When a low-dielectric constant material is used as the insulating material, processing under low pressure conditions is required. Accordingly, it is desirable to carry out the processing at a pressure of not more than 4 psi, preferably not more than 2 psi. Processing of a substrate as carried out under low pressure conditions can reduce the influence of elastic deformation of a polishing pad, and allows the polishing pad not to follow irregularities on the substrate and to preferentially process only raised portions, thus facilitating elimination of a level difference in the surface of the substrate.

The \textcircled{3} composite electrolytic processing is a processing method which effects removal processing by oxidizing and chelating (complexing) a metal surface so as to make the metal surface fragile, and then bringing the metal surface into mechanical contact with a contact member to scrub-remove the fragile metal surface. For the chelating, a chelating agent is added to an electrolytic solution. The electrolytic solution may be exemplified by an electrolytic solution containing an electrolyte, such as copper sulfate or ammonium sulfate. It is possible to add abrasive grains or a slurry to the electrolytic solution to increase the mechanical polishing action.

A polishing pad, a scrubbing member, or the like is generally used as the contact member. The contact member preferably has liquid permeability either in the material itself or by provision of a large number of pores. Further, in order to keep good contact with a substrate and not to damage the substrate, the contact member also preferably has elasticity. A contact member having electrical conductivity or capable of exchanging ions is more preferred. Specific examples of the contact member include porous polymers, such as foamed polyurethane; fibrous materials, such as nonwoven fabric; various polishing pads; and scrub cleaning members. It is also possible to a use a polishing pad containing abrasive grains without supplying abrasive grains or a slurry from the outside.

The \textcircled{4} common electrolytic processing is a processing method which effects removal processing by supplying an electrolytic solution between a substrate and a processing electrode while applying a voltage therebetween, thereby dissolving and removing a metal from the surface of the substrate. By adding an additive, such as a surface adjustment agent, to the electrolytic solution, it becomes possible to selectively remove only raised portions of the substrate. The common electrolytic processing may also be carried out in contact with or without contact with a contact member. The same contact member as used in the above-described composite electrolytic processing can be used. Also in this case, as with the above-described case, it is possible to supply abrasive grains or a slurry between the substrate and the processing electrode.

The \textcircled{5} abrasive processing utilizing a magnetic force is a processing method which utilizes the following principle: When a slurry containing magnetic abrasive grains is interposed between a tool and a substrate which are disposed between magnetic poles, the magnetic abrasive grains are lined along the magnetic field lines in the magnetic field created between the magnetic poles, and the abrasive grains come into contact with the substrate. By allowing the substrate and the tool to make a relative movement, a frictional force is generated between the abrasive grains and the substrate, whereby processing of the substrate proceeds. The abrasive processing utilizing an electrostatic force may be carried in a similar manner but replacing magnetism with static electricity, that is, applying an electric field between electrodes and allowing charged abrasive particles or insulating particles, such as resin particles, to act on a substrate. These processing methods can effect processing of a substrate by means of a mechanical action irrespective of whether an electrochemical change by a chemical liquid, electromagnetic force, heat, etc. is produced in the substrate, and are therefore usable in most of the process steps. An electric or electrostatic force is in inverse proportion of the square of the distance between a tool and a substrate. This is advantageous in eliminating a large level difference in the surface of a substrate, and enables uniform processing after the elimination of a level difference. Further, by controlling the electric field or magnetic field on the substrate side, a variety of processings, according to the shape pattern of interconnect trenches and via holes and to the structure of semiconductor device, becomes possible.

In the case of the abrasive processing utilizing an electrostatic or magnetic force, a single or plurality of electric field or magnetic field sensors may be provided, for example, on the tool side. A signal from the sensor is processed by means of e.g. a PC and, based on the processed signal, the electric or magnetic field can be equalized. This enables a level difference-eliminating processing. It is also possible to provide a plurality of fine electrodes or magnetic poles in a substrate holder or on the tool side and, according to the above-described signal processed by PC, cause the electrodes or magnetic poles to act electrically so as to effect uniform processing. It is also effective to utilize an end point detection mechanism.

The \textcircled{6} electrolytic processing utilizing a catalyst effects removal processing by supplying pure water, preferably ultrapure water, or a liquid having an electric conductivity of not more than 500 μS/cm between a substrate and an electrode, allowing an ion exchanger as a catalyst to be present between the substrate and the electrode, and applying an electric field between the substrate and the electrode, thereby processing the surface of the substrate with ions dissociated by the ion exchanger. Though a liquid having an electric conductivity of not more than 500 μS/cm is suited for the purpose of level difference elimination, a liquid having a higher electric conductivity may be used to increase the processing rate.

In the CMP, the composite electrolytic processing (polishing), the common electrolytic processing, the electrolytic processing utilizing a catalyst, etc. usable in the present invention, polishing tables (processing tools) of various types, such as rotary, linear, scroll, belt and roller, which can make various relative movements, can be selected and used in consideration of the merits and demerits of their manners of movement. A tool having a larger size than a substrate as a processing object is generally used. It is, however, possible to select and use a small-sized (small-diameter) tool (pencil type), having the merit of downsizing of the apparatus, or a small-sized roller-type tool (the length of roller is shorter than the diameter of substrate and movable lengthwise and crosswise). Further, with respect to the shape of tool, various shapes such as a web, including a disc-shaped web having a plane processing surface and a rectangular web having a plane processing surface, a cup, a cylindrical shape (such as the above-described roller type), etc. may be employed, according to necessity.

Of the above-described processing methods, the CMP with a polishing pad and a slurry, the fixed-abrasive CMP, the CMP with an abrasive-free chemical liquid and the composite electrolytic processing are based on the following general processing principle: The surface of an interconnect material is oxidized by a chemical component in a slurry supplied from the outside to form a chelate film (passivated film) of the interconnect material. Raised portions of the chelate film, corresponding to raised portions of the irregularities of the interconnect material, are removed selectively by the abrasive component of the slurry and by a relative movement between a polishing pad and a substrate. The step of forming the chelate film and the step of removing the chelate film are carried out repeatedly, thereby flattening the raised portions of the interconnect material.

Since the purpose of the first step is elimination of a level difference, the range of options of processing methods is broadened to cutting or grinding. Also to cutting or grinding, the general processing principle is applicable by using a chemical liquid.

In general, a cutting or grinding method is often used for obtaining a flat processed surface. However, when carrying out the processing of a substrate with this method at a high processing pressure, because of its large processing unit, processing distortions and cracks are likely to be produced. This processing method, therefore, is infrequently used for processing of a semiconductor wafer. On the other hand, with the recent advance of MEMS technology, production of a fine structure is becoming easier and production of a fine-processing tool is becoming possible. Considering the mechanical durability of a ULK (ultra low-dielectric constant) material that has been used recently, it is possible to use a fine-processing tool such as of a fine-bite array structure. By processing a substrate by means of such a fine-processing tool at a low processing pressure, e.g. an area-average pressure of not more than 3 psi, it becomes possible to effect a high-quality level difference elimination processing without damage to a substrate.

Also with grinding, production of ultrafine abrasive grains is becoming easier in these days. Further, an abrasive tool has been produced which employs, as a binder for binding abrasive grains, a water-soluble binder or a thermoplastic resin having a Tg around room temperature. With the use of a tool having a high content of fine abrasive grains and of a low processing pressure, processing without damage to a substrate has become possible. In a cutting or grinding process, processing of a workpiece is preferably carried out in the presence of a cooling liquid. In the case of cutting, it is possible to use a chemical liquid for preventing a processing surface from being roughened, promoting the processing, or protecting the bite, or use an electrolytic solution (for assisting current electrolysis). In the case of grinding, it is possible to use a chemical liquid for promoting re-generation of old abrasive grains remaining on the processing surface of a tool or promoting dispersion of the re-generated abrasive grains, or use an electrolytic solution (for assisting current electrolysis).

Even when the interconnect material is damaged during this process step (first step), if the damage is a small processing distortion, crack, scratch, or the like (surface defect), such a damage or defect can be removed in the subsequent process steps. Accordingly, even cutting or grinding, which is fairly likely to cause small defects, can be used. Cutting or grinding is a movement transfer technology. By using a precision instrument technology to move a tool at a high speed, it is possible to stabilize the moving surface of the tool and increase the processing frequency of each bite or each abrasive grain. This reduces and equalizes damages to a substrate, enabling a high-quality level difference-eliminating processing.

In the case of CMP method, with commonly-used high pressure (5-7 psi) and low relative movement speed (0.1-0.4 m/sec), a distortion will be produced by elastic deformation in the processing surface of a tool, and elimination of a level difference in the surface of a substrate can be achieved with difficulty. On the other hand, elimination of a level difference can be achieved by carrying out the processing with a tool having a high Young's modulus or under the conditions of low pressure (about 0.1-3 psi) and high relative movement speed (0.5-10 m/sec) Though CMP is currently most often carried out at a processing pressure around 6 psi, it is desirable, for protection of ULK material and prevention of peeling and cracking of interconnect material and also from a practical viewpoint as of processing rate, to carry out processing at a processing pressure of about 0.1 to 3 psi. In this connection, as shown in FIG. 2 and as will be also appreciated from the Preston's Equation (Processing rate ∝ processing pressure×Relative speed), a high-speed processing is possible even with a low processing pressure by moving a tool or abrasive grains at a high relative speed.

The composite electrolytic processing (polishing) method comprises a chelate film formation step of oxidizing the surface of an interconnect material (electrically conductive material) and forming a chelate film (passivated film) of the oxidized interconnect material, and a chelate film removal step of selectively removing raised portions of the chelate film, corresponding to raised portions of the irregularities of the interconnect material, thereby exposing the interconnect material at the raised portions, and carries out the chelate film formation step and the chelate film removal step repeatedly until the raised portions of the interconnect material are flattened (see, for example, Japanese Patent Laid-Open Publication No. 2001-326204). A slurry or abrasive grains may be used as necessary.

While the processing principle is similar to the above-described CMP, according to the composite processing method, the surface oxidation of interconnect material can be assisted by an electrical force, the processing surface of a substrate can be covered with a mechanically weak oxide film (passivated film), and only the processing surface in contact with a tool can be processed. The composite electrolytic processing method can, therefore, be used to eliminate a level difference in the surface of a substrate. Further, since the thickness of the oxide film can be controlled, a fast flattening speed can be achieved. Moreover, by controlling the processing pressure between a tool and a substrate within the range of from 0.1 to 3 psi, a defect-free processing becomes possible.

With respect to the electrolytic processing utilizing a catalyst, a method has been developed which uses as a tool an ion exchanger that performs a catalytic action, and uses as a processing liquid (environment) pure water, preferably ultrapure water, or a liquid having an electric conductivity of not more than 500 μS/cm. A substrate after plating has fine irregularities on the surface (plated surface). According to the electrolytic processing method, when pure water is used as the processing liquid, pure water is present also within the recesses in the substrate surface. Since pure water itself is little dissociated, removal processing of the substrate does not substantially progress at the recess portions in contact with pure water. Thus, removal processing progresses only at those portions that are in contact with an ion exchanger, which is abundant in ions. This electrolytic processing method has the advantage of superior flattening performance over an electrolytic processing method that uses a common electrolytic solution.

The processing principle of the electrolytic processing utilizing a catalyst, in contrast with a conventional physical processing, resides in a chemical dissolution reaction to effect removal processing or the like. Accordingly, this processing method is characterized by its no formation of defects, such as an affected layer and displacement due to plastic deformation, and its capability of performing processing without impairing the properties of an interconnect material. This processing method, by bringing an ion exchange membrane, as a catalyst for ion dissociation, into contact with the processing surface of a substrate, allows the contact portion to be selectively processed electrochemically. A high processing rate can, therefore, be obtained even when the processing pressure is controlled at a very low pressure (0.1 to 3 psi). Further, the processing method has a high capability of eliminating a level difference, and is therefore a very effective processing method. Though a liquid having an electric conductivity of not more than 500 μS/cm is suited for the purpose of eliminating a level difference, a liquid having a higher electric conductivity may also be used to increase the processing rate.

The step of removing the interconnect material until the interconnect material present in the non-interconnect region of the substrate becomes a thin film or remains partly on the barrier material (second step) is illustrated in FIGS. 6B and 6C. It is preferred that this processing step be carried by at least one of \textcircled{1} CMP, \textcircled{2} composite electrolytic processing, \textcircled{3} electrolytic processing utilizing a catalyst, \textcircled{4} a common electrolytic processing, \textcircled{5} abrasive processing utilizing an electrostatic or magnetic force and \textcircled{6} dry etching or chemical etching. This process step (second step) is a processing step for processing and removing the flattened interconnect material, while maintaining the surface flatness, until the interconnect material becomes a thin film with a thickness of several nm to several hundred nm or remains partly on the barrier material. It is therefore desirable to use a processing method which can effect uniform processing and, when the deposition amount of interconnect material is large, can process the interconnect material at a high rate. As with the first step, the \textcircled{1} CMP includes, besides a common CMP with a combination of a polishing pad and a slurry containing abrasive grains, fixed-abrasive CMP and CMP that employs an abrasive-free chemical liquid. This holds for the later process steps.

In particular, a processing method that utilizes an electric force, because of its controllability, can effect a high-speed processing. Processing by a chemical action with excellent isotropy is also effective. In cases where the isotropy cannot be maintained only with a chemical, for example when the interconnect material has a grain boundary, dry etching may be effective. In the case where dry etching can be utilized, formation of upper-layer interconnects is also possible. However, such an etching method may not be used for a device that uses copper as an interconnect material, because copper is hard to etch as described previously.

On the other hand, a processing method, such as cutting or grinding which is likely to cause a relatively large damage (surface defects), such as processing distortions, cracks and scratches, to a substrate, is not preferred for use in this process step. This is because the depth to be processed after completion of this step (i.e. the processing allowance in the next to final steps) is on the order of several nm to 100 nm and, therefore, it is fairly likely that the defects cannot be removed in the subsequent steps.

This process step (second step), unlike a conventional process, is terminated before the different material i.e., barrier material, appears in the processing surface. Accordingly, processing can be effected with a simplified processing system, and a high-quality processing is feasible. Since the barrier material is not exposed and processing is carried out exclusively on the conductive interconnect material, stable and highly uniform processing can be effected with a processing method utilizing an electric force, such as electrolytic processing, composite electrolytic processing, a common electrolytic etching, or ultrapure water electrolytic processing.

In order to terminate processing with a target film thickness, it is desirable to carry out the processing by an apparatus provided with an end point detection (EPD) device, such as a film thickness detection device. When the interconnect material is copper, detection of the film thickness using an eddy current is suited. The film thickness of interconnect material may also be detected optically.

In the case of carrying out this process step (second step) by CMP, it has been proposed generally to carry out this step of processing in the same step as level difference elimination. However, by making this step of processing independent of the level difference elimination step (first step) and specializing it as a step of uniformly processing the flattened surface of interconnect material until the interconnect material becomes a thin film, it becomes possible to carry out processing at a high processing rate and under processing conditions which are advantageous to uniform processing. In case that the above-described step (first step) and this step (second step) are carried out with the same processing tool, it is desirable to carry out this step (second step) at a higher processing pressure or with a higher relative movement speed than that of the first step so as to effect the additional processing after the flattening at a high rate.

As described above, the composite electrolytic processing is a processing method which involves the anodic oxidation and chelating of the surface of interconnect material by electrolysis in combination with polishing of the surface by mechanical contact. The processing may be carried out, for example, by supplying a slurry including an electrolytic solution or a chemical liquid including an electrolytic solution between a substrate and an electrode while allowing a polishing pad or the like to be in contact with the substrate and applying an electric field between the substrate and the electrode. In contrast with a conventional processing method that resorts mainly to physical processing, a processing method that effects physical processing utilizing an electric force or electrochemical processing, such as chemical polishing, electrolytic processing, composite electrolytic processing or electrolytic polishing, causes a chemical dissolution reaction to take place so that removal processing can be effected with a very weak physical force. Accordingly, formation of defects, such as an affected layer and displacement due to plastic deformation, can be prevented, and processing can be carried out without impairing the properties of the material being processed. Further, a processing method utilizing an electric force, in addition to its easy control of processing rate, enables a high-speed processing.

In the current process of embedding interconnect material by plating in interconnect recesses, because of the low covering and embedding characteristics, it is necessary to deposit the interconnect material thick to some extent. This requires a process step for removing not only a level difference produced in the deposition process, but also an extra deposition. Depending upon the deposition method and the depositing material, the processing amount (or thickness) in the removal processing step may be considerably large. In such a case, it is effective to employ a processing method utilizing an electric force that causes fewer scratches and can carry out the processing at a high speed.

It is possible to employ a processing method, which is excellent in eliminating a level difference, also in this process step (second step). Thus, when carrying out composite electrolytic processing, for example, the level difference elimination step (first step) and this step (second step) may be combined without separation, or carried out successively.

By employing electrolytic processing utilizing a catalyst in this process step and using pure water, preferably ultrapure as a processing liquid, it is possible to effect a high-quality processing without contamination. Further, because of electrochemical processing, this processing method enables a defect-free high-speed processing. When the electrolytic processing method utilizing a catalyst, which is excellent in elimination of a level difference, is employed also in this step, it is possible, as with the case of composite electrolytic processing, to combine the level difference elimination step (first step) and this step (second step),.and carry out these steps continuously under the same conditions. Alternatively, it is possible to carry out the first-step processing by supplying a liquid having an electric conductivity of not more than 500 μS/cm and replace the liquid with an electrolytic solution in the second step. This enables a high-speed processing after flattening.

A common electrolytic processing (carried out, for example, by immersing a processing object in an electrolytic solution) can provide a high-quality processed surface free from physical defects and can effect a high-speed uniform processing. A common electrolytic processing, therefore, is an effective processing method for this step.

Chemical etching is isotropic and, in principle, is fast processing, and therefore is an effective processing method for this step. Etching that utilizes a high relative speed of a slurry or chemical liquid (oxidizing agent such as H₂O₂, preservative such as BTA), which is advantageous to flattening, is also effective. For example, using a similar apparatus to a spin coater that is used in other process, a slurry or chemical liquid may be jetted toward a substrate almost parallel to the processing surface of the substrate so as to process. Alternatively, a substrate may be disposed in a bath, which is capable of flowing a slurry or chemical liquid at a high speed, such that the processing surface of the substrate is parallel to the flow of the slurry or liquid. This processing method can be used also in the level difference elimination step (first step).

There are cases where the isotropy cannot be maintained only with chemical etching, as in the case where the conductive material has a grain boundary. In such a case, dry etching such as RIE may also be employed.

In the second step, the film thickness of the interconnect material in the non-interconnect region is detected with an eddy-current sensor, an optical film thickness detection means, or the like. The second step is terminated when the film thickness has reached a value which is, for example, not more than 300 nm, preferably not more than 100 nm, more preferably not more than 50 nm. It is also possible to terminate the second step by time management.

The step of removing the interconnect material in the form of a thin film or remaining partly on the barrier material, thereby exposing the barrier material or further processing the barrier material (third step) is illustrated in FIGS. 6C and 6D. This process step is preferably carried out by at least one of \textcircled{1} CMP, \textcircled{2} composite electrolytic processing, \textcircled{3} a common electrolytic processing, \textcircled{4} electrolytic processing utilizing a catalyst and \textcircled{5} dry etching or chemical etching. As with the above-described step (second step) of processing the interconnect material into a thin film, this step (third step) carries out the processing of the interconnect material. On the other hand, the barrier material becomes exposed at the end of processing in this step. Accordingly, it is necessary to properly determine the end point of processing and, in addition, make the processing selectivity ratio between the interconnect material and the barrier material nearly 1. The processing amount is very small, several nm to several hundred nm, and therefore a high processing speed (rate) is not required. Instead, since the different material, barrier material, becomes exposed, adjustment of the selectivity ratio is needed and processing that does not cause a large damage to the interconnect material and the barrier material is required.

The selectivity ratio herein refers to the processing rate ratio between materials. Thus, the selectivity ratio 1:1 in processing of two materials means that the two materials are processed at the same processing rate. It is desirable to select a processing method involving a mechanical action that is excellent in flattening. In the case of a processing method involving a mechanical action, however, the barrier material is inevitably processed upon its exposure, simultaneously. In carrying out this step (third step), therefore, the processing environment and processing conditions are so adjusted as to make the processing rates of. the two materials almost equal (selectivity ratio is nearly 1). For this purpose, fixed-abrasive CMP, CMP with an abrasive-free CMP or composite electrolytic processing is especially effective.

In general, the interconnect material, due to the presence of a crystal grain boundary, has a processing anisotropy. Accordingly, flat processing of the interconnect material is difficult with a common CMP method. Further, adjustments are necessary to prevent formation of defects. On the other hand, flat processing of the interconnect material can be effected by using a tool of high Young's modules, such as a fixed-abrasive pad, and suppressing the elastic deformation. In carrying out such processing, attention should also be paid to prevention of defects and, for this purpose, it is desirable to carry out processing at a low pressure. Though depending upon the processing object material, the device structure, etc., it is desirable to use a processing pressure of about 0.1 to 3 psi, which is lower than the pressure of 5 to 7 psi currently used. Further, it is desirable to use a lower processing pressure than the processing pressure used in the second step.

It is also possible to use a special processing method which little processes the barrier material and can stop processing of the interconnect material immediately after the barrier material becomes exposed. In particular, a highly chemically adjusted CMP or an (pure water) electrolytic processing method utilizing a catalyst can be employed. When an etchable material, other than copper, is used as the interconnect material, a processing method not involving contact between the interconnect material and a tool, such as electrolytic processing, dry etching or chemical etching, may also be employed.

In this step (third step), it is important for maintaining the flatness of the processed surface to detect the full exposure of the different material, barrier material, so as to terminate the processing. When the interconnect material is copper, an eddy-current film thickness detection sensor may be used as an end point detection device. When the transmissivity, refractive index, and reflectivity of light differ between the interconnect material and the barrier material, an optical film thickness detection sensor (optical sensor) may also be used as an end point detection device. The use of an optical sensor (end point detector) which can detect the difference in reflectivity is practically desirable.

In case that determination as to whether a partial or full exposure of the barrier layer is difficult with an optical film thickness detection sensor, it is desirable to employ a combination of the film thickness detection means and time management, that is, after detection of exposure of the barrier layer with an optical sensor, continue processing for a predetermined length of time to termination.

The step of simultaneously removing the unnecessary interconnect material and the barrier material until the barrier material present in the non-interconnect region becomes a thin film or remains partly (fourth step) is illustrated in FIGS. 6D and 6E. This process step is preferably carried out by at least one of \textcircled{1} CMP, \textcircled{2} composite electrolytic processing, \textcircled{3} a common electrolytic processing, \textcircled{4} electrolytic processing utilizing a catalyst, \textcircled{5} dry etching or chemical etching and \textcircled{6} independent processings of interconnect material and of barrier material. This process step (fourth step) removes the interconnect material which has become a thin film and also simultaneously removes the barrier material deposited (in the form of a film) such that it covers the surface of interconnect trenches and via holes. Thus, the two different materials (interconnect material and barrier material) are always processed simultaneously. This process step necessitates a processing method and processing conditions that are superior in suppression of defects to the above-described steps and more securely prevents formation of defects. Further, in order to simultaneously process the different materials, i.e. the interconnect material and the barrier material, while maintaining the surface flatness obtained in the preceding steps, highly controlled processing conditions are needed in a chemical or electrochemical processing method.

When the barrier material is an electrically conductive material, such processing conditions are necessary that adjust the processing rate ratio (selectivity ratio) between the electrically conductive material as the interconnect material and the electrically conductive material as the barrier material to nearly 1. This requirement can be met by carrying out electrochemical processing while supply an electrolytic solution (containing an oxidizing agent such as H₂O₂, a preservative such as BTA) or chemical liquid, which is chemically adjusted to meet the conditions. Though dependent upon the processing time of this step and the processing accuracy of the next step, it is desirable that the selectivity ratio (the processing rate ratio of the interconnect material to the barrier material) be adjusted to about 0.25 to 4.0.

This process step can also be effected by employing CMP, such as fixed-abrasive CMP or CMP with an abrasive-free chemical liquid, which is carried out, under chemical conditions (addition of an oxidizing agent such as H₂O₂, a preservative such as BTA to a polishing liquid) with which the selectivity ratio is adjusted to nearly 1 or under the conditions of low processing pressure and high relative movement speed, by supplying a slurry or chemical liquid onto a polishing pad of a resin or an abrasive-containing resin while pressing a substrate against the polishing pad.

With a CMP method that utilizes mechanical processing or a composite electrolytic processing method, it is possible to adjust the selectivity rate by utilizing a high-speed relative movement and effect processing with few defects at a low processing pressure. According to (pure water) electrolytic processing utilizing a catalyst, the contact portion can be processed preferentially, which makes it possible to process the materials while maintaining the surface flatness.

When the amount of the barrier material to be removed is small, the selectivity ratio may not necessary be nearly 1. For example, it is possible to first preferentially progress processing of the barrier material under such conditions that the barrier material is preferentially removed, and then preferentially progress processing of the interconnect material under such conditions that the interconnect material is preferentially removed.

Further, when the barrier material is an insulating material, chemical mechanical processing (CMP) can be employed for carrying out this process step. Besides a common CMP that uses a polishing pad and a slurry containing abrasive grains, it is possible to employ a CMP, such as fixed-abrasive CMP or CMP with an abrasive-free chemical liquid, which carries out processing of a substrate by supplying a slurry or chemical liquid onto a polishing pad of e.g. a resin containing resin particles or abrasive grains while pressing the substrate against the polishing pad, as described above.

Provided that the selectivity ratio is chemically adjustable, this process step can be carried out by chemical etching. Etching utilizing a high relative speed of a slurry or chemical liquid, which is advantageous to flattening, may also be employed.

Further, when the barrier material is a material hard to process, processing of the interconnect material and processing of the barrier material may be carried out independently. In that case, it is possible to mask the interconnect material with a photo-resist and process. the barrier material by dry etching.

The step of removing the unnecessary interconnect material and the barrier material in the form of the thin film, thereby exposing the insulating material in the non-interconnect region or further processing the insulating material (fifth step) is illustrated in FIGS. 6E and 6F. This process step is preferably carried out by at least one of \textcircled{1} CMP, \textcircled{2} composite electrolytic processing, \textcircled{3} a common electrolytic processing, \textcircled{4} electrolytic processing utilizing a catalyst, and \textcircled{5} dry etching or chemical etching. As with the above-described process step of processing the interconnect material and the barrier material into thin films (fourth step), this process step (fifth step) processes the two materials. On the other hand, the insulating material becomes exposed at the end of this process step. It is therefore necessary to properly determine the end point of processing and carry out the processing with the processing selectivity ratio between the interconnect material, the barrier material and the insulating material nearly 1:1:1. The processing amount is very small, several nm to several tens nm, and therefore a high processing rate (speed) is not required. Instead, since the different material, the insulating material, becomes exposed, adjustment of the selectivity ratio is needed and processing that does not cause even a small damage to the surface of the interconnect material, the barrier material and the insulating material is required.

It is therefore desirable to select a processing method involving a mechanical action that is excellent in flattening and causes few defects. In the case of a processing method involving a mechanical action, the insulating material is inevitably processed upon its exposure, simultaneously. In carrying out this step, therefore, the processing environment and processing conditions should be so adjusted that the processing rates of the three materials become almost equal (selectivity ratio nearly 1:1:1). For this purpose, fixed-abrasive CMP, CMP with an abrasive-free chemical and composite electrolytic processing are effective.

Since the depth to the processing end surface is as small as several nm, attention should also be paid to prevention of defects and, therefore, processing should desirably be carried out at a low processing pressure. Though depending upon the processing object material, the device structure of the substrate, etc., a desirable processing pressure in CMP is 0.1 to 3 psi, which is lower than the pressure of 5 to 7 psi currently used. The processing pressure in this process step is preferably further lower than that used in the fourth step.

It is also possible to use a special processing method which little processes the insulating material and can stop processing of the interconnect material and the barrier material immediately after the insulating material becomes exposed. In particular, a highly chemically adjusted CMP or an (pure water) electrolytic processing method utilizing a catalyst can be employed. A processing method not involving contact between the materials and a tool, such as electrolytic processing, dry etching or chemical etching, may also be employed.

It is important for maintaining the flatness of the processed surface to detect the full exposure of the different material so as to terminate the processing. When the interconnect material is copper or the barrier material is conductive material, an eddy-current film thickness detection sensor may be used as an end point detection device. When the reflectivity of e.g. light differs between the barrier material and the insulating material, an optical sensor may also be used as an end point detection device.

As the technology node becomes smaller a barrier material will become thinner. It is considered, therefore, that in the further this step (fifth step) may possibly be carried out under the same processing conditions as the steps before and/or after this step. That is, the fourth and fifth steps, the fifth and sixth steps, or the fourth, fifth and sixth steps may possibly be carried out not as separate steps, but as a combined step. Such a combined step could nevertheless effect processing without impairing the surface flatness.

The step of simultaneously processing the unnecessary interconnect material, the barrier material and the insulating material (sixth step) is illustrated in FIGS. 6F and 6G. This process step is preferably carried out, for example, by at least one of \textcircled{1} CMP and \textcircled{2} dry etching or chemical etching. Processing of the interconnect region and the insulating region is completed in this step (sixth step) and the processed surface after processing directly affects the device performance. This step is therefore important for suppressing or reducing defects and ensuring the surface flatness. This step is optional and carried out according to necessity, and is directed to removal of defects formed in the preceding steps. It is therefore desirable to select a processing method that does not produce defects.

The processing objects, in this step, include the insulating material which is required to be electrochemically stable. Accordingly, composite electrolytic processing carried out by supplying a slurry or chemical liquid, including an electrolytic solution, between a substrate and a polishing pad while applying an electric field between the processing surface of the polishing pad and the substrate, electrolytic processing utilizing a catalyst, electrolytic processing without contact between a tool and a substrate, etc. are not preferred. Effective processing methods for this step are, for example, a CMP, such as fixed-abrasive CMP or CMP with an abrasive-free chemical liquid, which is carried out by supplying a slurry or chemical liquid onto a polishing pad of e.g. a resin or an abrasive-containing resin while pressing a substrate against the polishing pad, and dry etching or chemical etching. A processing method involving a weak physical action is preferred. A defect-free processing can be effected by operating at a low pressure, for example, not more than 3 psi.

In the case of CMP, for example, a defect-free processing can be effected by using a slurry containing special abrasive grains, such as very fine abrasive grains, resin particles, composite abrasive grains with resin particles or a surfactant as nuclei, and composite particles comprising abrasive grains and a protective coating of a surfactant or a polymer or the like, which can carry out processing only with the abrasive grain portion which has protruded out of the protective coating by application of a pressing force. A defect-free processing can also be effected by carrying out special chemical adjustments, such as surface modification by light (a photo-catalyst may also be used), processing of softening or weakening of the topmost surface of the insulating material with a chemical, followed by processing of the modified portion.

The present invention also provides yet another substrate processing method for removing unnecessary interconnect material and barrier material on a substrate and flattening a surface of the substrate, wherein the interconnect material is embedded in interconnect recesses, the interconnect recesses being formed on a surface of an insulating material and having a film of the barrier material formed on the surface of an insulating material, the method comprising: removing the interconnect material until the interconnect material present in the non-interconnect region of the substrate becomes a thin film or remains partly; and then completely removing the interconnect material, present in the non-interconnect region, in the form of the thin film or remaining partly, thereby exposing an underlying material present under the interconnect material in the non-interconnect region.

The step of removing the interconnect material until the interconnect material present in the non-interconnect region of the substrate becomes a thin film or remains partly may comprise an additional step of eliminating a level difference in the surface of the interconnect material. Further, the step of removing the interconnect material until the interconnect material present in the non-interconnect region of the substrate becomes a thin film or remains partly may be terminated when the film thickness of the interconnect material present in the non-interconnect region has reached a value of not more than 300 nm. The film thickness of the interconnect material present in the non-interconnect region is preferably detected with an eddy-current or optical film thickness measuring means.

Preferably, the processing rate of the interconnect material in the step of completely removing the interconnect material, present in the non-interconnect region, in the form of the thin film or remaining partly is lower than the processing rate of the interconnect material in the step of removing the interconnect material until the interconnect material present in the non-interconnect region of the substrate becomes a thin film or remains partly. The step of completely removing the interconnect material, present in the non-interconnect region, in the form of the thin film or remaining partly may be carried out by using a processing liquid or a chemical liquid.

The step of completely removing the interconnect material, present in the non-interconnect region, in the form of the thin film or remaining partly may be carried out while applying a first pressure to the substrate, and the step of removing the interconnect material until the interconnect material present in the non-interconnect region of the substrate becomes a thin film or remains partly may be carried out while applying a second pressure, which is lower than the first pressure, to the substrate.

The substrate processing method may further comprise a step of removing the underlying material present in the non-interconnect region until a material present under the underlying material becomes exposed. The step of removing the underlying material may comprise a step of removing the underlying material until the underlying material becomes a thin film or remains partly, and a step of removing the underlying material in the non-interconnect region until a material present under the underlying material becomes exposed.

The present invention also provides a substrate processing method for removing unnecessary interconnect material and barrier material on a substrate and flattening a surface of the substrate, wherein the interconnect material is embedded in interconnect recesses, the interconnect recesses being formed on a surface of an insulating material and having a film of the barrier material formed on the surface of an insulating material, the method comprising: simultaneously removing the unnecessary interconnect material and barrier material until the barrier material present in the non-interconnect region of the substrate becomes a thin film or remains partly; and then removing the unnecessary interconnect material and the barrier material in the form of the thin film or remaining partly, thereby exposing an underlying material present under the barrier material in the non-interconnect region.

The step of removing the unnecessary interconnect material and the barrier material in the form of the thin film or remaining partly (second step) may be carried out while applying a first pressure to the substrate, and the step of simultaneously removing the unnecessary interconnect material and barrier material until the barrier material present in the non-interconnect region of the substrate becomes a thin film or remains partly (first step) may be carried out while applying a second pressure, which is lower than the first pressure of the second step, to the substrate. Though scratch-free processing can be generally effected by carrying out the second step of processing at a lower processing pressure than that of the first step, elimination of a level difference and high-speed processing can be achieved by changing the hardness or elastic coefficient of a tool. Thus, depending upon the conditions, the first step of processing can be carried at a lower processing pressure than that of the second step.

The present invention also provides a substrate processing apparatus, comprising: an electrolytic processing section, provided with an end point detection device, for carrying out electrolytic processing of a substrate held by a substrate holder; a CMP section, provided with an endpoint detection device, for carrying out chemical mechanical polishing of the substrate held by a substrate holder; and a substrate transfer device for transferring the substrate, wherein the substrate is processed both in the electrolytic processing section and in the CMP section.

The electrolytic processing includes composite electrolytic processing, electrolytic processing using an electrolytic solution, electrolytic processing using a catalyst, and a common electrolytic processing.

### BRIEF DESCRIPTION OF DRAWINGS

FIGS. 1A through 1F are diagrams illustrating, in sequence of process steps, a conventional copper-interconnects formation process;

FIG. 2 is a graph showing the relationship between “relative speed” and “processing pressure” in CMP;

FIG. 3 is an overall plan view of a substrate processing apparatus according to an embodiment of the present invention;

FIG. 4 is a diagram showing the relationship between a substrate holder, a CMP section and an electrolytic processing section shown in FIG. 3;

FIG. 5 is an enlarged view of the electrolytic processing section shown in FIG. 3;

FIGS. 6A through 6G are diagrams illustrating, in sequence of process steps, a substrate processing method according to the present invention;

FIG. 7 is a diagram illustrating protection of exposed surfaces of interconnects with a protective film;

FIG. 8 is a schematic diagram showing an electroless plating apparatus;

FIG. 9 is a schematic diagram showing another electroless plating apparatus;

FIG. 10 is a cross-sectional view showing a substrate head of yet another electroless plating apparatus upon transfer of a substrate;

FIG. 11 is an enlarged view of the portion B of FIG. 10;

FIG. 12 is a view corresponding to FIG. 11, showing the substrate head of the electroless plating apparatus of FIG. 10 upon fixing of a substrate;

FIG. 13 is a view corresponding to FIG. 11, showing the substrate head of the electroless plating apparatus of FIG. 10 upon plating;

FIG. 14 is a partially sectional front view of a plating tank of the electroless plating apparatus of FIG. 10;

FIG. 15 is a cross-sectional view of a cleaning tank of the electroless plating apparatus of FIG. 10;

FIG. 16 is a partially sectional front view of a CMP apparatus;

FIG. 17A is a plan view of a support plate provided in the CMP apparatus of FIG. 16, and FIG. 17B is a cross-sectional view taken along the line A-A of FIG. 17A;

FIG. 18 is a perspective view of another CMP or electrolytic processing apparatus;

FIG. 19 is a perspective view of yet another CMP or electrolytic processing apparatus;

FIGS. 20A through 20C are diagrams showing a cup-type abrasive wheel provided in yet another CMP or electrolytic processing apparatus;

FIG. 21 is a perspective view of the CMP or electrolytic processing apparatus incorporating the cup-type abrasive wheel shown in FIG. 20A through 20C;

FIG. 22 is a cross-sectional view of yet another CMP or electrolytic processing apparatus;

FIG. 23A is a sectional side view (taken along the line G-G of FIG. 23B) showing another cup-type abrasive wheel, and FIG. 23B is a rear view of the cup-type abrasive wheel;

FIG. 24 is a perspective view of yet another CMP or electrolytic processing apparatus;

FIG. 25 is a front view of yet another CMP or electrolytic processing apparatus;

FIG. 26 is a plan view of FIG. 25;

FIG. 27 is a side view of yet another CMP or electrolytic processing apparatus;

FIG. 28 is a front view of FIG. 27;

FIG. 29 is a cross-sectional view taken along the line A-A of FIG. 28;

FIG. 30A shows the apparatus of FIG. 28 as viewed from arrow C, and FIGS. 30B and 30C are sectional side views of FIG. 30A;

FIG. 31 is a cross-sectional view taken along the line B-B of FIG. 27;

FIG. 32 is a schematic diagram showing a composite electrolytic processing apparatus;

FIGS. 33A through 33C are diagrams illustrating the principle of composite electrolytic processing in the composite electrolytic processing apparatus of FIG. 32;

FIG. 34 is a schematic diagram showing an electrolytic processing apparatus that carries out a common electrolytic processing;

FIG. 35 is a plan view showing an electrolytic processing apparatus that utilizes a catalyst;

FIG. 36 is a vertical sectional front view of the electrolytic processing apparatus shown in FIG. 35;

FIG. 37 is a plan view of an electrode section of the electrolytic processing apparatus shown in FIG. 35;

FIG. 38 is a cross-sectional view taken along the line B-B of FIG. 37;

FIG. 39 is an enlarged view of a portion of FIG. 38;

FIG. 40 is a cross-sectional view showing the main portion of another substrate holder usable in the electrolytic processing apparatus that utilizes a catalyst;

FIG. 41 is a plan view of a substrate holder of FIG. 40;

FIG. 42 is a schematic diagram showing a dry etching apparatus;

FIG. 43A is a side view showing a chemical etching apparatus, and FIG. 43B is a plan view of FIG. 43A;

FIG. 44 is a vertical sectional front view of yet another CMP apparatus;

FIG. 45 is a plan view of a turntable of FIG. 44;

FIG. 46A is an enlarged sectional view of a portion of the turntable with a polishing cloth attached thereto, showing an eddy-current sensor embedded in the turntable, and FIG. 46B is an enlarged sectional view of a portion of the turntable with a fixed-abrasive plate mounted thereon, showing the eddy-current sensor embedded in the fixed-abrasive plate;

FIG. 47 is a vertical sectional front view of yet another electrolytic processing apparatus;

FIG. 48 is a front view of yet another CMP apparatus;

FIG. 49 is a schematic diagram illustrating a construction of the sensor section of FIG. 48;

FIG. 50 is a schematic diagram illustrating another construction of the sensor section of FIG. 48; and

FIG. 51 is a vertical sectional front view of yet another electrolytic processing apparatus.

### BEST MODE FOR CARRYING OUT THE INVENTION

Preferred embodiment of the present invention will now be described with reference to the drawings.

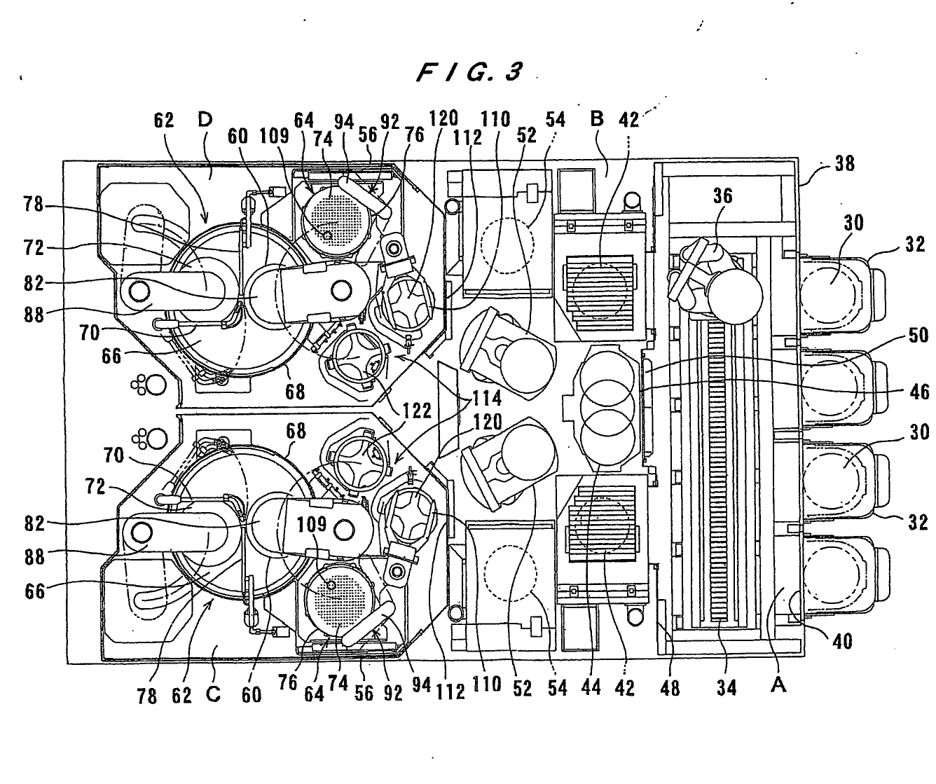

FIG. 3 is an overall plan view of a substrate processing apparatus according to an embodiment of the present invention. As shown in FIG. 3, the substrate processing apparatus includes four loading/unloading stages 32 each for mounting a substrate cassette 30 that stores a number of substrates, such as semiconductor wafers. A first transfer robot 36 having two hands is disposed on a travel mechanism 34 so that the robot 36 can reach the substrate cassettes 30 on the loading/unloading stages 32. The travel mechanism 34 employs a linear motor system. The use of linear motor system enables a stable high-speed transfer of a substrate even when the substrate has large size and weight.

According to this embodiment, an external SMIF (Standard Manufacturing Interface) pod or FOUP (Front Opening Unified Pod) is used as the loading/unloading stage 32 for mounting the substrate cassette 30. The SMIF and FOUP are closed vessels each of which can house the substrate cassette 30 therein and, by covering with a partition, can keep the internal environment independent of the external space. When the SMIF or FOUP is set as the loading/unloading stage 32 of the substrate processing apparatus, a shutter 40 on the substrate processing apparatus side, provided in a housing 38, and a shutter on the SMIF or FOUP side are opened, whereby the substrate processing apparatus and the substrate cassette 30 side become integrated. After completion of substrate processing process, the shutters are closed to separate the SMIF or FOUP from the substrate processing apparatus, and the SMIF or FOUP is transferred automatically or manually to another processing process. It is therefore necessary to keep the internal atmosphere of the SMIF or FOUP clean.

For that purpose, there is a down flow of clean air through a chemical filter in the upper space of an area A, which a substrate passes through right before returning to the substrate cassette 30. Further, since the linear motor is employed for traveling of the first transfer robot 30, scattering of dust can be reduced and the atmosphere in the area A can be kept clean.

In order to keep substrates in the substrate cassette 30 clean, it is possible to use a clean box that may be a closed vessel, such as a SMIF or FOUP, having a built-in chemical filter and a fan, and can maintain its cleanness by itself.

A pair of cleaning machines 42 is disposed on the opposite side of the travel mechanism 34 for the first transfer robot 36 from the loading/unloading stages 32. Each cleaning machine 42 is disposed at a location within reach of the hands of the first transfer robot 36. Further, a substrate station 46 provided with four substrate stages 44 is disposed between the pair of cleaning machines 42 and at a location within reach of the hands of the first transfer robot 36.

In order to differentiate the degree of cleanness of an area B in which the cleaning machines 42 and the substrate station 46 are disposed from the degree of cleanness of the area A in which the substrate cassettes 30 and the first transfer robot 36 are disposed, a partition wall 48 is disposed between the areas A and B. The partition wall 48 is provided with an openable/closable shutter 50 for transfer of a substrate between the areas A and B. A pair of second transfer robots 52 is disposed at such a location that they can reach the cleaning machines 42 and the substrate station 46. Further, a pair of cleaning machines 54 is disposed adjacently to the cleaning machines 42 and within reach of the hand of either one of the second transfer robots 52.

The cleaning machines 42, 54, the substrate station 46 and the second transfer robot 52 are all disposed in the area B, and the ambient air pressure in the area B is adjusted to be lower than that in the area A. The cleaning machine 54 may be one capable of cleaning both sides of a substrate.

The substrate processing apparatus includes a housing (not shown) that surrounds the devices and machines, and the interior of the housing is divided by the partition wall 48 and a pair of partition walls 56 into a plurality of rooms (including the areas A and B). Thus, two areas C and D, constituting two substrate processing rooms, are divided from the area B by the pair of partition walls 56. The interior constructions of the areas C and D are the same, and hence a description will be given hereinbelow only of the area C.

In the area C are disposed a substrate holder (top ring) 60 for detachably holding a substrate, a CMP section 62 for carrying out chemical mechanical polishing of the substrate held by the substrate holder 60, and an electrolytic processing section 64 for carrying out electrolytic processing of the substrate held by the substrate holder 60 by utilizing an ion exchanger as a catalyst. The CMP section 62 includes a rotatable polishing table 68 provided on its surface (upper surface) with a polishing pad 66 of a resin or an abrasive-containing resin and, positioned beside the polishing table 68, a liquid supply nozzle 70 for supplying a liquid (polishing liquid), such as a slurry or a chemical liquid, onto the upper surface of the polishing pad 66, and a dresser 72 for dressing the polishing pad 66. On the other hand, the electrolytic processing section 64 includes a processing table 76 which, according to this embodiment, makes a so-call scroll movement (translational rotation).

The CMP section 62 includes, besides the mechanical dresser 72, an atomizer 78 as a fluid-pressure dresser. An atomizer is designed to jet a mixed fluid of a liquid (e.g. pure water) and a gas (e.g. nitrogen) in the form of a mist from a plurality of nozzles to the polishing surface. The main purpose of the atomizer is to rinse away polished scrapings and slurry particles deposited on and clogging the polishing surface. Cleaning of the polishing surface by the fluid pressure of the atomizer and toothing of the polishing surface by the mechanical contact of the dresser 72 can effect a more desirable dressing, i.e. regeneration of the polishing surface.

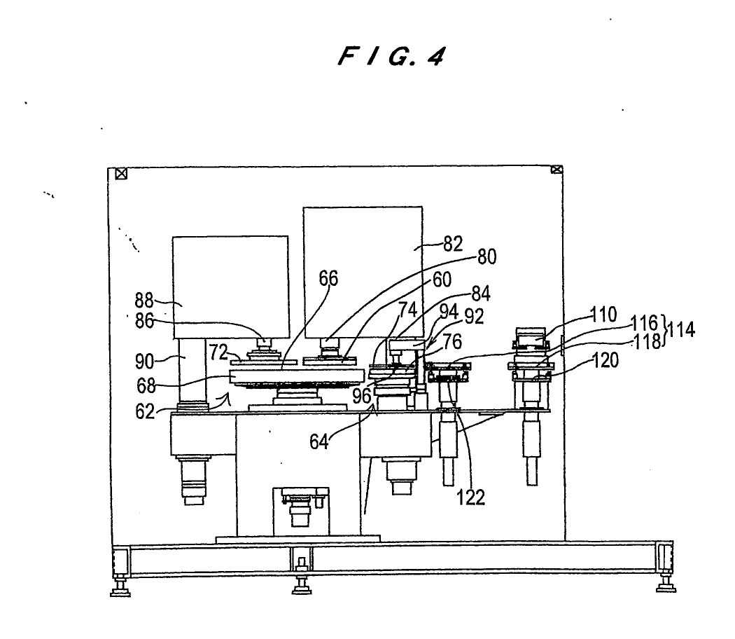

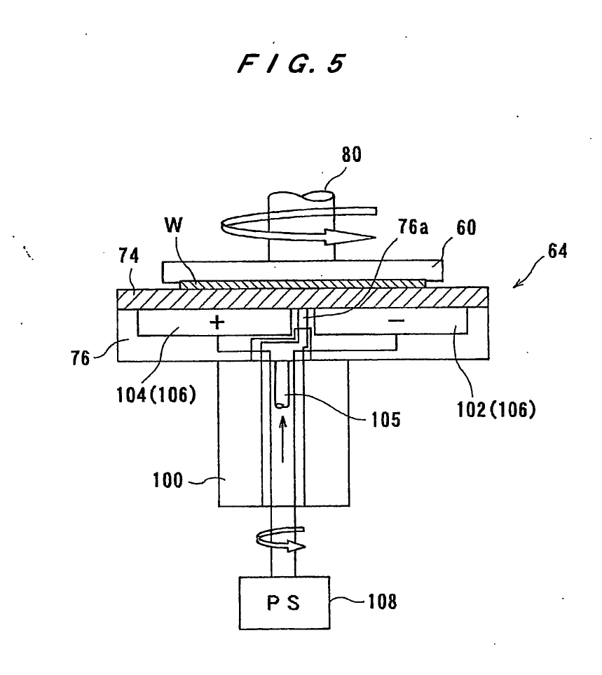

FIG. 4 shows the relationship between the substrate holder 60, the CMP section 62 and the electrolytic processing section 64. As shown in FIG. 4, the substrate holder 60 is suspended from a substrate head 82 by a drive shaft 80 that is rotatable. The substrate head 82 is coupled to the upper end of a pivot shaft 84 which can be angularly positioned, and the substrate holder 60 has access to a polishing table 68 of the CMP section 62 and a processing table 76 of the electrolytic processing section 64. The dresser head 88 is coupled to the upper end of the pivot shaft 90 which can be angularly positioned, and the dresser 72 can move between a standby position and a dressing position above the polishing table 68.

The electrolytic processing section 64 is provided with a regeneration section 92, positioned beside the processing table 76, for regenerating an ion exchanger 74. The regeneration section 92 includes a pivot arm 94 pivotable between a retreat position and a regeneration position above the processing table 76, and a regeneration head 96 held at the free end of the pivot arm 94. The regeneration head 96 has a long shape with its length longer than the diameter of the processing table 76. In regenerating the ion exchanger 74, while applying an electric potential, which is reverse to that employed in electrolytic processing, from a power source 108 (see FIG. 5) to the ion exchanger 74, the regeneration head 96 is pivoted like a windshield wiper, thereby transferring e.g. copper accumulated in the ion exchanger 74 to the regeneration head 96 side and thus regenerating the ion exchanger 74. The regenerated ion exchanger 74 is rinsed with pure water or ultrapure water supplied onto the upper surface of the processing table 76.

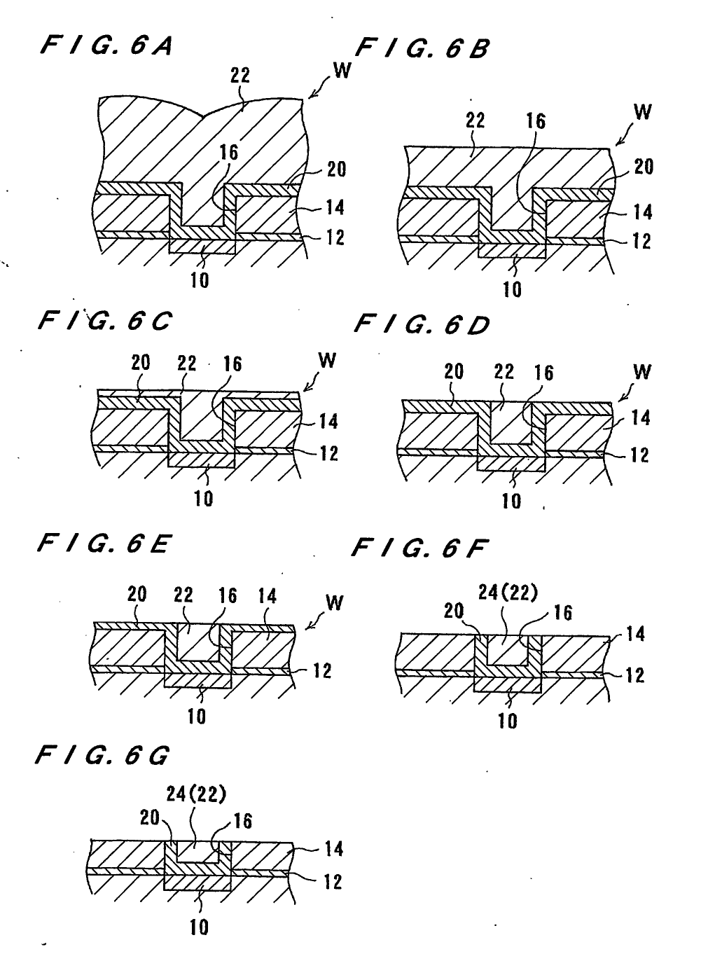

Though not shown diagrammatically, the polishing table 68 of the CMP section 62 is equipped with a film thickness detection sensor for measuring the film thickness of e.g. copper 22 (see FIG. 6A) of a substrate W, held by the substrate holder 60, in an optical method or utilizing an eddy current, or utilizing a combination of such methods.

FIG. 5 shows the details of the electrolytic processing section 64. As shown in FIG. 5, the electrolytic processing section 64 includes the processing table 76 which is directly connected to a hollow motor 100 and, by the actuation of the hollow motor 100, makes a revolutionary movement without rotation about its own axis, a so-called scroll movement (translational rotation). The processing table 76 is made of an insulating material. In the upper surface of the processing table 76 are embedded fan-shaped processing electrodes 102 and feeding electrodes 104 which are arranged alternately at regular intervals along the circumferential direction of the processing table 76. The ion exchanger 74 is disposed over the upper surfaces of the processing electrodes 102 and the feeding electrodes 104. Further, a pure water supply pipe 105 extends from the outside through the hollow motor 100 and communicates with a through-hole 76a which is provided in the center of the processing table 76 and is open to the upper surface of the processing table 76. Thus, pure water, preferably ultrapure water is supplied through the pure water supply pipe 105 and the through-hole 76a to the ion exchanger 74 on the upper surface of the processing table 76.

Pure water herein refers to water having an electric conductivity of e.g. not more than 10 μS/cm (at 1 atom and 25° C.), and ultrapure water refers to water having an electric conductivity of e.g. not more than 0.1 μS/cm. Instead of pure water or preferable ultrapure water, it is possible to use a liquid having an electric conductivity of not more than 500 μS/cm or any electrolytic solution. It is also possible to add an antioxidant (e.g. BTA: benzotriazole) to pure water or ultrapure water. The use of an electrolytic solution or the addition of an antioxidant (e.g. BTA: benzotriazole) in electrolytic processing can obviate processing instability due to processing products, generation of gasses, etc., enabling uniform and well-reproducible processing. BTA forms a thin coating (insoluble complex) on the surface of various metals. According to the electrolytic processing of the present invention, the coating formed can be removed by the scrubbing effect of the ion exchanger 74, whereby an exposed metal surface without an oxide film can be brought into contact with the processing electrodes 102 or the ion exchanger 74 on the processing electrodes 102.

According to this embodiment, a plurality of fan-shaped electrode plates 106 are arranged along the circumferential direction in the upper surface of the processing table 76. The electrode plates 106 are connected alternately to the cathode and to the anode of the power source 108, and the electrode plates 106 connected to the cathode of the power source 108 serve as the processing electrodes 102 and the electrode plates 106 connected to the anode 106 serve as the feeding electrodes 104. In this case, an insulator is interposed between the processing electrode 102 and the feeding electrode 104. This is because electrolytic processing action occurs on the cathode side in the case of e.g. copper. Depending upon the material to be processed, the cathode side may serve as a feeding electrode and the anode side may serves as a processing electrode. In particular, when the material to be processed is, for example, copper, molybdenum or iron, electrolytic processing action occurs on the cathode side. Thus, the electrode plates 106 connected to the cathode of the power source 108 serve as the processing electrodes 102 and the electrode plates 106 connected to the anode serve as the feeding electrodes 104. On the other hand, when the material to be processed is, for example, aluminum or silicon, electrolytic processing action occurs on the anode side. Thus, electrodes connected to the anode of a power source may serve as processing electrodes and electrodes connected to the cathode may serve as feeding electrodes.

The arrangement of electrodes is not limited to the above-described one. A large number of cathodes and anodes may be dotted in an insulator on the processing table 76. It is also possible to feed electricity from the substrate holder to a bevel portion of a substrate and provide only processing electrodes on the upper surface of the processing table 76.

The processing table 76 of the electrolytic processing section 64 is equipped with a film thickness detection sensor 109 (see FIG. 3) for detecting the film thickness of e.g. copper 22 (see FIG. 6A) of a substrate W, held by the substrate holder 60, in an optical method or utilizing an eddy current, or utilizing a combination of such methods.

The ion exchanger 74 may be composed of a nonwoven fabric which has an anion-exchange group or a cation-exchange group. A cation exchanger preferably carries a strongly acidic cation-exchange group (sulfonic acid group); however, a cation exchanger carrying a weakly acidic cation-exchange group (carboxyl group) may also be used. Though an anion exchanger preferably carries a strongly basic anion-exchange group (quaternary ammonium group), an anion exchanger carrying a weakly basic anion-exchange group (tertiary or lower amino group) may also be used.

The nonwoven fabric carrying a strongly basic anion-exchange group can be prepared by, for example, the following method: A polyolefin nonwoven fabric having a fiber diameter of 20-50 μm and a porosity of about 90% is subjected to the so-called radiation graft polymerization, comprising γ-ray irradiation onto the nonwoven fabric and the subsequent graft polymerization, thereby introducing graft chains; and the graft chains thus introduced are then aminated to introduce quaternary ammonium groups thereinto. The capacity of the ion-exchange groups introduced can be determined by the amount of the graft chains introduced. The graft polymerization may be conducted by the use of a monomer such as acrylic acid, styrene, glicidyl methacrylate, sodium styrenesulfonate or chloromethylstyrene, or the like. The amount of the graft polymerization can be controlled with adjusting the monomer concentration, the reaction temperature and the reaction time. Thus, the degree of grafting, i.e. the ratio of the weight of the nonwoven fabric after graft polymerization to the weight of the nonwoven fabric before graft polymerization, can be made 500% at its maximum. Consequently, the capacity of the ion-exchange groups introduced after graft polymerization can be made 5 meq/g at its maximum.

The nonwoven fabric carrying a strongly acidic cation-exchange group can be prepared by the following method: As in the case of the nonwoven fabric carrying a strongly basic anion-exchange group, a polyolefin nonwoven fabric having a fiber diameter of 20-50 μm and a porosity of about 90% is subjected to the so-called radiation graft polymerization comprising γ-ray irradiation onto the nonwoven fabric and the subsequent graft polymerization, thereby introducing graft chains; and the graft chains thus introduced are then treated with a heated sulfuric acid to introduce sulfonic acid groups thereinto. If the graft chains are treated with a heated phosphoric acid, phosphate groups can be introduced. The degree of grafting can reach 500% at its maximum, and the capacity of the ion-exchange groups thus introduced after graft polymerization can reach 5 meq/g at its maximum.

The base material of the ion exchanger 74 may be a polyolefin such as polyethylene or polypropylene, or any other organic polymer. Further, besides the form of a nonwoven fabric, the ion exchanger may be in the form of a woven fabric, a sheet, a porous material, a net, or short fibers, etc.

When polyethylene or polypropylene is used as the base material, graft polymerization can be effected by first irradiating radioactive rays (γ-rays or electron beam) onto the base material (pre-irradiation) to thereby generate a radical, and then reacting the radical with a monomer, whereby uniform graft chains with few impurities can be obtained. When an organic polymer other than polyolefin is used as the base material, on the other hand, radical polymerization can be effected by impregnating the base material with a monomer and irradiating radioactive rays (γ-rays, electron beam or UV-rays) onto the base material (simultaneous irradiation). Though this method fails to provide uniform graft chains, it is applicable to a wide variety of base materials.

By using a nonwoven fabric having an anion-exchange group or a cation-exchange group as the ion exchanger 74, it becomes possible that pure water or ultrapure water, or a liquid such as an electrolytic solution can freely move within the nonwoven fabric and easily arrive at the active points in the nonwoven fabric having a catalytic activity for water dissociation, so that many water molecules are dissociated into hydrogen ions and hydroxide ions. Further, by the movement of pure water or ultrapure water, or a liquid such as an electrolytic solution, the hydroxide ions produced by the water dissociation can be efficiently carried to the surface of the processing electrode 102, whereby a high electric current can be obtained even with a low voltage applied.

As shown in FIG. 3, in the area C divided by the partition wall 56 from the area B, a reversing machine 110 for reversing a substrate is disposed at a location within reach of the hand of the second transfer robot 52. An opening for transfer of a substrate is provided at a position opposite to the reversing machine 110 in the partition wall 56 that divides the area C from the area B. The opening is provided with a shutter 112.

The reversing machine 110 includes a chuck mechanism for chucking a substrate, a reversing mechanism for vertically. reversing the substrate through 180°, and a substrate detection sensor for checking whether the substrate is chucked by the chuck mechanism or not. A substrate is transferred to the reversing machine 110 by the second transfer robot 52.

A linear transporter 114, constituting a transfer robot for transferring a substrate between the reversing machine 110 and the substrate holder 60, is disposed in the area C. The linear transporter 114 includes two stages 116, 118 that reciprocate linearly. Transfer of a substrate between the linear transporter 114 and the substrate holder 60 or the reversing machine 110 is carried out via a substrate tray. on the right side of FIG. 4, the relationship of the linear transporter 114, a lifter 120 and a pusher 122 is shown. As shown in FIG. 4, the lifter 120 and the pusher 122 are disposed below the linear transporter 114, and the reversing machine 110 are disposed above the linear transporter 114.

After positioning one stage 116 above the lifter 120 and positioning the other stage 118 above the pusher 122, the both stages 116, 118 are moved simultaneously and passed by each other so that the stage 116 can be positioned above the pusher 122 and the stage 118 can be positioned above the lifter 120. The substrate holder 60 can be pivoted to a position above the pusher 122 and to a position above the linear transporter 114.

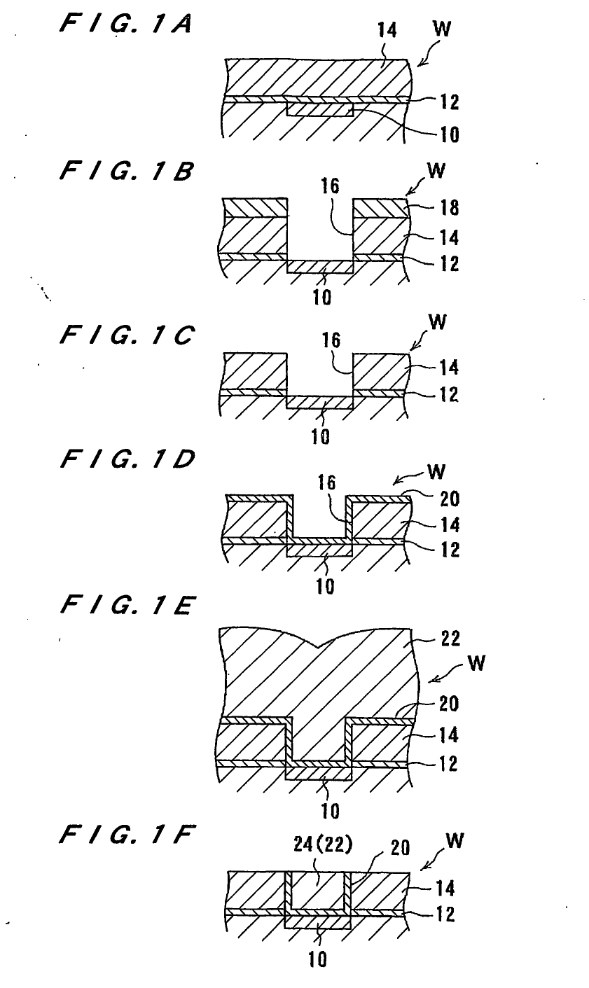

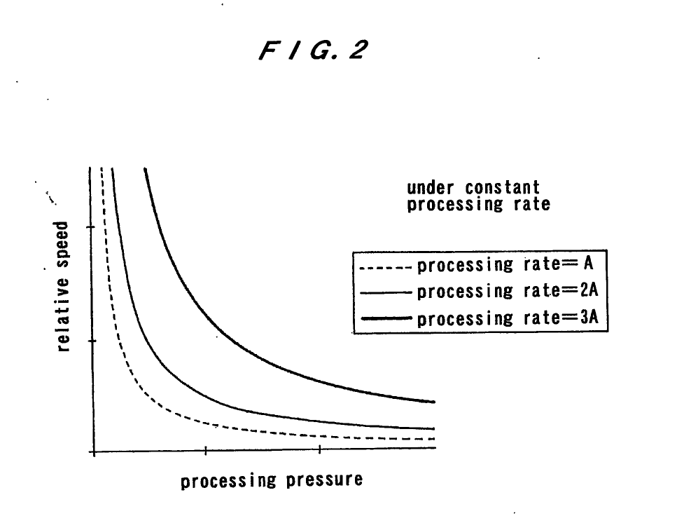

A substrate processing process as carried out by the substrate processing apparatus shown in FIGS. 3 through 5 will now be described by also referring to FIG. 6. In the following process, a substrate W as shown in FIG. 1E and FIG. 6A is prepared by plating the surface with copper to fill interconnect recesses 16 with copper 22 as an interconnect material and deposit copper 22 on the insulating film 14. The copper 22 and the barrier metal 20 on the insulating film 14 are removed so that the surface of copper 22 becomes flush with the surface of the insulating film 14, thereby forming interconnects (copper interconnects) 24 composed of copper 22.

First, a substrate W, having a surface layer of copper 22 as an interconnect material which has been formed in the above-described manner, is taken by the first transfer robot 36 out of the substrate cassette 30, housing substrates W, set in the loading/unloading stage 32. The substrate W is transferred by the first transfer robot 36 onto the substrate stage 44 of the substrate station 46, and the substrate W on the substrate stage 44 is transferred by the second transfer robot 52 to the reversing machine 110, where the substrate W is reversed so that the front surface having the surface layer of copper 22 faces downward. Next, the reversed substrate W is transferred by the second transfer robot 52 to the linear transporter 114. The substrate head 82 is pivoted to move the substrate holder 60 to right above the lifter 120. The lifter 120 is then raised to receive the substrate W from the linear transporter 114. The substrate W received by the lifter 120 is raised so that it is attracted and held by the substrate holder 60.

Next, the substrate head 82 is pivoted to move the substrate holder 60 holding the substrate W to above the processing table 76. Thereafter, the substrate holder 60 is lowered so as to bring the substrate W held by the substrate holder 60 into contact with the ion exchanger 74 on the upper surface of the processing table 76. While rotating the processing table 76 and the substrate holder 60, and supplying pure water, preferably ultrapure water to the ion exchanger 74 on the processing table 76, a voltage is applied between the processing electrodes 102 and the feeding electrodes 104, thereby carrying out electrolytic processing (first step) of the surface (lower surface) of the substrate.

Electrolytic processing of copper 22 of the substrate W is effected by hydrogen ions or hydroxide ions produced by the ion exchanger 74. By allowing pure water, preferably ultrapure water to flow within the ion exchanger 74, a large amount of hydrogen ions or hydroxide ions are generated, and the ions are supplied to the surface of the substrate W, whereby the electrolytic processing can be carried out efficiently.

According to this electrolytic processing method, when pure water is used as a processing liquid, pure water is present also within recesses in the substrate surface. Since pure water itself is little ionized, removal processing of the substrate does not substantially progress at the recess portions in contact with pure water. Thus, removal processing progresses only at those portions which are in contact with the ion exchanger which is abundant in ions. This electrolytic processing method has the advantage of superior flattening performance over an electrolytic processing method that uses a common electrolytic solution.

It is preferred to use as the upper ion exchanger 74 one having an excellent water permeability. By permitting pure water, preferably ultrapure water to flow through the ion exchanger 74, a sufficient amount of water can be supplied to a functional group (sulfonic acid group in the case of a strongly acidic cation-exchange material) to thereby increase the amount of dissociated water molecules, and the processing products (including gasses) formed by the reaction between the to-be-processed material and hydroxide ions (or OH radicals) can be removed by the flow of water, whereby the processing efficiency can be enhanced. The flow of pure water, preferably ultrapure water is therefore necessary, and the flow should desirably be constant and uniform. The constancy and uniformity of the flow leads to constancy and uniformity in the supply of ions and the removal of the processing products, thus leading to constancy and uniformity in the processing efficiency.

During the electrolytic processing, the voltage or electric current applied between the processing electrodes 102 and the feeding electrodes 104 is controlled so as to optimize the processing rate. Further, the quantity of electricity is determined by the product of the electric current and the processing time, and the electrolytic processing as the first step is terminated when the quantity of electricity has reached a predetermined value. It is also possible to measure the film thickness of copper 22 with the film thickness detection sensor 109 equipped in the processing table 76, and terminate the electrolytic processing as the first step when the measured film thickness has reached a predetermined value.

The electrolytic processing as the first step is carried out to process and remove the surface of copper 22 having a level difference as shown in FIG. 6A, thereby flattening the surface of copper 22, as shown in FIG. 6B. Thus, the electrolytic processing selectively or preferentially processes and removes only raised portions of the irregular surface of copper 22, thereby eliminating the level difference in the copper surface. Accordingly, it is preferred to use as the ion exchanger 74, which is to make contact with a substrate W, a hard ion exchanger in order to reduce the influence of elastic deformation of the ion exchanger 74. A hard ion exchanger 74, though excellent in the ability to eliminate the level difference, is likely cause physical or chemical damage to the processed surface of a substrate after processing. Thus, though elimination of the level difference is possible, a high-quality processed surface without damage is difficult to obtain. However, if the damage to the surface of copper 22 is small distortion, cracks, scratches, etc. (surface defects), such defects can be removed in the later process steps. It is therefore desirable that the level difference elimination step be carried out in an early stage, especially at the initial stage, i.e. as the first step, of the combination of the process steps according to the present invention. This broadens the range of choices of processing methods for the later process steps, enabling a choice of processing method on account not only of the performance of processing, but also of the cost and throughput.

The first step (level difference elimination step) may also be carried out by cutting or grinding or by a CMP method. In the case of CMP method, with commonly-used high pressing force (5-7 psi) and low relative movement speed (0.1-0.4 m/sec), a distortion will be produced by elastic deformation in the processing surface of a tool, and elimination of a level difference in a surface of a substrate can be effected with difficulty. On the other hand, elimination of a level difference can be effected by carrying out the processing with a tool having a high Young's modulus or under the conditions of low pressure (about 0.1-3 psi) and high relative movement speed (0.5-10 m/sec).

The first step may also be carried out by a composite electrolytic processing (polishing) method which comprises a chelate film formation step of oxidizing the surface of copper and forming a chelate film (passivated film) of the oxidized copper and a chelate film removal step of selectively scrub removing raised portions of the chelate film, corresponding to raised portions of the irregularities of copper, thereby exposing copper at the raised portions, and carries out the chelate film formation step and the chelate film removal step repeatedly until the raised portions of copper are flattened. While the processing principle is similar to CMP, according to the composite processing method, the surface oxidation of copper can be assisted with an electrical force, the processing surface of a substrate can be covered with a mechanically weak oxide film, and only the processing surface in contact with a tool can be processed. The composite electrolytic processing method can, therefore, be used to eliminate a level difference in the surface of a substrate. Further, since the thickness of the oxide film can be controlled, a fast flattening speed can be achieved. Moreover, by controlling the processing pressure between a tool and a substrate within the range of from 0.1 to 3 psi, a defect-free processing becomes possible.

In the case of composite electrolytic processing, an apparatus similar to the above-described apparatus shown in FIG. 5 may be used, but instead of the ion exchanger 74, a liquid-permeable polishing pad or the like may be mounted on the processing table 76. It is possible to use an electrolytic solution containing abrasive grains, or to supply slurry separately from an electrolytic solution in order to enhance the mechanical action.

Next, the substrate W held by the substrate holder 60 is brought into contact with the ion exchanger 74 of the processing table 76 in the above-described manner. While rotating the processing table 76 and the substrate holder 60, and supplying pure water, preferably ultrapure water to the ion exchanger 74 on the upper surface of the processing table 76, a voltage is applied between the processing electrodes 102 and the feeding electrodes 104, thereby carrying out electrolytic processing (second step) of the surface (lower surface) of the substrate. The electrolytic processing of the second step is thus carried out in the same manner as the electrolytic processing of the first step, but the processing conditions are changed to increase the processing rate, thereby increasing the throughput.

The electrolytic processing as the second step is carried out to uniformly process and remove the flattened surface of copper 22 as shown in FIG. 6B, and remove copper 22 until the copper 22 becomes a thin film with a thickness of e.g. several nm to several hundred nm or remains partly on the barrier metal 20 in the non-interconnect region, as shown in FIG. 6C. The film thickness of copper 22 may be measured by the optical or eddy-current film thickness detection sensor 109, and this step may be terminated when the measured film thickness has reached a predetermined value. It is desirable to use for the second step a processing method that can effect uniform removal processing of copper 22 and, when the deposition amount of copper 22 is large, can effect processing at a high rate.

The second process step is terminated before the barrier metal 20 appears in the processing surface. Accordingly, processing can be effected with a considerably simplified processing system, and a high-quality processing is feasible. Since the barrier metal 20 is not exposed, besides the above-described electrolytic processing, a processing method utilizing an electric force, such as composite electrolytic processing, or a processing method such as a common electrolytic etching can effect stable and highly uniform processing.

In the case of carrying out the second step by CMP, it has been proposed generally to carry out this step of processing in the same step as level difference elimination. However, by making this step of processing independent of the level difference elimination step (first step) and specializing it as a step of uniformly processing the flattened surface of interconnect material until the interconnect material becomes a thin film, it becomes possible to carry out processing at a high processing rate and under processing conditions which are advantageous to uniform processing. In case that the above-described step (first step) and this step (second step) are carried out with the same processing tool, it is desirable to carry out this step (second step) at a higher processing pressure or with a higher relative movement speed than the first step so as to effect the additional processing after the flattening at a high rate.

As described above, the composite electrolytic processing is a processing method which involves the anodic oxidation and chelating of the surface of interconnect material by electrolysis in combination with scrub polishing of the surface by contact with a contact member. The processing may be carried out, for example, by supplying a slurry including an electrolytic solution or a chemical liquid including an electrolytic solution between a substrate and a polishing pad, and scrubbing the substrate surface with the polishing pad while applying an electric field between the substrate and the processing surface of the polishing pad. In contrast to a conventional physical processing method, a processing method that effects physical processing utilizing an electric force or electrochemical processing, such as chemical polishing, electrolytic processing, composite electrolytic processing or electrolytic polishing, causes a chemical dissolution reaction to take place so that removal processing can be effected with a very weak physical force. Accordingly, formation of defects, such as an affected layer and displacement due to plastic deformation, can be prevented, and processing can be carried out without impairing the properties of the material being processed. Further, a processing method utilizing an electric force, in addition to its easy control of processing rate, enables a high-speed processing.

It is possible to employ the electrolytic processing method, which uses pure water, preferably ultrapure water and which is excellent in elimination of the level difference and free from contamination, also in this step (second step), and carry out the level difference elimination step (first step) and this step (second step) continuously under the same conditions, thereby increasing the throughput.

It is also possible to carry out the second step with a common electrolytic processing. A common electrolytic processing can provide a high-quality processed surface free from physical defects and can effect a high-speed uniform processing. Chemical etching is also usable. Chemical etching is isotropic and, in principle, is a fast processing, and therefore is an effective processing method for the second step. Etching that utilizes a high relative speed of a slurry or chemical liquid (oxidizing agent such as H₂O₂ or preservative such as BTA), which is advantageous to flattening, is also effective. For example, using a similar apparatus to a spin coater that is used in other process, a slurry or chemical liquid maybe jetted toward a substrate almost parallel to the processing surface of the substrate. Alternatively, a substrate may be disposed in a bath, which is capable of flowing a slurry or chemical liquid at a high speed, such that the processing surface of the substrate is parallel to the flow of the slurry or chemical liquid. This processing method can be used also in the level difference elimination step (first step).

There are cases where the isotropy cannot be maintained only with chemical etching, as in the case where the conductive material has a grain boundary. In such a case, dry etching such as RIE may also be employed.

The second step may be terminated when the film thickness of copper 22 in the non-interconnect region has reached a value of e.g. not more than 300 nm. Electrolytic processing, when carried out in the second step, could cause formation of pits. In an exaggerate consideration of the maximum pit depth by way of precaution, the second step may be terminated when the film thickness of copper 22 has reached a value of not more than 400 nm. However, in order to take advantage of the high-speed polishing of electrolytic processing, it is generally preferred to continue electrolytic processing (second step) until the film thickness reaches a value of not more than 300 nm or 200 nm, preferably not more than 100 nm, more preferably not more than 50 nm.

After completion of the electrolytic processing (first and second steps), the power source is disconnected, the substrate holder 60 is raised, and the rotations of the processing table 76 and of the substrate holder 60 are stopped.

Next, the substrate head 82 is pivoted to move the substrate holder 60 holding the substrate W to right above the polishing table 68. Thereafter, the substrate holder 60 is lowered so as to press the substrate W, held by the substrate holder 60, against the polishing pad 66 of the polishing table 68 at a predetermined pressure. While rotating the polishing table 68 and the substrate holder 60, a liquid (polishing liquid) is supplied from the liquid supply nozzle 70 to the polishing pad 66, thereby carrying out a first CMP (chemical mechanical polishing), as a third step, of the surface (lower surface) of the substrate W.

The third step is carried out to remove copper 22 which, as shown in FIG. 6C, is in the form of a thin film or remaining partly on the barrier metal 20, thereby exposing the barrier metal 20, or further process the barrier metal 20, as shown in FIG. 6D. The processing may be terminated based on a signal from the film thickness detection sensor provided in the processing table 68 and/or by time management. As with the step of processing copper 22 into a thin film (second step), the third step processes only copper 22. On the other hand, the barrier metal 20 becomes exposed at the end of processing in this step. Accordingly, it is necessary to properly determine the end point of processing and, in addition, make the processing selectivity ratio between copper 22 and barrier metal 20 nearly 1. The processing amount is very small, several nm to several tens nm, and therefore a high processing speed (rate) is not required. Instead, since the barrier metal 20 becomes exposed, adjustment of the selectivity ratio is needed and processing that does not cause a large damage to the surfaces of copper 22 and barrier metal 20 is required.

Accordingly, when the third step is carried out by CMP as in this embodiment, delicate processing is carried out using a low polishing rate and applying a low pressing force from the substrate W to the polishing pad 66. Further, the processing environment and processing conditions are so adjusted as to make the processing rates of copper 22 and barrier metal 20 almost equal (selectivity ratio is nearly 1).

In this connection, copper as an interconnect material, due to the presence of a crystal grain boundary, has a processing anisotropy. Accordingly, flat processing of copper 22 is difficult with a common CMP method. Further, adjustments are necessary to prevent formation of defects. On the other hand, flat processing of copper 22 can be effected by using a polishing pad 66 (tool) of high Young's modules, such as a fixed-abrasive pad, and suppressing the elastic deformation. In carrying, out such processing, attention should also be paid to prevention of defects and, for this purpose, it is desirable to carry out the processing at a low pressure. Though depending upon the processing object material, the device structure, etc., it is desirable to use a processing pressure of about 0.1 to 3 psi, which is lower than the pressure of 5 to 7 psi generally used in a common CMP. Further, it is desirable to use a lower processing pressure than the processing pressure used in the second step.

It is also possible to use a special processing method which little processes the barrier metal 20 and can stop processing of copper 22 immediately after the barrier metal 20 becomes exposed. In particular, a highly chemically adjusted CMP or an (pure water) electrolytic processing method utilizing a catalyst can be employed. When an etchable material, other than copper, is used as an interconnect material, a processing method not involving contact between the interconnect material and a tool, such as electrolytic processing, dry etching or chemical etching, may also be employed.

Further to the third step, it is important for maintaining the flatness of the processed surface to detect the full exposure of the different material, the barrier metal 20, so as to terminate the processing. When the interconnect material is copper, an eddy-current film thickness detection sensor may be used as an end point detection device. When the transmissivity, refractive index and reflectivity of light differ between the interconnect material and the barrier material, an optical film thickness detection sensor (optical sensor) may also be used as an end point detection device. The use of an optical sensor (end point detector) that can detect the difference in reflectivity is practically desirable.

Though various electrolytic processing methods may be employed for processing the third step, in view of the fact that copper decreases gradually, a processing method involving mechanical polishing using abrasive grains is more suited.

After completion of the third step, as necessary, pure water or water is supplied onto the polishing table 68 to carry out water polishing for removal of foreign matter at a lowered pressure on the substrate.

Next, as with the third step, while rotating the polishing table 68 and the substrate holder 60, and pressing the substrate W held by the substrate holder 60 against the polishing pad 66 of the polishing table 68 at a predetermined pressure, a liquid (polishing liquid) is supplied from the liquid supply nozzle 70 to the polishing pad 66, thereby carrying out a second CMP (chemical mechanical polishing), as a fourth step, of the surface (lower surface) of the substrate W.

The fourth step is carried out to simultaneously polish the barrier metal 20 exposed on the substrate and copper 22 present in the interconnect region as shown in FIG. 6D so as to simultaneously remove the barrier metal 20 and copper 22 until the barrier metal 20 in the non-interconnect region becomes a thin film, as shown in FIG. 6E. The film thickness of the barrier metal 20 is measured with the film thickness detection sensor provided in the polishing table 68, and the processing is terminated when the measured film thickness has reached a predetermined value. The fourth step removes copper 22 in the interconnect region and also simultaneously removes the barrier metal 20 deposited (in the form of a film) such that it covers the surfaces of interconnect trenches and via holes. Thus, the two different materials (interconnect material and barrier material) are always processed simultaneously. This process step necessitates a processing method and processing conditions that more securely prevent formation of defects than the preceding steps. Further, in order to simultaneously process the different materials (interconnect material and barrier material), while maintaining the surface flatness obtained in the preceding steps, highly controlled processing conditions are needed in a chemical or electrochemical processing method.

When the barrier material is an electrically conductive material (barrier metal) as in this embodiment, such processing conditions are necessary that adjust the processing rate ratio (selectivity ratio) between the electrically conductive material as the interconnect material and the electrically conductive material as the barrier metal to nearly 1. This requirement can be met by carrying out electrochemical processing while supplying an electrolytic solution (containing an oxidizing agent such as H₂O₂ or a preservative such as BTA) or chemical liquid that is chemically adjusted to meet the condition. Though dependent upon the processing time of this step and the processing accuracy of the next step, it is desirable that the selectivity ratio (the processing rate ratio of the interconnect material to the barrier metal) be adjusted to about 0.25 to 4.0, preferably about 0.5 to 2.0.

The fourth step processing can also be effected by employing CMP, such as fixed-abrasive CMP or CMP with a below-described abrasive-free chemical liquid, which is carried out, under chemical conditions (addition of an oxidizing agent such as H₂O₂ or a preservative such as BTA to a polishing liquid) with which the selectivity ratio is adjusted to nearly 1 or under the conditions of low processing pressure and high relative movement speed, by supplying a slurry or chemical liquid onto a polishing pad of a resin or an abrasive-containing resin while pressing the substrate W against the polishing pad 66.

With a CMP method that utilizes mechanical processing or a composite electrolytic processing method, it is possible to adjust the selectivity ratio by utilizing a high-speed relative movement and effect processing with few defects at a low processing pressure. The fourth step may also be carried out with an (pure water) electrolytic processing utilizing a catalyst. According to this method, the contact portion can be processed preferentially, which makes it possible to process the materials while maintaining the surface flatness.

Even when the barrier material is an insulating material, chemical mechanical processing (CMP) can be employed for carrying out the fourth step. Thus, as described above, it is possible to employ a CMP, such as fixed-abrasive CMP or CMP with an abrasive-free chemical liquid, which carries out the processing of a substrate by supplying a slurry or chemical liquid onto a polishing pad of e.g. a resin or an abrasive-containing resin while pressing the substrate against the polishing pad.

Provided that the selectivity ratio is chemically adjustable, the fourth step can be carried out with chemical etching. Etching utilizing a high relative speed of a slurry or chemical liquid, which is advantageous to flattening, may also be employed.

Further, when the barrier material is of a material hard to process, processing of the interconnect material and processing of the barrier material may be carried out independently. In that case, it is possible to mask the interconnect material with a photo resist and process the barrier material by dry etching.

After completion of the fourth step, as necessary, water is supplied onto the polishing table 68 to carry out water polishing for removal of foreign matter at a low pressure.

Next, as with the third and fourth steps, while rotating the polishing table 68 and the substrate holder 60, and pressing the substrate W held by the substrate holder 60 against the polishing pad 66 of the polishing table 68 at a predetermined pressure, a liquid (polishing liquid) is supplied from the liquid supply nozzle 70 to the polishing pad 66, thereby carrying out CMP (chemical mechanical polishing) which is the same as the third step, as a fifth step, of the surface (lower surface) of the substrate W.

The fifth step is carried out to simultaneously remove copper 22 and the barrier metal 2 0 which has become a thin film as shown in FIG. 6E, thereby exposing the insulating film 14 present in the non-interconnect region or further processing the insulating film 14, as shown in FIG. 6F. The processing may be terminated, for example, based on a signal from the film thickness detection sensor provided in the polishing table 68 and by time management. As with the above-described fourth step of removing copper 22 and the barrier metal 20 and making the barrier metal 20 into a thin film, the fifth step processes the two materials. On the other hand, the insulating film 14 becomes exposed at the end of this step. It is therefore necessary to properly determine the end point of processing and carry out processing with the processing selectivity ratio between copper 22, the barrier metal 20 and the insulating film 14 nearly 1:1:1. The processing amount of this step is very small, several nm to several tens nm, and therefore a high processing rate (speed) is not required. Instead, since the different material, the insulating film 14, becomes exposed, adjustment of the selectivity ratio is needed and processing that does not cause even a small damage to the surfaces of copper 22, the barrier metal 20 and the insulating film 14 is required.

It is therefore desirable to select a processing method involving a mechanical action that is excellent in flattening and causes few defects. In the case of a processing method involving a mechanical action, the insulating film 14 is inevitably processed upon its exposure. In carrying out this step, therefore, the processing environment and processing conditions should be adjusted so that the processing rates of copper 22, barrier metal 20 and insulating film 14 become almost equal (selectivity ratio is nearly 1:1:1).

Since the depth to the processing end surface is as small as several nm, attention should also be paid to prevention of defects particularly and, therefore, processing should desirably be carried out at a low processing pressure. In this regard, the fifth step is a finishing processing step. Further, when a ULK (ultra low-k) material is used as the insulating film 14, the ULK becomes exposed at the end of processing. Accordingly, the fifth step, when carried out by fixed-abrasive CMP as in this embodiment, is required to be carried out most delicately at the lowest pressure of all the process steps. Though depending upon the processing object material, the device structure of the substrate, etc., a desirable processing pressure in the fifth step by CMP is 0.1 to 3 psi, which is lower than the pressure of 5 to 7 psi generally used in common CMP, and more preferably not more that 1 psi, further lower than the processing pressure in the fourth step. Further, it is preferred to make the relative speed between the substrate W and the polishing pad 66 higher than the fourth step. It is also possible to carry out hydroplaning polishing by the liquid between the substrate W and the polishing pad 66 at a further lowered pressure.

It is also possible to use a special processing method which little processes the insulating film 14 and can stop processing of copper 22 and the barrier metal 20 immediately after the insulating film 14 becomes exposed. In particular, a highly chemically adjusted CMP or an (pure water) electrolytic processing method utilizing a catalyst can be employed. A processing method not involving contact between the materials and a tool, such as electrolytic processing, dry etching or chemical etching, may also be employed.

It is important for maintaining the flatness of the processed surface to detect the full exposure of the insulating film 14 so as to terminate the processing. When the interconnect material is copper, an eddy-current film thickness detection sensor may be used as an end point detection device. When the reflectivity of light differs between the barrier material and the insulating material, an optical sensor may also be used as an end point detection device.

As the technology node becomes smaller, a barrier material will become thinner. It is considered, therefore, that in the future this step (fifth step) may possibly to be carried out under the same processing conditions as the steps before and/or after this step. That is, the fourth and fifth steps may possibly be carried out not as separate steps, but as a combined step. Such a combined step could nevertheless effect processing without impairing the surface flatness.

After completion of the fifth step, as necessary, water is supplied onto the polishing table 68 to carry out water polishing for removal of foreign matter at a lowered pressure on the substrate.

Next, according to necessity and as with the third to fifth steps, while rotating the polishing table 68 and the substrate holder 60, and pressing the substrate W held by the substrate holder 60 against the polishing pad 66 of the polishing table 68 at a predetermined pressure, a liquid (polishing liquid) is supplied from the liquid supply nozzle 70 to the polishing pad 66, thereby carrying out CMP (chemical mechanical polishing) which is the same as the fourth step, as a sixth step, of the surface (lower surface) of the substrate W.

The sixth step is carried out to further polish the surface of the substrate W on which the insulating film 14 is exposed as shown in 6F, effecting processing of copper 22, the barrier metal 20 and the insulating film 14 as shown in FIG. 6G. Such processing of this step can be effected by so adjusting the processing environment and processing conditions as to make the processing rates of copper 22, the barrier metal 20 and the insulating film 14 almost equal (selectivity ratio is nearly 1:1:1). The processing may be terminated, for example, based on a signal from the film thickness detection sensor provided in the polishing table 68 and by time management. Processing of the interconnect region and the insulating region is completed in the sixth step and the processed surface after processing directly affects the device performance. This step is therefore important for suppressing or reducing defects and ensuring the surface flatness. The sixth step is optional and carried out according to necessity, and is directed to removal of defects formed in the preceding steps. It is therefore desirable to select a processing method that does not produce defects.

The processing objects in the sixth step include the insulating film (insulating material) 14, which is required to be electrochemically stable. Accordingly, preferred processing methods for this step include a CMP, such as fixed-abrasive CMP or CMP with an abrasive-free chemical liquid, which is carried out by supplying a slurry or chemical liquid onto a polishing pad of a resin (particle) or an abrasive-containing resin while pressing a substrate against the polishing pad, and dry etching or chemical etching. A processing method involving a weak physical action is more preferred. A defect-free processing can be effected by operating at a low pressure, for example, not more than 3 psi.

In the case of CMP, for example, a defect-free processing can be effected by using a slurry containing special abrasive grains, such as very fine abrasive grains, resin particles, composite abrasive grains with resin particles or a surfactant as nuclei, and composite particles comprising abrasive grains and a protective coating of a surfactant or a polymer, which can carry out processing only with the abrasive grain portion which has protruded out of the protective coating by application of a pressing force. A defect-free processing can also be effected by carrying out special chemical adjustments, such as surface modification by light (a photo-catalyst may also be used) comprising softening or weakening of the surface of the insulating material with a chemical, followed by processing of the modified portion.

After completion of the sixth step, as necessary, water is supplied onto the polishing table 68 to carry out water polishing for removal of foreign matter at a low pressure.

Next, the substrate holder 60 is raised, the rotations of the polishing table 68 and the substrate holder 60 are stopped, and the supply of liquid is stopped, thereby terminating the chemical mechanical polishing.

After completion of the polishing, the substrate head 82 is pivoted to transfer the substrate W to the linear transporter 114 via the pusher 122. The second transfer robot 52 receives the substrate W from the linear transporter 114 and, according to necessity, transfers the substrate W to the reversing machine 110 where the substrate is reversed, and transfers the substrate W to the cleaning machine 54 for primary cleaning and then to the cleaning machine 42 for finish cleaning and spin drying. Thereafter, the dried substrate is returned by the first transfer robot 36 to the substrate cassette 30 on the loading/unloading stage 32.

According to this embodiment, pure water, preferably ultrapure water is supplied to the electrolytic processing section 64. Carrying out electrolytic processing using pure water, preferably ultrapure water, not containing an electrolyte, can avoid impurities such as an electrolyte adhering to and remaining on the surface of the substrate W. Further, copper ions, etc. which have been dissolved by electrolysis are instantly captured by the ion exchanger 74 through ion exchange reaction. This prevents dissolved copper ions, etc. from re-depositing on the other portion of the substrate W or being oxidized to become fine particles which could contaminate the surface of the substrate W.

Ultrapure water has a high resistivity, and therefore an electric current is hard to flow therethrough. A lowering of the electric resistance is made by making the distance between an electrode and a processing object as small as possible, or by interposing an ion exchanger between the electrode and the processing object. Further, an electrolytic solution, when used in combination with ultrapure water, can further lower the electric resistance and reduce the power consumption. When electrolytic processing is carried out by using an electrolytic solution, a processing object can be processed over a slightly wider area than the area of the processing electrode. In the case of the combined use of ultrapure water and an ion exchanger, on the other hand, since almost no electric current flows through ultrapure water, electric processing is effected only within the area of a processing object that is equal to the area of the processing electrode and the ion exchanger.

It is possible to use, instead of pure water or ultrapure water, an electrolytic solution obtained by adding an electrolyte to pure water or ultrapure water. The use of such an electrolytic solution can further lower the electric resistance and reduce the power consumption. Further, the removal processing rate of processing object can be increased. A solution of a neutral salt such as NaCl or Na₂SO₄, a solution of an acid such as HCl or H₂SO₄, or a solution of an alkali such as ammonia, may be used as the electrolytic solution, and these solutions may be selectively used depending on the properties of the processing object.

Further, it is also possible to use, instead of pure water or ultrapure water, a liquid obtained by adding a surfactant to pure water or ultrapure water, and having an electric conductivity of not more than 500 μS/cm, preferably not more than 50 μS/cm, more preferably not more than 0.1 μS/cm (resistivity of not less than 10 MΩ.cm). Due to the presence of a surfactant, the liquid can form a layer, which functions to inhibit ion migration evenly, at the interface between the substrate W and the ion exchanger 74, thereby moderating concentration of ion exchange (metal dissolution) to enhance the flatness of the processed surface. The surfactant concentration is desirably not more than 100 ppm. When the electric conductivity is too high, the current efficiency is lowered and the processing rate is decreased. The use of a liquid having an electric conductivity of not more than 500 μS/cm, preferably not more than 50 μS/cm, more preferably not more than 0.1 μS/cm, can achieve the desired processing rate.

The processing rate can be considerably enhanced by interposing the ion exchanger 74 between the substrate W and the processing and feeding electrodes 102, 104 in the electrolytic processing section 64. In this regard, electrochemical processing using ultrapure water is effected by a chemical interaction between hydroxide ions in ultrapure water and a material to be processed. However, the amount of the reactant hydroxide ions in ultrapure water is as small as 10⁻⁷ mol/L under normal temperature and pressure conditions, so that the removal processing efficiency can decrease due to reactions (such as an oxide film-forming reaction) other than the reaction for removal processing. It is therefore necessary to increase hydroxide ions in order to carry out removal processing efficiently. A method for increasing hydroxide ions includes a method which promotes the dissociation reaction of ultrapure water by a catalytic material, and an ion exchanger can be effectively used as such a catalytic material. More specifically, the activation energy relating to water-molecule dissociation reaction is lowered by the interaction between functional groups in an ion exchanger and water molecules, whereby the dissociation of water is promoted to thereby enhance the processing rate.

When electrolytic processing of copper is carried out by using, as the ion exchanger 74, an ion exchanger having a cation-exchange group, for example, the ion-exchange group of the ion exchanger (cation exchanger) 74 is saturated with copper after the processing, whereby the processing efficiency of the next processing is lowered. When electrolytic processing of copper is carried out by using, as the ion. exchange 74, an ion exchanger having an anion-exchange group, fine particles of copper oxide can be produced and adhere to the surface of the ion exchanger (anion exchanger) 74, whereby particles can contaminate the surface of a next substrate.

When the ion exchanger 74 is contaminated with copper, etc., the regeneration head 96 mounted to the pivot arm 94 is brought closed to or into contact with the ion exchanger 74, and a reverse potential to that in electrolytic processing is applied from the power source 108 to the ion exchanger 74 to promote dissolution of copper, etc. adhering to the ion exchanger 74, thereby regenerating the ion exchanger 74 during processing. The regenerated ion exchanger 74 is rinsed with pure water or ultrapure water supplied onto the upper surface of the processing table 76.

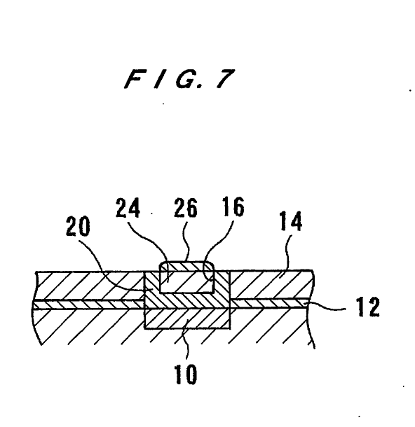

According to this embodiment, after completion of the sixth step, the substrate W is cleaned and dried, and is then returned to the substrate cassette 30. It is, however, also possible to replace at least one of the pair of cleaning machines 42 or of the pair of cleaning machines 54 with an electroless plating apparatus and, by using the electroless plating apparatus, selectively form a protective film 26 of Co alloy, Ni alloy, or the like, on the exposed surface of the interconnects 24 to protect the surface of interconnects 24 with the protective film 26, as shown in FIG. 7. Thus, immediately after exposure of interconnects 24 by CMP or the like and the subsequent cleaning of the substrate surface, the exposed surface of interconnects 24 may be covered and protected with the protective film 26, whereby corrosion of the copper interconnects can be prevented. After the interconnect region is covered with the protective film 26, the substrate is cleaned and dried by a cleaning machine, and is then returned to the cassette 30.

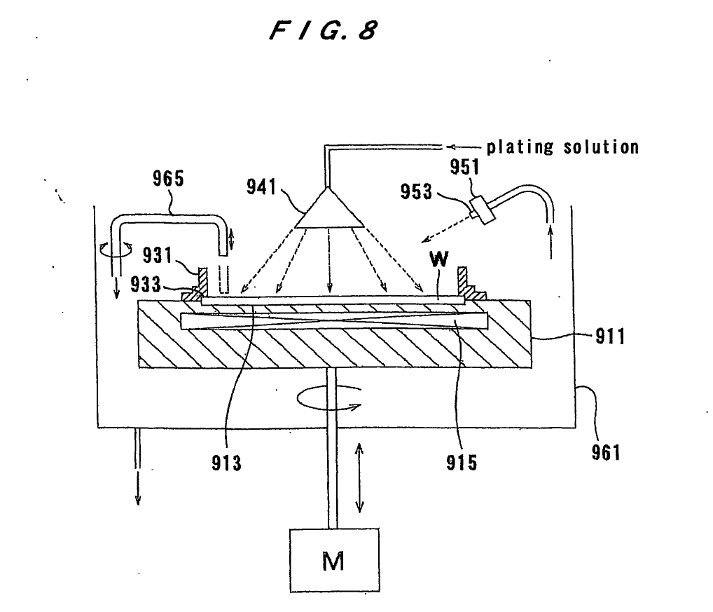

FIG. 8 shows an example of an electroless plating apparatus. The electroless plating apparatus comprises holding means 911 for holding a substrate W on its upper surface, a dam member 931 for contacting a peripheral edge portion of a surface to be plated (upper surface) of the substrate W held by the holding means 911 to seal the peripheral edge portion, and a shower head 941 for supplying a plating solution to the surface, to be plated, of the substrate W having the peripheral edge portion sealed with the dam member 931. The electroless plating apparatus further comprises cleaning liquid supply means 951 disposed near an upper outer periphery of the holding means 911 for supplying a cleaning liquid to the surface, to be plated, of the substrate W, a recovery vessel 961 for recovering a cleaning liquid or the like (plating waste liquid) discharged, a plating solution recovery nozzle 965 for sucking in and recovering the plating solution held on the substrate W, and a motor M for rotationally driving the holding means 911.

The holding means 911 has a substrate placing portion 913 on its upper surface for placing and holding the substrate W. The substrate placing portion 913 is adapted to place and fix the substrate W. Specifically, the substrate placing portion 913 has a vacuum attracting mechanism (not shown) for attracting the substrate W to a backside thereof by vacuum suction. A backside heater 915, which is planar and heats the surface, to be plated, of the substrate W from underside to keep it warm, is installed on the backside of the substrate placing portion 913. The backside heater 915 is composed of, for example, a rubber heater. This holding means 911 is adapted to be rotated by the motor M and is movable vertically by raising and lowering means (not shown).

The dam member 931 is tubular, has seal portion 933 provided at a lower portion thereof for sealing the outer peripheral edge of the substrate W, and is installed so as not to move vertically from the illustrated position.

The shower head 941 is of a structure having many nozzles provided at the front end for scattering the supplied plating solution in a shower form and supplying it substantially uniformly to the surface, to be plated, of the substrate W. The cleaning liquid supply means 951 has a structure for ejecting a cleaning liquid from a nozzle 953. The plating solution recovery nozzle 965 is adapted to be movable vertically and swingable, and the front end of the plating solution recovery nozzle 965 is adapted to be lowered inwardly of the dam member 931 located on the upper surface peripheral edge portion of the substrate W and to suck in the plating solution on the substrate W.

Next, the operation of the electroless plating apparatus will be described. First, the holding means 911 is lowered from the illustrated position to form a gap of a predetermined dimension between the holding means 911 and the dam member 931, and the substrate W is placed on and fixed to the substrate placing portion 913.

Then, the holding means 911 is raised to bring its upper surface into contact with the lower surface of the dam member 931 as illustrated, and the outer periphery of the substrate W is sealed with the seal portion 933 of the dam member 931. At this time, the surface of the substrate W is in an open state.

Then, the plating solution heated, for example, to 50° C. is ejected from the shower head 941 to pour the plating solution over substantially the entire surface of the substrate W. Since the surface of the substrate W is surrounded with the dam member 931, the poured plating solution is all held on the surface of the substrate W. The amount of the supplied plating solution may be a small amount that will become a 1 mm thickness (about 30 ml) on the surface of the substrate W. The depth of the plating solution held on the surface to be plated may be 10 mm or less, and may be even 1 mm as in this embodiment. If a small amount of the supplied plating solution is sufficient, the heating apparatus for heating the plating solution may be of a small size.

By so designing the apparatus as to heat the substrate W itself, the heating temperature of the plating solution, which needs large power consumption to heat, may be made relatively low. This favorably lowers the power consumption and prevents a change in the quality of plating solution. The heating of the substrate W itself can be effected with small power consumption. Further, the amount of the plating solution held on the substrate W is small. Accordingly, heat retention of the substrate W by the backside heater 915 can be effected with ease, and the volume of the backside heater 915 can be small whereby the apparatus can be made compact. Further, by using a means for directly cooling the substrate W itself, it becomes possible to make a heating/cooling shift during plating to thereby change the plating conditions. Furthermore, since the amount of the plating solution held on the substrate W is small, a highly-sensitive temperature control can be effected.

The substrate W is instantaneously rotated by the motor M to perform uniform liquid wetting of the surface to be plated, and then plating of the surface to be plated is performed in such a state that the substrate W is in a stationary state. Specifically, the substrate W is rotated at 100 rpm or less for only 1 second to uniformly wet the surface, to be plated, of the substrate W with the plating solution. Then, the substrate W is kept stationary, and electroless plating is performed for 1 minute. The instantaneous rotating time of the substrate W is 10 seconds or less at the longest.

After completion of the plating treatment, the front end of the plating solution recovery nozzle 965 is lowered to an area near the inside of the dam member 931 on the peripheral edge portion of the substrate W to suck in the plating solution. At this time, if the substrate W is rotated at a rotational speed of, for example, 100 rpm or less, the plating solution remaining on the substrate W can be gathered in the portion of the dam member 931 on the peripheral edge portion of the substrate W under centrifugal force, so that recovery of the plating solution can be performed with a good efficiency and a high recovery rate. The holding means 911 is lowered to separate the substrate W from the dam member 931. The substrate W is started to be rotated, and the cleaning liquid (ultrapure water) is jetted at the plated surface of the substrate W from the nozzle 953 of the cleaning liquid supply means 951 to cool the plated surface, and simultaneously perform dilution and cleaning, thereby stopping the electroless plating reaction. At this time, the cleaning liquid jetted from the nozzle 953 maybe supplied to the dam member 931 to perform cleaning of the dam member 931 at the same time. The plating waste liquid at this time is recovered into the recovery vessel 961 and discarded.

The plating solution, once used, is not reused but disposed of. As described above, this apparatus enables the use of a very small amount of plating solution as compared to the use of a conventional apparatus. Accordingly, the amount of the plating solution disposed of can be small. It is also possible, in some cases, not to provide the plating solution recovery nozzle 965 and recover the used plating solution, together with the cleaning liquid, as plating waste in the recovery vessel 961.

Then, the substrate W is rotated at a high speed by the motor M for spin-drying, and then the substrate W is removed from the holding means 911.

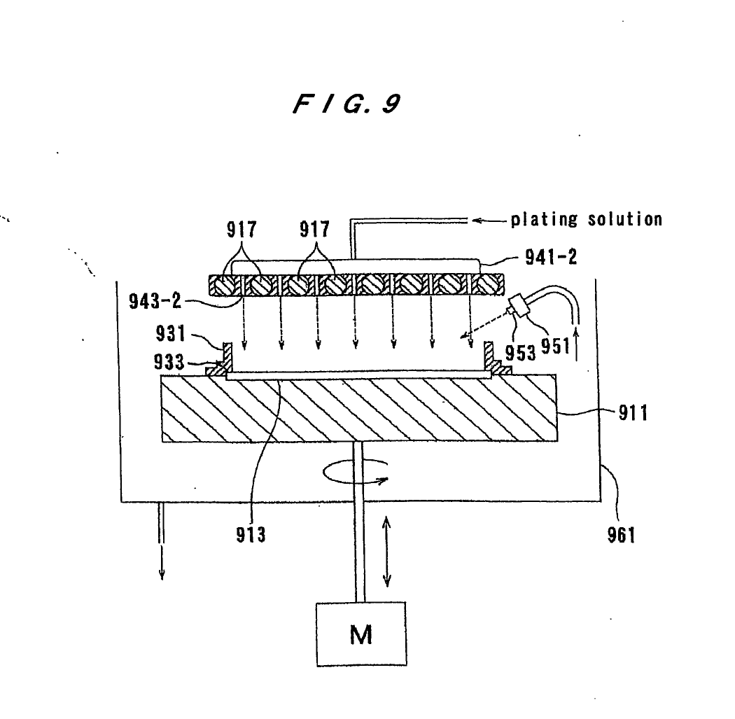

FIG. 9 is a schematic diagram of another electroless plating apparatus. The electroless plating apparatus of FIG. 9 is different from the electroless plating apparatus of FIG. 8 in that instead of providing the backside heater 915 in the holding means 911, lamp heaters 917 are disposed above the holding means 911, and the lamp heaters 917 and a shower head 941-2 are integrated. For example, a plurality of ring-shaped lamp heaters 917 having different radii are provided concentrically, and many nozzles 943-2 of the shower head 941-2 are open in a ring form from the gaps between the lamp heaters 917. The lamp heaters 917 may be composed of a single spiral lamp heater, or may be composed of other lamp heaters of various structures and arrangements.

Even with this constitution, the plating solution can be supplied from each nozzle 943-2 to the surface, to be plated, of the substrate W substantially uniformly in a shower form. Further, heating and heat retention of the substrate W can be performed by the lamp heaters 917 directly uniformly. The lamp heaters 917 heat not only the substrate W and the plating solution, but also ambient air, thus exhibiting a heat retention effect of the substrate W.

Direct heating of the substrate W by the lamp heaters 917 requires the lamp heaters 917 with a relatively large electric power consumption. In place of such lamp heaters 917, lamp heaters 917 with a relatively small electric power consumption and the backside heater 915 shown in FIG. 8 may be used in combination to heat the substrate W mainly with the backside heater 915 and to perform heat retention of the plating solution and ambient air mainly by the lamp heaters 917. Means for directly or indirectly cooling the substrate W may be provided to perform temperature control.

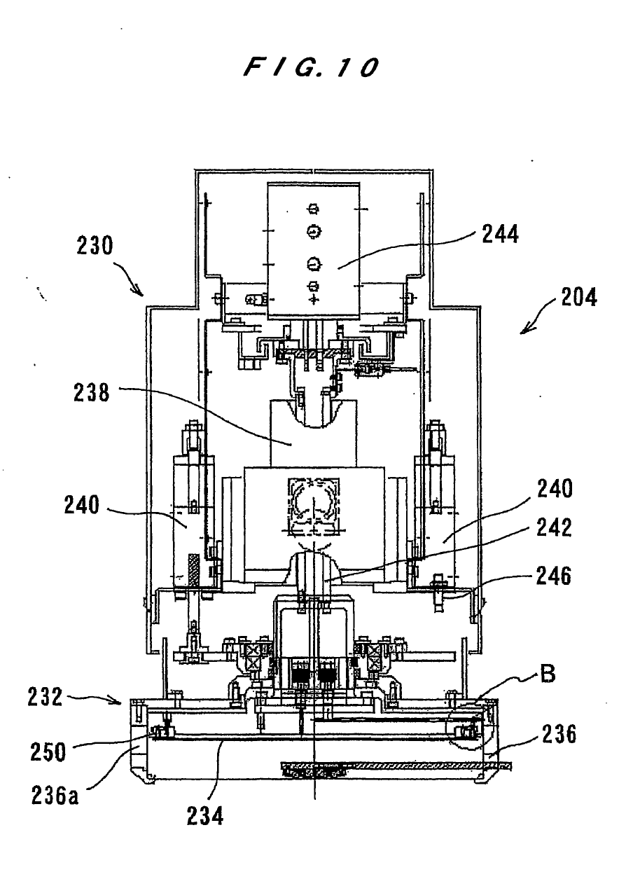

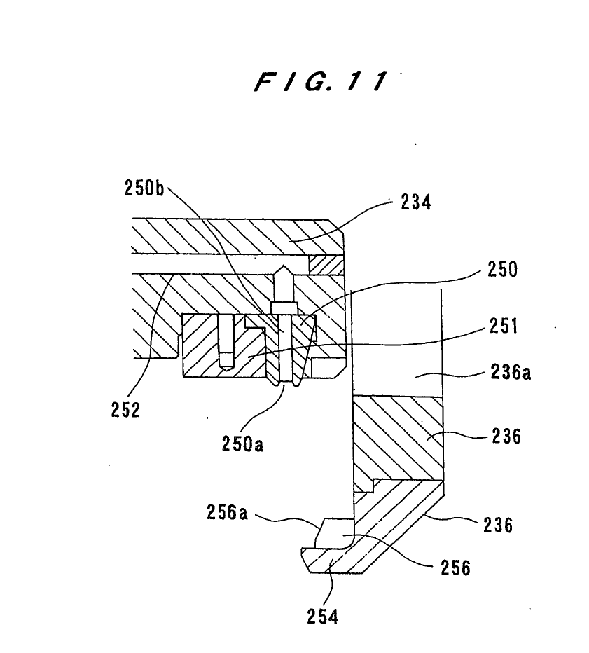

FIGS. 10 through 15 show yet another electroless plating apparatus. This electroless plating apparatus includes a plating tank 200 and a substrate head 204, disposed above the plating tank 200, for detachably holding a substrate W.

As shown in detail in FIG. 10, the processing head 204 has a housing 230 and a head assembly 232. The head assembly 232 mainly comprises a suction head 234 and a substrate receiver 236 for surrounding the suction head 234. The housing 230 accommodates therein a substrate rotating motor 238 and substrate receiver drive cylinders 240. The substrate rotating motor 238 has a hollow output shaft 242 having an upper end coupled to a rotary joint 244 and a lower end coupled to the suction head 234 of the head assembly 232. The substrate receiver drive cylinders 240 have respective rods coupled to the substrate receiver 236 of the head assembly 232. Stoppers 246 are provided in the housing 230 for mechanically limiting upward movement of the substrate receiver 236.

The suction head 234 and the substrate receiver 236 are operatively connected to each other by a splined structure such that when the substrate receiver drive cylinders 240 are actuated, the substrate receiver 236 vertically moves relatively to the suction head 234, and when the substrate rotating motor 238 is energized, the output shaft 242 thereof is rotated to rotate the suction head 234 and the substrate receiver 236 in unison with each other.

As shown in detail in FIGS. 11 through 13, a suction ring 250 for attracting and holding a substrate W against its lower surface to be sealed is mounted on a lower circumferential edge of the suction head 234 by a presser ring 251. The suction ring 250 has a recess 250a continuously defined in a lower surface thereof in a circumferential direction and in communication with a vacuum line 252 extending through the suction head 234 by a communication hole 250b that is defined in the suction ring 250. When the recess 250a is evacuated, the substrate W is attracted to and held by the suction ring 250. Because the substrate W is attracted under vacuum to the suction ring 250 along a radially narrow circumferential area provided by the recess 250a, any adverse effects such as flexing caused by the vacuum on the substrate W are minimized. When the suction ring 250 is dipped in the plating solution, not only the surface (lower surface) of the substrate W, but also its circumferential edge, can be dipped in the plating solution. The substrate W is released from the suction ring 250 by introducing N₂ into the vacuum line 252.

The substrate receiver 236 is in the form of a downwardly open, hollow bottomed cylinder having substrate insertion windows 236a defined in a circumferential wall thereof for inserting therethrough a substrate W into the substrate receiver 236. The substrate receiver 236 also has an annular ledge 254 projecting inwardly from its lower end, and an annular protrusion 256 disposed on an upper surface of the annular ledge 254 and having a tapered inner circumferential surface 256a for guiding a substrate W.

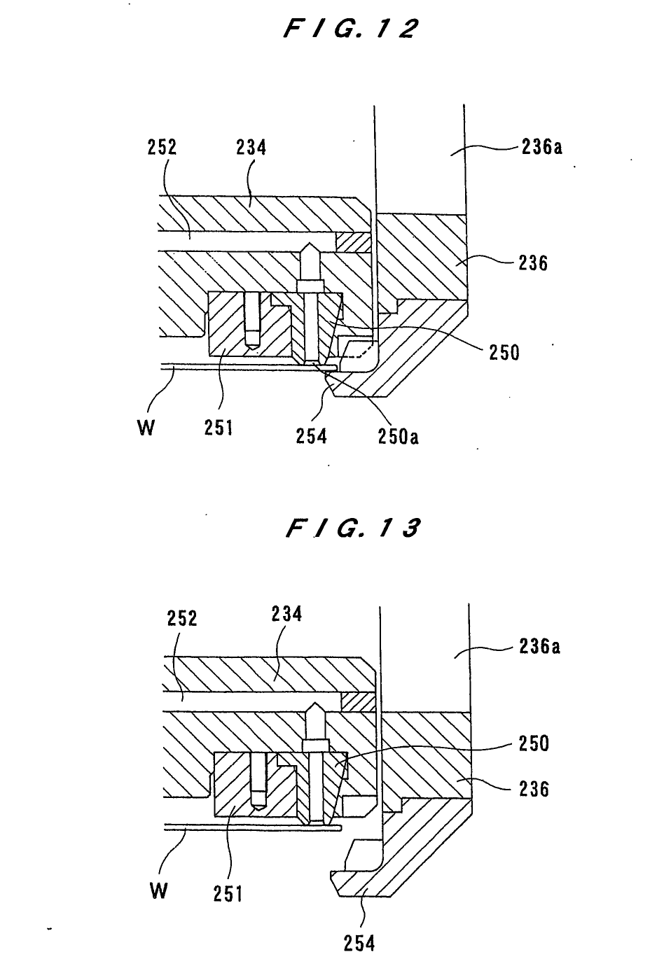

As shown in FIG. 11, when the substrate receiver 236 is lowered, the substrate W is inserted through the substrate insertion window 236a into the substrate receiver 236. The substrate W thus inserted is guided by the tapered surface 256a of the protrusion 256 and positioned thereby onto the upper surface of the ledge 254 in a predetermined position thereon. The substrate receiver 236 is then elevated until it brings the upper surface of the substrate W placed on the ledge 254 into abutment against the suction ring 250 of the suction head 234, as shown in FIG. 12. Then, the recess 250a in the vacuum ring 250 is evacuated through the vacuum line 252 to attract the substrate W while sealing the upper peripheral edge surface of the substrate W against the lower surface of the suction ring 250. To plate the substrate W, as shown in FIG. 13, the substrate receiver 236 is lowered several mm to space the substrate W from the ledge 254, keeping the substrate W attracted by only the suction ring 250. The substrate W now has its lower peripheral edge surface prevented from not being plated because it is held out of contact with the ledge 254.

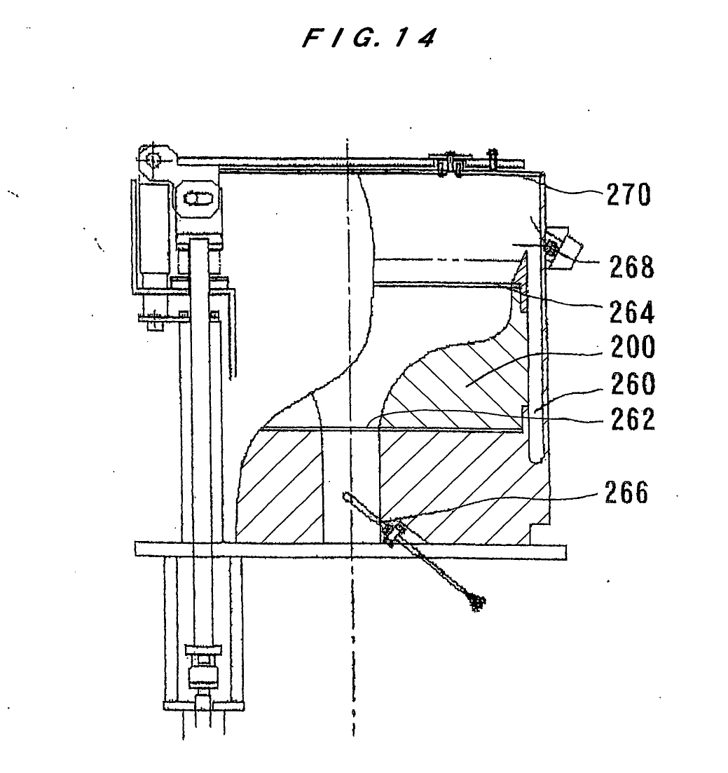

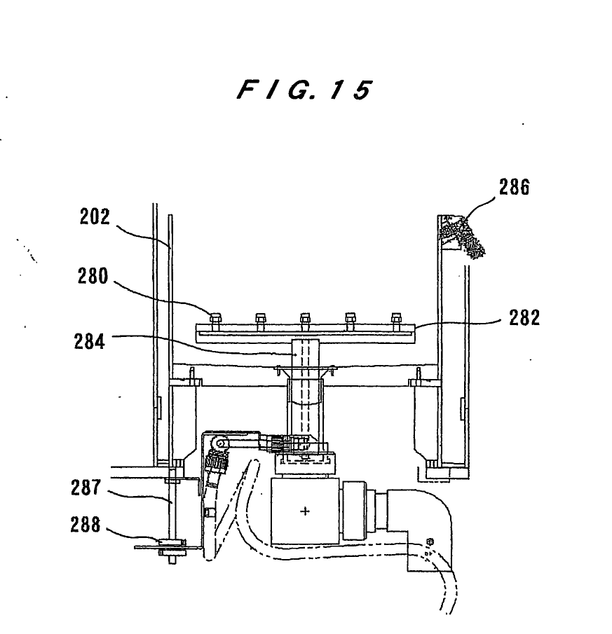

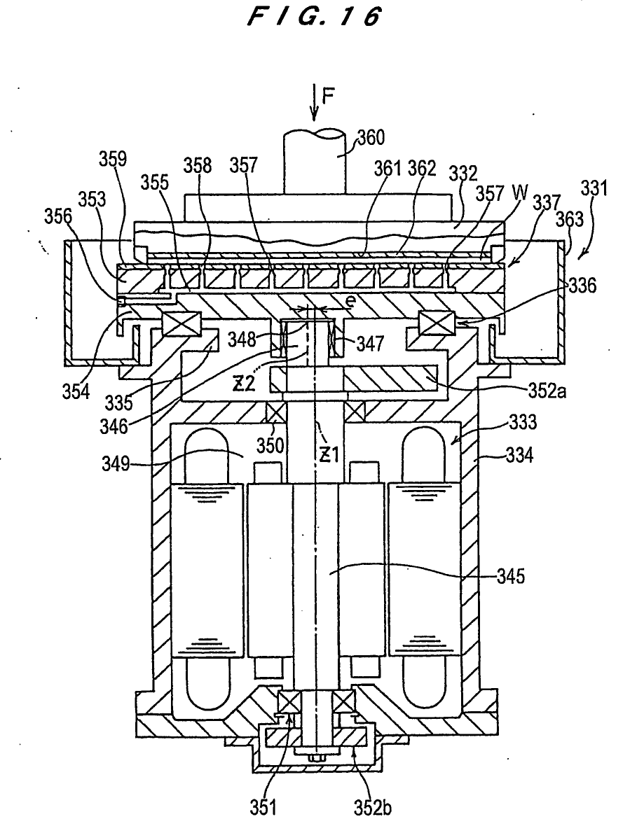

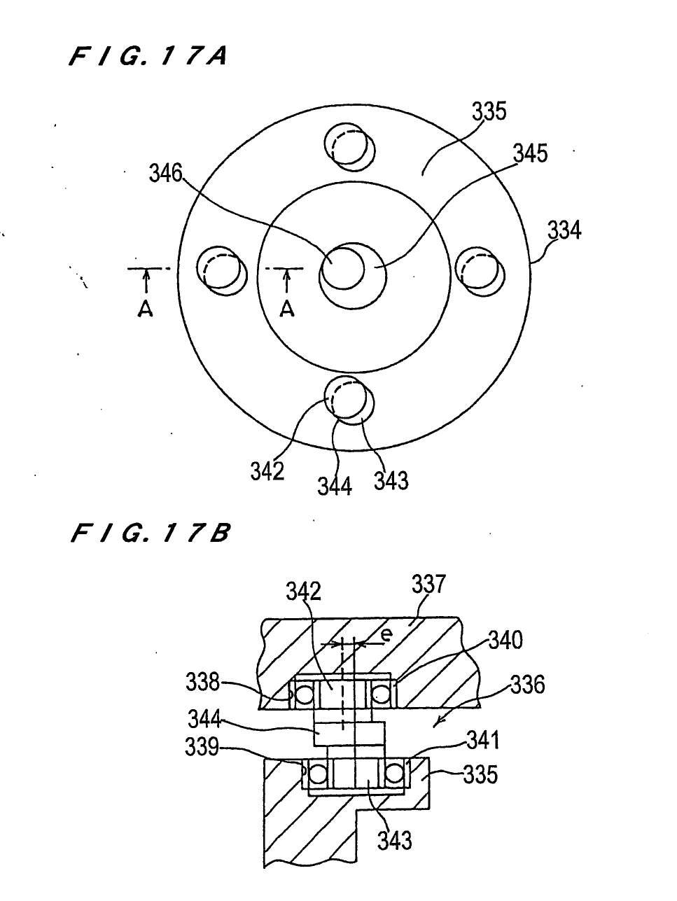

FIG. 14 shows the details of the plating tank 200. The plating tank 200 is connected at the bottom to a plating solution supply pipe (not shown), and is provided in the peripheral wall with a plating solution recovery groove 260. In the plating tank 200 are disposed two current plates 262, 264 for stabilizing the flow of a plating solution flowing upward. A thermometer 266 for measuring the temperature of the plating solution introduced into the plating tank 200 is disposed at the bottom of the plating tank 200. Further, on the outer surface of the peripheral wall of the plating tank 200 and at a position slightly higher than the liquid level of the plating solution held in the plating tank 200, there is installed a jet nozzle 268 for jetting a stop liquid which is a neutral liquid having a pH of 6 to 7.5, for example pure water, inwardly and slightly upwardly in the normal direction. After plating, the substrate W held in the head portion 232 is raised and stopped at a position slightly above the surface of the plating solution. Pure water (stop liquid) is immediately jetted from the jet nozzle 268 toward the substrate W to cool the substrate W, thereby preventing progress of plating by the plating solution remaining on the substrate W.

Further, at the top opening of the plating tank 200 is provided an openable/closable plating tank cover 270 which closes the top opening of the plating tank 200 in a non-plating time, such as idling time, so as to prevent unnecessary evaporation of the plating solution from the plating tank 200.

FIG. 15 shows the details of a cleaning tank 202 provided beside the plating tank 200. At the bottom of the cleaning tank 202 is disposed a nozzle plate 282 to which is mounted a plurality of jet nozzles 280 for upwardly jetting a rinsing liquid, such as pure water. The nozzle plate 282 is coupled to the upper end of a nozzle lifting shaft 284. The nozzle lifting shaft 284 can be moved vertically by changing the position of engagement between a nozzle position adjustment screw 287 and a nut 288 engaging the screw 287 so as to optimize the distance between the jet nozzles 280 and a substrate W located above the jet nozzles 280.

Further, on the outer surface of the peripheral wall of the cleaning tank 202 and at a position above the jet nozzles 280, a head cleaning nozzle 286 is provided for jetting a cleaning liquid, such as pure water, inwardly and slightly downwardly onto at least a portion, which was in contact with the plating solution, of the head portion 232 of the substrate head 204.

In operating the cleaning tank 202, the substrate W held in the head portion 232 of the substrate head 204 is located at a predetermined position in the cleaning tank 202. A cleaning liquid (rinsing liquid), such as pure water, is jetted from the jet nozzles 280 to clean (rinse) the substrate W and, at the same time, a cleaning liquid, such as pure water, is jetted from the head cleaning nozzle 286 to clean at least a portion, which was in contact with the plating solution, of the head portion 232 of the substrate head 204, thereby preventing a deposit from accumulating on that portion which was immersed in the plating solution.

According to this electroless plating apparatus, when the substrate head 204 is in a raised position, the substrate W is held by vacuum attraction in the head portion 232 of the substrate head 204 as described above, while the plating solution in the plating tank 200 is allowed to circulate.

When carrying out plating, the plating tank cover 270 is opened, and the substrate head 204 is lowered, while rotating it, so that the substrate W held in the head portion 232 is immersed in the plating solution in the plating tank 200.

After immersing the substrate W in the plating solution for a predetermined time, the substrate head 204 is raised to lift the substrate W from the plating solution in the plating tank 200 and, according to necessity, pure water (stop liquid) is immediately jetted from the jet nozzle 268 toward the substrate W to cool the substrate W, as described above. The substrate head 204 is further raised to lift the substrate W to a position above the plating tank 200, and the rotation of the substrate head 204 is stopped.

Next, while the substrate W is kept held by vacuum attraction in the head portion 232 of the substrate head 204, the substrate head 204 is moved to a position right above the cleaning tank 202. While rotating the substrate head 204, it is lowered to a predetermined position in the cleaning tank 202. A cleaning liquid (rinsing liquid), such as pure water, is jetted from the jet nozzles 280 to clean (rinse) the substrate W and, at the same time, a cleaning liquid, such as pure water, is jetted from the head cleaning nozzle 286 to clean at least a portion, which was in contact with the plating solution, of the head portion 232 of the substrate head 204.

After completion of the cleaning of substrate W, the rotation of the substrate head 204 is stopped, and the substrate head 204 is raised to lift the substrate W to a position above the cleaning tank 202. Thereafter, the substrate W is transferred to the next process step.

Though in this embodiment the respective process steps, e.g. the second and third steps, and the fourth and fifth steps, are carried out separately, the present invention, of course, is not limited to such a manner. With provision of various processing means, transfer robots and end point detection means, it is possible to combine the process steps, and select and effect polishing methods suited to flattening of a semiconductor device, a processing object including various different materials.

A sputtering method is now generally employed for the formation of a barrier material for which a Ta-based material, such as Ta or TaN, is mainly used. From the coverage viewpoint, the thickness of a barrier metal is about 60 to 80 nm (when the technology node is around 100 nm). In the future, as technology advances, a CVD method will take the place of the current sputtering, and then the thickness of a barrier material will become thinner to a level of several to several tens nm. In processing of such a thin barrier material, rather than the processibility, suppression of defects will be more important. Further, semiconductor devices will become finer. It is said that at a technology node of 65 nm, the thickness of a barrier material will be as thin as several nm.

In processing different materials (interconnect material and barrier material), when the processing thickness is large, there is often the problem of worsening of flatness due to difficulty of simultaneous processing. As a barrier material becomes thinner, the time for processing will be shortened. Accordingly, processing of a barrier material, irrespective of its processing methods, will less affect flattening. Thus, the process steps involving polishing (removal) of a barrier material will be combined relatively easily. For example, a common CMP method could be employed for the third and fourth steps if the influence on flatness, which is currently a problem, is reduced and the processing performance in the level difference elimination step is improved.

Copper material is difficult to remove by chemical etching. On the other hand, electrochemical etching and chemical etching are also effective when the barrier material is processed into a thin film or when a material other than copper is used as the interconnect material. A wider choice of processing methods is thus possible.

Also with the above-described fifth step, since the processing should be carried out while maintaining the flattened surface, it is desirable to put the fourth step and the sixth step before and after the fifth step. As described above, however, as a barrier material becomes thinner, there will be a case where a plurality of steps can be carried out with the same processing method. Thus, the fourth and fifth steps, the fifth and sixth steps, or the fourth to sixth steps could be combined or carried out in the same step.

For the above-described first to sixth steps, it is desirable to select appropriate processing methods according to the respective objectives. However, in case a particular processing method, with the same processing conditions, can achieve the objectives of two or more steps, it is possible to combine the two or more steps into the one step and carry out the combined step under the same processing conditions. For example, when a processing method utilizing an electric force is employed, a high-quality simple processing can be effected by changing the processing method or the processing conditions between the second and third steps. On the other hand, when a pure water electrolytic processing method utilizing a catalyst, which is excellent in elimination of a level difference as well as in uniform and high-speed processing, is employed, it is possible to carry out the processings in the second and third steps with the same processing method. Likewise, the first and second steps may be carried out as a combined step by an ultrapure water electrolytic processing utilizing a catalyst. Further, the third and fourth steps, the third to fifth steps, the third to sixth steps, the fourth and fifth steps, or the fourth to sixth steps may be carried out as a combined step by CMP carried out under low-pressure, high-relative speed conditions, using ultrafine abrasive grains and a chemically-adjusted slurry.

In the case where a barrier material (barrier metal) is not present, if any, is so thin as not to affect flattening, the present method for embedding an interconnect material into interconnect recesses formed in a surface of an insulating material, and removing unnecessary interconnect material on a substrate and flattening the surface of the substrate, comprises the steps of: a first step of eliminating a level difference in the surface of the interconnect material and removing the interconnect material until the interconnect material present in the non-interconnect region of the substrate becomes a thin film or remains partly; and a second step of removing the interconnect material in the form of the thin film or remaining partly until an underlying material present under the interconnect material in the non-interconnect region becomes exposed.

In this method, the first step may be terminated when the film thickness of the interconnect material present in the non-interconnect region has reached a value of not more than 300 nm. The film thickness of the interconnect material present in the non-interconnect region may be detected, for example, with an eddy-current or optical film thickness detection sensor.

Preferably, the processing rate of the interconnect material in the second step is higher than the processing rate of the interconnect material in the first step. The second step may be carried out by using a processing liquid containing chemical liquid. Further, the second step, which is carried out while suppressing formation of defects, may be carried out while applying a pressure to the substrate, and the first step may be carried out while applying a pressure, which is lower than the pressure of the second step, to the substrate.

The substrate processing method may further comprise a step of removing the underlying material until a material present under the underlying material becomes exposed. The step of removing the underlying material may comprise a step of removing the underlying material until the underlying material becomes a thin film or remains partly, and a step of removing the underlying material in the non-interconnect region until the material present under the underlying material becomes exposed.

In the case of processing only a barrier layer in two steps, the present method for embedding an interconnect material into interconnect recesses having a film of a barrier material formed on the surface, and removing unnecessary interconnect material and barrier material on a substrate and flattening the surface of the substrate, comprises the steps of: a first step of simultaneously removing the unnecessary interconnect material and barrier material until the barrier material present in the non-interconnect region of the substrate becomes a thin film or remains partly; and a second step of removing the unnecessary interconnect material and the barrier material in the form of the thin film or remaining partly, thereby exposing an insulating material present in the non-interconnect region.

In this method, the second step may be carried out while applying a pressure to the substrate, and the first step may be carried out while applying a pressure, which is lower than the pressure of the second step, to the substrate.

In consideration of substrate transfer steps and the conditions that are required for the above-described steps, the best processing methods for the respective steps may be as follows:

The first and second steps are carried out by electrolytic processing using pure water. Such electrolytic processing may be carried out, for example, in the electrolytic processing section 64 shown in FIG. 3. According to electrolytic processing using pure water, the substrate after processing is free from contamination with a chemical or abrasive grains, which avoids the need for a cleaning step. Further, the use of the same processing tool in the first and second steps can decrease the number of substrate transfer steps, leading to an increase in the throughput. In the first step, before shifting to the second step, elimination of a level difference is determined, for example, by detecting a change in the torque current of the hollow motor 100 which drives the processing table 74.

In the second step, further processing of the interconnect material may be carried under the same conditions as in the first step. It is possible to carry out the first step under constant-voltage conditions with a controlled constant voltage, and carry out the second step under constant-current conditions with a controlled constant current. By carrying out the first step under a constant-voltage control, the same voltage can be secured even when the contact area of a processing object having an initial level difference is changed, and polishing of the processing object can be carried out under stable processing conditions with excellent level difference elimination. When carrying out the step second with a constant-current control after a flat surface is obtained in the first step, a high processing rate at a large current can be secured. The second-step processing can be carried out under such conditions that make the polishing rate largest of all the process steps. In the second step, the film thickness of the conductive interconnect material (copper 22) is measured e.g. with an eddy-current sensor, and processing is terminated when the film thickness has reached a predetermined value which, depending upon the processing performance in the second step, etc., is for example 300 nm, preferably not more than 100 nm, more preferably not more than 50 nm.

The third step is carried out by CMP. In the case of carrying out CMP with the CMP section 62 shown in FIG. 3, the shift from the second step to the third step can be made while a substrate is kept held by the same substrate holder 60. In the third step, the interconnect material, for example copper, and the barrier material are polished simultaneously, and therefore a delicate processing is required. Thus, a pressure of about 0.1 to 3 psi is applied to the substrate during processing, and the processing pressure is made lower than that in the second step. Since the different material becomes exposed, the end point of the third-step processing is determined with an optical film thickness detector or an eddy-current sensor. This step is aimed at complete removal of the interconnect material in the non-interconnect region. In a case where the complete removal of interconnect material cannot be determined clearly, after detecting the underlying different material, the barrier layer, by an optical detection means, the end point may be determined by time management. It is desired that the third step be carried out under such conditions that the polishing (removal) rate is made lower than the first and second steps. After completion of the third step, the liquid supplied onto the polishing table 68 is preferably replaced with pure water so that the polishing table 68 can be cleaned with pure water and the substrate can be water-polished, thereby removing foreign matter or debris on the substrate. The tool may be dressed to improve its cleanliness. The dressing may be carried out during processing.

The fourth step of processing is carried out by CMP on the same polishing table 68 as in the third step, continuously. The fourth step is directed to processing of the interconnect material in the interconnect region and the barrier material. In view of this, a chemical liquid which makes the selectivity ratio between the interconnect material (copper) and the barrier material nearly 1:1 is added to the polishing liquid used in the third step. Alternatively, the polishing liquid is replaced with such a chemical liquid. Further, the processing pressure, the rotational speed, the degree of dressing, etc. are changed during processing. For the fourth step, the end point is suitably determined with an optical or eddy-current film thickness detection means. Also after the fourth step, water polishing and tool dressing may be carried out as in the third step. The dressing may also be carried out during processing.

The fifth step of processing is carried out by CMP on the polishing table 68 as in the forth step, continuously. The chemical liquid, the processing pressure, the rotational speed, the degree of dressing, etc. are changed during processing. The fifth step removes the barrier material and is a finish processing step. Further, the underlying insulating film, for example a ULK (ultra low-k) material, becomes exposed in this step. Accordingly, the fifth-step processing is required to be carried out at a lower pressure than the third and fourth steps, in particular at a pressure not more than 1 psi. Further, the relative speed between a substrate and the processing member should preferably be higher than the fourth step. It is also possible to carry out a hydroplaning polishing at a lowered pressure by the liquid present between a substrate and the processing member. Also in the fifth step, the end point of processing may be determined, for example, by time management.

The sixth step is carried out, according to necessity, to further process the insulating film (insulating material). Also in this step, especially when the insulating film is a ULK (ultra low-k) material, processing is carried out at a low pressure, which is the same as or even lower than that in the fifth step. After completion of the fifth or sixth step, as necessary, the above-described water polishing and dressing may preferably be carried out. The dressing may also be carried out during processing.

The detection of end point in each step is preferably carried out by in-situ film thickness measurement and/or time management in an automated process using a PC. This enables a more precise process control. It is also possible to carry out time management to some extent, and carry out the measurement of film thickness within a limit of a specified time. The measurement accuracy can be improved by employing a combination of two end point detection means selected from an optical detection means, an electrical detection means, a torque detection means, etc.

After completion of the above-described steps of removal processing, the processed substrate is subjected to multi-step cleaning in the cleaning machine 42, followed by drying, and is returned by the first transfer robot 36 to the substrate cassette 30 in which the substrate before processing was housed. It is possible to replace one of the pair of cleaning machines 42 with an electroless plating apparatus as described above. Thus, in this case, the substrate after processing is cleaned in the cleaning machine 42. Thereafter, a protective film is formed in the interconnect region of the substrate by the electroless plating apparatus. The substrate is then subjected to multi-step cleaning in the cleaning machine 42, followed by drying, and is returned to the substrate cassette 30.

FIGS. 16 and 17 show a CMP apparatus which is replaceable with the substrate head 82 having the substrate holder 60 and with the CMP section 62, both shown in FIG. 3. This CMP apparatus can also be used to carry out various types of electrolytic processings. The CMP apparatus includes a translational table section 331 which provides a polishing tool surface that makes a translational cyclic movement, and a top ring 332 for holding a substrate W with its polishing surface facing downward and pressing the substrate W against the polishing tool surface at a predetermined pressure. Incidentally, the processing table 76 provided in the CMP section 62 shown in FIG. 3 is also designed to make a translational cyclic movement.

The translational table section 331 has a tubular casing 334 housing a motor 333 therein, an annular support plate 335 projecting inwardly from an upper portion of the tubular casing 334, three or more support sections 336 circumferentially spaced and mounted on the annular support plate 335, and a surface plate 337 supported on the support sections 336. An upper surface of the support plate 335 and a lower surface of the surface plate 337 have a plurality of recesses 338, 339 at positions which are corresponding each other and spaced at equal intervals in the circumferential direction, and bearings 340, 341 are mounted in the respective recesses 338, 339. As shown in FIG. 17, a joint 344 has two shafts 342, 343 that are displaced by a distance “e” from each other, and these shafts 342, 343 have ends mounted respectively in the bearings 340, 341, allowing the surface plate 337 to make a translational movement along a circle having a radius “e”.

In the central lower surface of the surface plate 337 is formed a recess 348 housing, via a bearing 347, a drive end 346 provided eccentrically on the top end of a main shaft 345 of the motor 333. The eccentricity also is “e”. The motor 333 is housed in a motor chamber 349 formed in a casing 334, and the main shaft 345 is supported by upper and lower bearings 350, 351. Balancers 352a, 352b for balancing an imbalance load due to the eccentricity are mounted to the main shaft 345.

The surface plate 337 has a diameter which is slightly larger than the sum of the diameter of a substrate W to be polished or processed and the eccentricity “e”, and is composed of two plate-like members 353, 354 bonded to each other. A space 355 is formed between the members 353, 354 for passing a polishing liquid (processing liquid) to be supplied to the polishing surface (processing surface). The space 355 communicates with a polishing liquid supply inlet 356 provided in the side surface of the surface plate 337 and also with a plurality of polishing liquid outlet holes 357 which are open to the upper surface of the surface plate 337.

A fixed abrasive (abrasive plate) 359 is attached to the upper surface of the surface plate 337 of the CMP apparatuses. The fixed abrasive 359 has outlet holes 358 formed at positions corresponding to the polishing liquid outlet holes 357. The outlet holes 357, 358 are generally distributed almost uniformly over the entire surfaces of the surface plate 337 and of the fixed abrasive 359. It is possible to use a polishing pad, such as foamed polyurethane, instead of the fixed abrasive 359. Further, in the case of using the apparatus for electrolytic processing, instead of the fixed abrasive 359, an ion exchanger or a scrubbing member may be provided.

The fixed abrasive 359 is produced by binding fine abrasive grains having a diameter of not more than several μm, such as CeO₂, SiO₂, Al₂O₃or a resin, with a binder and molding the material into a disc-like shape. Selection of materials and production process control are practiced so as to avoid a warp or deformation of the product upon molding or during storage, thereby ensuring the surface flatness of the product (fixed abrasive). In the surface of the fixed abrasive 359 is formed a lattice-like, spiral or radial groove (not shown) for passing a polishing liquid therethrough or removing shavings. The groove communicates with the outlet holes 358.

The top ring 332, which is a pressing means, is mounted to the lower end of the shaft 360 such that it can tilt to a certain degree to follow the polishing surface. The pressing force of a not-shown air cylinder and the torque of a not-shown drive motor are transmitted to the top ring 332 via the shaft 360. An elastic sheet 362 is mounted on the substrate holder 361 of the top ring 332 so that fine irregularities on the substrate holder 361 are not transferred to a to-be-polished surface of a substrate. A recovery tank 363 for recovering the polishing liquid supplied is provided around the top portion of the casing 334.

The operation of the thus-constructed CMP apparatus will now be described. A substrate W is set in the top ring 332. The surface plate 337 makes a translational circular movement by the actuation of the motor 333, while the substrate W set in the top ring 332 is pressed against the surface of the fixed abrasive 359 attached to the surface plate 337. A polishing liquid is supplied through the polishing liquid supply inlet 356, the polishing liquid space 355 and the polishing liquid outlet holes 357, 358 to the polishing surface. The polishing liquid is supplied between the fixed abrasive 359 and the substrate W via the groove in the surface of the fixed abrasive 359.

The fixed abrasive 359 and the substrate W make a relative movement, which is a small translational circular movement with the radius “e”, whereby uniform polishing is effected over the entire to-be-polished surface of the substrate W. Further, the top ring 332 is rotated slowly. In this regard, if the positional relationship between the to-be-polished surface and the polishing surface remains unchanged, a local difference in the polishing surface affects the to-be-polished surface. In order to avoid this, the top ring 332 is rotated so as to prevent the to-be-polished surface from being polished by the same portion of the fixed abrasive 359.

The polishing is usually water polishing using pure water as a polishing liquid. If necessary, however, a chemical liquid or a slurry may be used. When a slurry is used, the slurry may contain the same abrasive grains as the abrasive material of the fixed abrasive. This sometimes produces a good effect. Instead of the polishing liquid, an electrolytic solution optionally containing abrasive grains, for example, may be used in the case of electrolytic processing, and a liquid having an electric conductivity of not more than 500 μS/cm, for example, may be used in the case of electrolytic processing using ultrapure water.

Since the CMP apparatus of this embodiment is of a translational cyclic movement type, it is enough for the surface plate 337 to have a size which is larger than the size of the substrate W by the eccentricity “e”. Accordingly, the installation space can be made considerable smaller. Consequently, when the apparatus is unitized with a cleaning device and a reversing device, the designing can be made with ease and a modification can also be made with ease.

Further, since the surface plate 337 of the CMP apparatus makes a translational cyclic movement, it is possible to support the surface plate 337 at its peripheral portions. This enables a flatter polishing as compared to the use of a conventional turntable that rotates at a high speed.

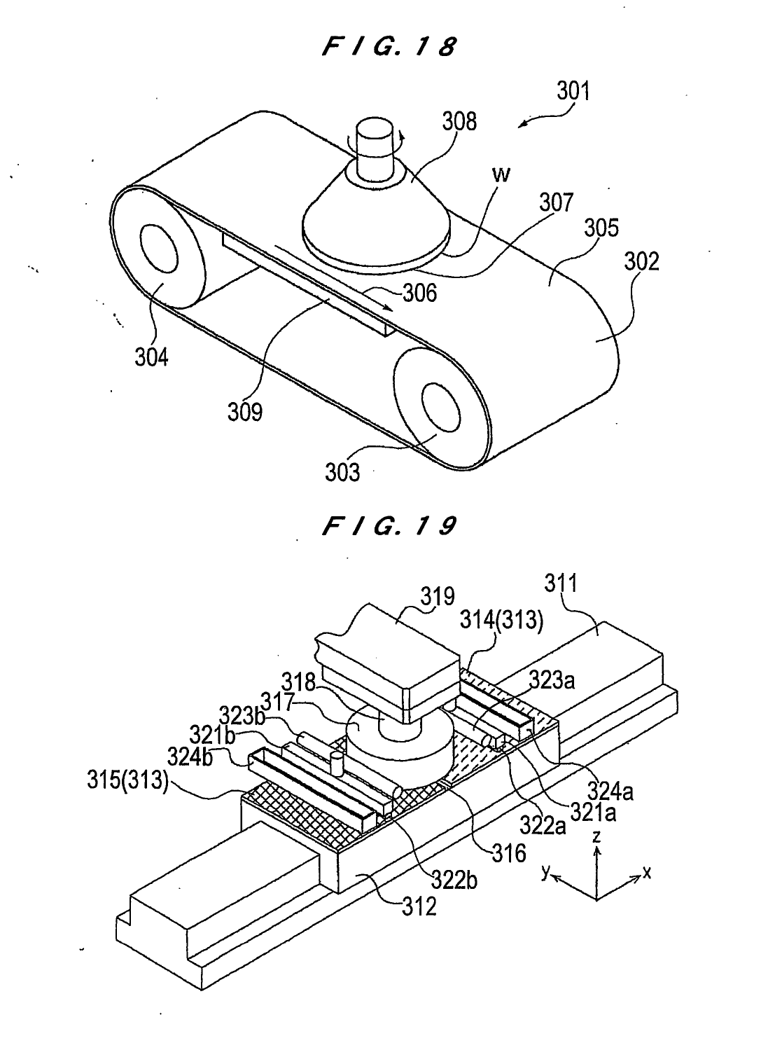

FIG. 18 shows another CMP or electrolytic processing apparatus. According to this processing apparatus, a belt 302 runs on a pair of rollers 303, 304 which are disposed in parallel and rotate about their shafts. To a surface of the belt 302 is attached a polishing pad 305 having elasticity and a flexible sheet-like fixed abrasive, an ion exchanger, or a scrubbing member. A backup plate 309 for supporting the backside of the belt 302 is provided at an intermediate position between the rollers 303, 304 where the belt 302 runs linearly. A rotatable top ring 308 for holding a substrate W and pressing the substrate W against the polishing pad 305 is disposed opposite the belt 302 supported by backup plate 309.

FIG. 19 shows yet another CMP or electrolytic processing apparatus. The processing apparatus includes a rail 311 as a linear guide having a horizontal guide surface, and a polishing table 312, placed on the guide surface of the rail 311, which makes a reciprocating linear movement in a horizontal direction by the linear guide of the guide rail 311. Taking now an x-y-z orthogonal coordinate system with the x axis as the direction of the reciprocating linear movement of the guide rail 311, the y axis as a horizon direction perpendicular to the x axis and the z axis as the vertical direction. In the coordinate system, the x-axis direction is taken as a first direction.

The upper surface of the processing table 312 constitutes a processing surface 313 in a horizontal plane. The processing surface 313 is divided into a high-speed processing surface 314 and a finish processing surface 315 with a fine texture. The provision of the two processing surfaces enables the same processing apparatus to perform two types of processing steps. Between the high-speed processing surface 314 and the finish processing surface is formed a multifunctional groove 316 that extends linearly in the direction (y-axis direction) perpendicular to the direction (x-axis direction) of the linear movement of the processing table 312. In the following description, the high-speed processing surface 314 and the finish processing surface 315 are collectively referred to simply as the processing surface 313 unless they should be discriminated.

Though in this embodiment the two types of processing surfaces 314, 315 are provided, it is possible to provide three or more types of processing surfaces according to the process requirements. For example, besides the processing surfaces for rough processing and finish processing, a modification surface for modifying the surface of a processing object so as to enhance the cleaning effect, may be provided. When the apparatus is used for electrolytic processing, an ion exchanger, a polishing pad or a scrubbing member may be employed. It is also possible to use one processing surface for CMP, and provide an electrode in other processing surface for use in electrolytic processing.

A disc-shaped top ring 317 for holding a processing object, for example a circular semiconductor substrate, opposite the processing surface 313 and pressing the processing object against the processing surface 313, is disposed vertically above the processing surface 313. The top ring 317 has, on the opposite side from the substrate holding surface, a pad pressing mechanism 318 that rotates the top ring 317 horizontally. The pad pressing mechanism 318 is designed to move the top ring 317 in the horizontal direction perpendicular to the moving direction of the polishing table 317 and press the top ring 317 against the polishing pad 313. The pad pressing mechanism 318 can be moved by an arm 319.

A pair of dressers 321a, 321b for dressing the processing surface 313 or regenerating an ion exchanger are provided adjacent to the top ring 317 in the x-axis direction and symmetrically about the top ring 317. The dressers 321a, 321b have dresser materials 322a, 322b facing the processing surface 313. The dressers 321a, 321b and the dresser materials 322a, 322b mounted thereto are formed in a rectangular shape, and the dresser materials 322a, 322b are disposed such that the long direction of the rectangular shape coincides with the y-axis direction. Further, nozzles 323a, 323b for supplying a liquid to the dressers 321a, 321b are provided between the top ring 317 and the dressers 321a, 321b.

Further, on the opposite side of each dresser 321a, 321b from each nozzle 323a, 323b in the x-axis direction are disposed rectangular dresser pods 324a, 324b with the long direction coincident with the y-axis direction.

In the following description, two identical elements, for example dressers 321a, 321b, are simply referred to e.g. as dresser 321 with the subscripts a, b omitted unless they should be discriminated.

The operation of the thus-constructed processing apparatus will now be described. When carrying out the processing, a substrate W, which is vacuum-attracted and held with its to-be-processed surface facing downward by the top ring 317, is pressed against the processing surface 313 which is reciprocating in the x-axis direction.

The top ring 317 reciprocates in the direction (y-axis direction) perpendicular to the direction (x-axis direction) of the reciprocating linear movement of the processing surface 313. In order to prevent local damage to the surface being processed, the top ring 317 is rotated at a low speed, for example, about 10 min⁻¹. Because of the low rotational speed, the movement of the to-be-processed surface of the substrate W relative to the processing surface 313 is substantially a linear movement. In other words, the top ring 317 is rotated at such a low speed that the movement of the to-be-processed surface relative to the processing surface 313 is substantially a linear movement.

In theory, a stationary to-be-processed surface, which is being pressed against the reciprocating processing surface 313, has the same moving speed relative to the processing surface at every point in the to-be-processed surface. Thus, uniform processing (polishing) can be effected theoretically. Further, by rotating the to-be-processed surface at a very low speed, it becomes possible to prevent local damage to the to-be-processed surface while maintaining uniform processing.

A plurality of holes (not shown) for ejection of a processing liquid are open in the processing surfaces 314, 315 so that a processing liquid, such as an abrasive liquid, is directly supplied between the processing surfaces 314, 315 and the substrate W. This manner makes it possible to supply a processing liquid (abrasive liquid) uniformly onto the to-be-processed surface despite the fact that unlike the case of rotational movement, a processing liquid can be supplied with difficulty in the case of reciprocating linear movement.

In order to carry out a first processing with the processing surface 314, the processing table 312 reciprocates in the x-axis direction in such a manner that the substrate W is processed only on the processing surface 314. Similarly, in the case of the processing surface 315 for carrying out a second processing, the processing table 312 reciprocates in the x-axis direction within the range of the processing surface 315. The different steps of processing can thus be carried out on the same processing table 312.

Though in carrying out CMP, an elastic pad, such as a polishing cloth, may be used for the processing surfaces 314, 315, because of the reciprocating linear movement of the processing table 312, it is also possible to use a fixed abrasive for either one or both of the processing surfaces 314, 315. The use of a fixed abrasive can prevent dishing in the to-be-processed surface. Since the processing table 312 makes a reciprocating linear movement, unlike an endless belt, the upper surface of the processing table 312 is a plane with a limited space, usually of a rectangular shape. Accordingly, a change of pad can be made with ease.

According to an apparatus which employs a polishing pad, an abrasive liquid is generally supplied between a polishing object and the polishing pad. Since a polishing pad is an elastic body, even when polishing is carried out while applying a uniform pressure from the polishing pad to the entire to-be-processed surface of the polishing object, not only raised portions of irregularities on the to-be-processed surface, but also depressed portions can also be polished. Accordingly, upon completion of polishing of the raised portions, the depressed portions have also been polished to some extent to newly form depressed portions. The formation of such depressed portions remaining after polishing is called “dishing”. A method for increasing the polishing rate is to increase the pressure of the polishing object against the polishing pad. In this case, however, the dishing problem becomes more serious. It is therefore difficult with the use of a polishing pad to simultaneously achieve high polishing rate and good flattening.

On the other hand, the use of a fixed abrasive can simultaneously achieve high polishing rate and prevention of dishing. A fixed abrasive can be effectively used especially for the processing surface 314 for rough processing.

For either of the processing surface 314 for rough processing and the processing surface 315 for finish processing, it is desirable to provide a groove such that it extends fully across the processing surface. The groove may extend at a right angle to the movement direction (x-axis direction) of the processing surface, or extend obliquely to promote discharge. of used abrasive liquid or the like and prevent peeling of the cloth.

A description will now be given of dressing of the processing surfaces 314, 315 to carry out dressing, removal of foreign matter and regeneration. The dresser materials 322a, 322b, for example diamond as a hard material and a nylon brush as a soft material, are pressed against the processing surfaces 314, 315 reciprocating linearly in the x-axis direction.

The dressers 321a, 321b reciprocate linearly in the direction (y-axis direction) perpendicular to the moving direction (x-axis direction) of the processing surfaces 314, 315. With the provision of the dressers 321a, 321b that move in the direction perpendicular to the direction of the reciprocating linear movement of the processing surfaces 314, 315, dressing can be effected uniformly over the entire processing surfaces 314, 315.

During the dressing, a dressing liquid is emitted from the nozzles 323a, 323b provided in the vicinity of the dressers 321a, 321b to discharge floating foreign matter out of the processing surfaces 314, 315.

By thus providing the dressers 321a, 321b on both sides of the top ring 317, the distance of reciprocating linear movement in the x-axis direction for dressing can be shorted, and therefore the apparatus can be downsized. The rectangular dresser materials 322a, 322b of the dressers 321a, 321b are preferably so designed that their lengths in the long direction are larger than the width of the processing table 312. This improves uniformity of dressing.

If foreign matter, etc. is accumulated on the top ring 317 side, such foreign matter adversely affects the polishing performance. Therefore, for example, during the latter half of dressing, when the ends of the processing table 312 are moving away from the dressers 321a, 321b, the dressers 321a, 321b may be brought out of contact with the processing surfaces 314, 315, while when the ends of the processing table 312 are moving close to the dressers 321a, 321b, the dressers 321a, 321b maybe brought into contact with the processing surfaces 314, 315, thereby sweeping foreign matter, etc. out to the opposite side of the multifunctional groove 316. By moving the processing table 312 up to a position at which the dressers 321a, 321b are out of the processing table 312, foreign matter, etc. can be completely swept away. Further, foreign matter, etc. collected by the dressers 321a, 321b may be discharged by using the discharging function of the multifunctional groove 316.

During a non-dressing period, the dressers 321a, 321b are on standby at positions distant from the processing surfaces 314, 315. The dressers 321a, 321b have been moved to the positions by a lifting mechanism. The nozzles 323a, 323b are so designed that they can supply a rinsing liquid to the dresser materials 322a, 322b even when the dressers 321a, 321b are in the standby positions.

In this embodiment, the generally rectangular dressers 321a, 321b are disposed such that the long direction coincides with the y-axis direction, and the direction of the reciprocating linear movements of the dressers 321a, 321b, as a second direction, coincides with the y-axis direction. The second direction, however, is not limited to such, and a direction crossing the x-axis direction will be sufficient. It is, however, preferred that the second direction be the same as the direction of the multifunctional groove 316. Similarly, though the direction of the reciprocating linear movement of the top ring 317, as a third direction, coincides with the y-axis direction in this embodiment, the third direction is not limited to such and a direction crossing the x-axis direction will be sufficient.

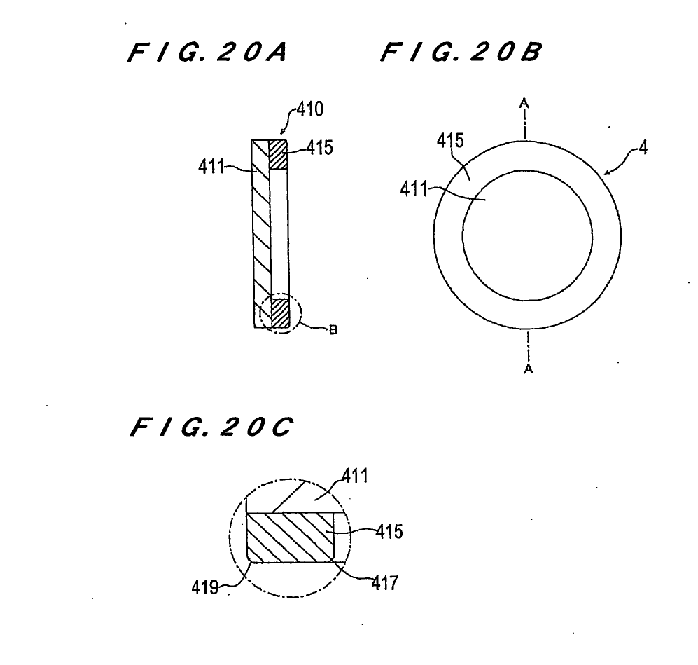

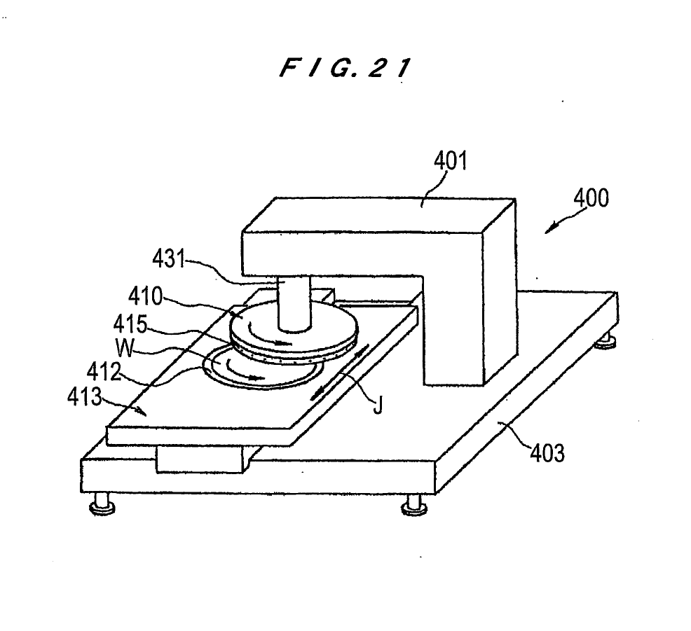

FIGS. 20A to 20C and 21 show yet another CMP or electrolytic processing apparatus. The processing apparatus includes a cup-type processing tool 410 which is comprised of a disc-shaped processing member support member 411 and a ring-shaped processing member 415 mounted on the lower surface of the support member 411. Each of the entire inner and outer edge portions 417, 419 of the lower surface of the processing member 415 has roundness with a predetermined radius.

The processing member 415 effects removal processing of the surface of a substrate by rubbing its surface against the substrate in the presence of a processing liquid. When an abrasive wheel is used as the processing member 415, the abrasive wheel may comprise abrasive grains having an average grain size of e.g. not more than 2 μm, which are bonded with a binder. Specific examples of the abrasive grains include resin particles such as CeO₂, Sio₂, Al₂O₃, ZrO₂, MnO₂ and Mn₂O₃; composite particles composed of abrasive grains supported on a resin; and composite particles composed of abrasive grains coated with a resin. Specific examples of the binder include a polyamide resin, a phenolic resin, urethane, PVA (polyvinyl alcohol) and a thermoplastic resin. The abrasive wheel may optionally contain an additive, such as resin particles and water-soluble particles.

FIG. 21 is a schematic perspective view showing the processing apparatus incorporating with the cup-type abrasive tool 410. As shown in the FIG. 21, a rotating shaft 431 is mounted at one end to the center of the upper surface of the cup-type processing tool 410, and is mounted at the other end to an arm section 401 having a built-in drive mechanism for rotationally driving the rotating shaft 431. A disc-shaped substrate (semiconductor wafer) W is held on a substrate holder 412. In the case of using the apparatus for electrolytic processing, a processing electrode and a feeding electrode, both to be connected to a power source, are mounted in the ring-shaped processing tool. Further, an ion exchanger, or a polishing pad or scrubbing member having electric conductivity and permeability to liquid is used as the processing member.

The substrate holder 412 and the substrate W are set in a table 413 such that they are exposed on the table 413, i.e., the upper surfaces of the substrate holder 412 and the substrate W are almost flush with the upper surface of the table 413.

The table 413 is designed to be movable, together with the substrate holder 412, in a linear direction (direction of arrow J) on a base 403 by a not-shown drive mechanism.

While rotating the substrate holder 412 and the cup-type processing tool 410 independently, the processing member 415 is pressed against the substrate W and the table 413 is moved linearly, whereby processing of the entire surface of the substrate W is effected.

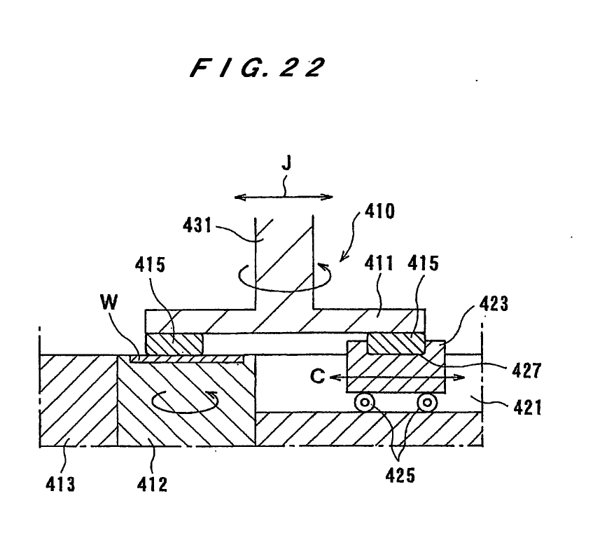

FIG. 22 shows yet another CMP or electrolytic processing apparatus. Also in this processing apparatus, as with the processing apparatus shown in FIG. 21, a substrate (semiconductor wafer) W is held on the substrate holder 412, the substrate holder 412 and the substrate W are exposed on the table 413, and the cup-type processing tool 410 is disposed over the substrate W.

This processing apparatus differs from the apparatus shown in FIG. 21 in that a groove 421, extending in a direction away from the substrate holder 412, is provided in the table 413 and a processing surface regeneration mechanism 423 is housed in the groove 421.

The processing surface regeneration mechanism 423 has wheels (bearings such as magnetic bearings or linear bearings) 425 at the bottom, so that it can move linearly in the direction of arrow C within the groove 421. Further, a recess 427 having the same configuration as the processing member 415 is provided in the upper surface of the processing surface regeneration mechanism 423. The interior surface of the recess 427 functions as follows: When the processing member 415, such as an abrasive wheel or a polishing pad, passes through the recess 427, the surface of the processing member 415 is polished into exactly the same configuration as the configuration of the recess 427. In the case of using an ion exchanger as the processing member 415, metal ions accumulated in the ion exchanger are dissolved out through contact of the ion exchanger with the recess 427.

As with the apparatus shown in FIG. 21, the rotating processing member 415 of the cup-type processing tool 410 is pressed against the substrate W held on the rotating substrate holder 412 while the table 413, holding the substrate holder 412, is moved linearly, thereby processing the substrate W.

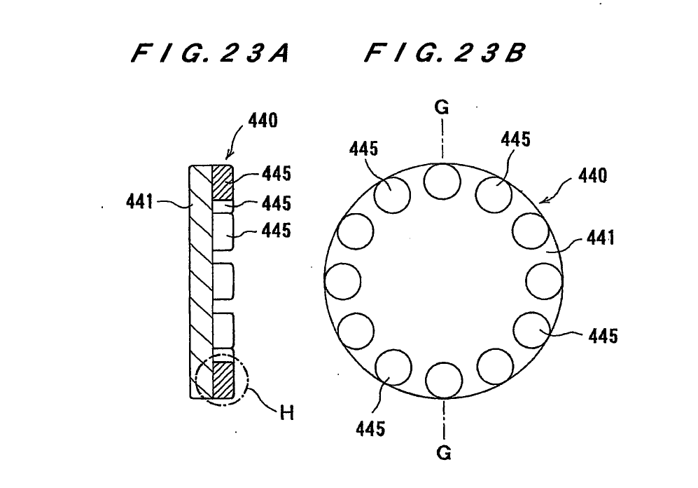

FIGS. 23A and 23B show a cup-type processing tool 440 comprising pellet-like processing members: FIG. 23A is a sectional side view (taken along the line G-G of FIG. 23B); and FIG. 23B is a rear view. As shown in FIGS. 23A and 23B, the cup-type processing tool 440 is comprised of a disc-shaped processing member support member 441, and a plurality (twelve) of pellet-like (columnar) processing members 445 mounted on the lower surface of the support member 441 in a ring or over the entire surface. It is also possible to mount a processing tool, such as an abrasive wheel or a pad, which is of an integral ring shape. In the case of using the apparatus for electrolytic processing, the pellet-like processing members each may be utilized as a processing electrode or a feeding electrode.

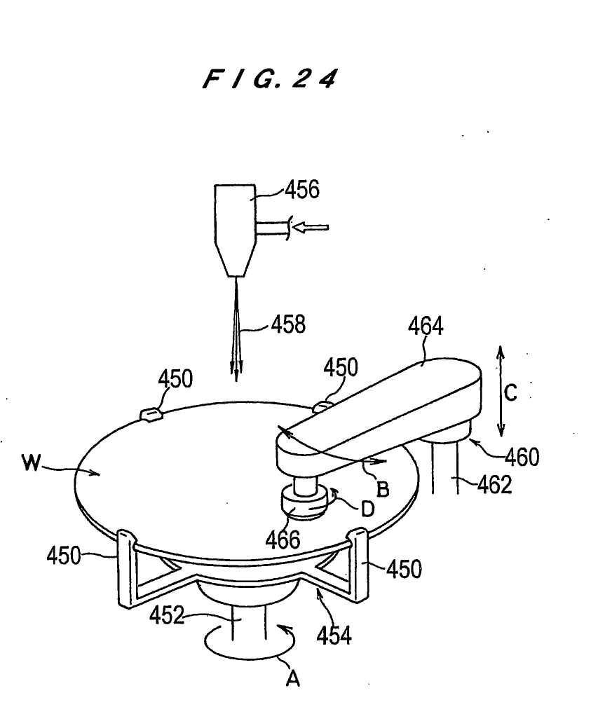

FIG. 24 shows yet another CMP or electrolytic processing apparatus. The processing apparatus includes a rotary chuck 454 having chuck claws 450 for gripping the peripheral end of a substrate W. The rotary chuck 454 rotates about a main shaft 452 in the direction of arrow A. Instead of the rotary chuck 454, other chuck means, such as an electrostatic chuck or a vacuum chuck, may also be employed. The apparatus is provided with a fixed processing liquid nozzle 456 which can jet a processing liquid 458 onto the processing surface (upper surface) of a substrate W. A processing section 460 includes a pivot arm 464 supported on an arm shaft 462, and a processing member (fixed abrasive, polishing pad, ion exchanger or scrubbing member such as a sponge) 466 mounted to the front end of the pivot arm 464. The arm shaft 462 can move vertically as shown by arrow C, and the pivot arm 464 supported on the pivot shaft 462 moves vertically by the vertical movement of the pivot shaft 412 and can pivot by the rotation of the arm shaft 462, as shown by arrow B.

According to the processing apparatus, while rotating the rotary chuck 454 in the direction of arrow A, the processing liquid 458 is jetted from the processing liquid nozzle 456 toward the upper surface of the substrate W held by the rotary chuck 454 and, at the same time, while pivoting the pivot arm 464 in the direction of arrow B and rotating the processing member 466, the processing member 466 is pressed against the upper surface of the substrate W, thereby processing the to-be-processed surface (upper surface) of the substrate W with the processing member 466. In the case of carrying out electrolytic processing by the processing apparatus, the anode of a power source is connected to the chuck claws 450, while the cathode of the power source is connected via the pivot arm 464 to the processing member 466. Electrolytic processing is carried out by bring the processing member 466 also as a processing electrode into contact with a to-be-processed material of a substrate while feeding electricity from the chuck claws 450 to the to-be-processed material via the bevel portion of the substrate. It is also possible to supply a processing liquid, such as a polishing liquid, from the interior of the processing member 466, such as an abrasive wheel or a pad.

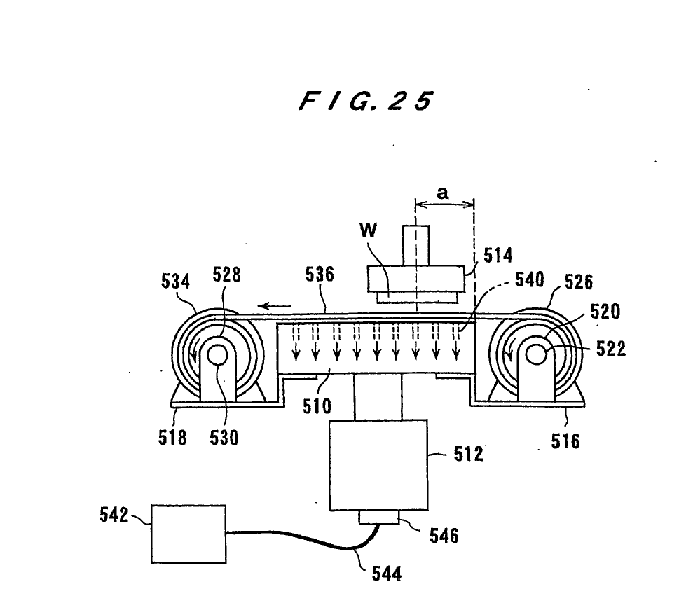

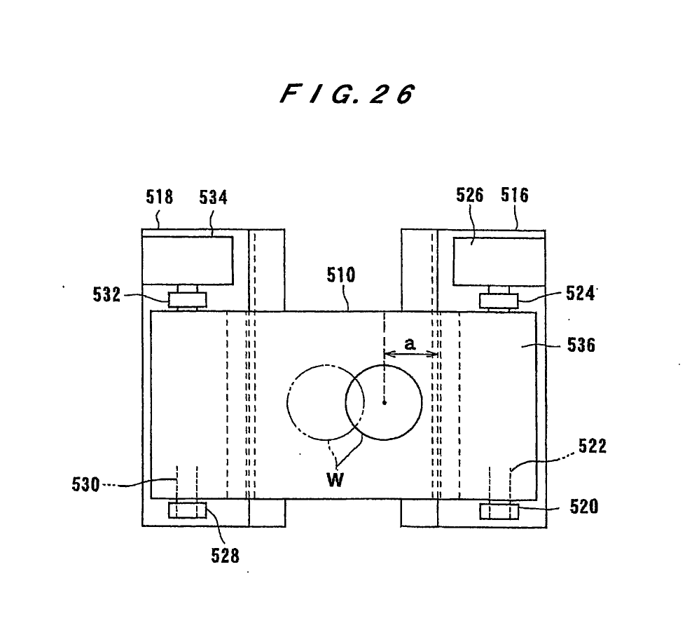

FIGS. 25 and 26 show yet another CMP or electrolytic processing apparatus according. As shown in FIGS. 25 and 26, a processing apparatus comprises a rectangular planar processing table 510, a table-rotating motor 512 for rotating the processing table 510, and a top ring 514 vertically movably disposed above the processing table 510 for detachably holding a substrate W such as a semiconductor wafer with its surface, to be polished,. facing the processing table 510.

Support plates 516, 518 are attached to the lower surfaces on opposite sides of the processing table 510. One support plate 516 supports a bearing 520 on its upper surface. An supply roll 522 has an end rotatably supported by the bearing 520, and an opposite end connected by a coupling 524 to a supply roll motor 526 that is supported on the upper surface of the support plate 516. When the supply roll motor 526 is energized, the supply roll 522 is rotated about its own axis. The other support plate 518 supports a bearing 528 on its upper surface. An take-up roll 30 has an end rotatably supported by the bearing 528 and an opposite end connected by a coupling 532 to a take-up roll motor 534 that is supported on the upper surface of the support plate 518. When the take-up roll motor 534 is energized, the take-up roll 530 is rotated about its own axis.

A processing member 536, such as elongated polishing pad or ion exchanger, sheet-like fixed abrasive, or a scrubbing member, is wound onto the supply roll 522, extends along the upper surface of the processing table 510, and has a free end detachably gripped by the take-up roll 530. When the supply roll motor 526 and the take-up roll motor 534 are energized, the supply roll 522 and the take-up roll 530 are synchronously rotated about their own axes in one direction to cause the processing member 536 to travel from the supply roll 522 along the upper surface of the processing table 510 toward the take-up roll 530 onto which the processing member 536 is wound. The tension of the processing member 536 between the supply roll 522 and the take-up roll 530 can be adjusted by regulating the rotational speeds of the supply roll 522 and the take-up roll 530. The processing member 536 can be returned from the take-up roll 530 toward the supply roll 522 when the supply roll 522 and the take-up roll 30 are reversed.

The processing table 510 has an attraction section 540 for attracting the processing member 536 under vacuum to the upper surface of the processing table 510. The attraction section 540 comprises a plurality of vacuum holes which are formed in the processing table 510, and are open at the upper surface of the processing table 510 and connected to a vacuum source such as a vacuum pump. A rotary joint 546 which connects a cable 544 extending from a controller 542 and cables extending respectively from the supply roll motor 526 and the take-up roll motor 534 is attached to the table-rotating motor 512. The controller 542 controls the supply roll motor 526 and the take-up roll motor 534, respectively. The controller 542 maybe arranged to control the supply roll motor 526 and the take-up roll motor 534 in a wireless fashion.

According to the embodiment, while the processing table 510 and the top ring 514 are being rotated independently about their own axes, the substrate W is pressed against the processing member 536 under a constant pressure by the top ring 514, and a processing liquid such as abrasive liquid is supplied from a nozzle (not shown) to the processing member 536, thereby polishing the surface of the substrate W to be processed to a flat mirror finish. At this time, the processing member 536 is attracted to and held by the upper surface of the processing table 536 under vacuum. Therefore, the processing member 536 is prevented from being displaced with respect to the processing table 510 while the substrate W is being polished thereby.

For polishing an oxide film on the substrate W, for example, the abrasive liquid comprises a silica slurry such as SS-25 (manufactured by Cabbot), a CeO₂ slurry, or the like. For polishing a tungsten film on the substrate W, for example, the abrasive liquid comprises a silica slurry such as W2000 (manufactured by Cabbot) containing an H₂O₂ as an oxidizing agent, an alumina-base slurry of iron nitrate, or the like. For polishing a copper film on the substrate W, for example, the abrasive liquid comprises a slurry containing an oxidizing agent, such as H₂O₂ for turning the copper film into an oxide copper film, a slurry for polishing a barrier layer, or the like. In order to remove particles or defects from the substrate being polished, surfactant or alkali solution as a polishing liquid may be supplied halfway for conducting a finish polishing.

A polishing pad made of foamed polyurethane such as IC1000 or a suede-like material such as Polytex is used as the processing member 536. In order to increase the resiliency of the polishing pad (processing member) 536, the polishing pad 536 may be lined with a layer of nonwoven cloth or sponge, or a layer of nonwoven cloth or sponge may be attached to the upper surface of the processing table 510.

The processing member 536 may comprise a fixed abrasive pad comprising particles of CeO₂, silica, alumina, SiC, or diamond embedded in a binder, so that the processing member 536 can polish the substrate W while not a abrasive liquid but a polishing liquid containing no abrasive particles is being supplied thereto. An ammeter, a vibrometer, or an optical sensor may be incorporated in the processing table 510 and/or the top ring 514 for measuring the state of the substrate W while the substrate W is being polished.

When the region of the processing member 536 which has been used is worn to the extent that its processing capability can no longer be restored by a dresser, the controller 542 sends a signal to energize the supply roll motor 526 and the take-up roll motor 534 to rotate the supply roll 522 and the take-up roll 530, respectively, in synchronism with each other in one direction. Thus, the processing member 536 travels from the supply roll 522 toward the take-up roll 530 along the upper surface of the processing table 510. After the processing member 536 has traveled a predetermined distance the processing member 536 is stopped.

Even when the processing table 510 is in rotation, the worn region of the processing member 536 can be automatically replaced with a new region thereof by transporting the processing member 536 from the supply roll 522 toward the take-up roll 530 over the upper surface of the processing table 510 by the predetermined distance corresponding to the length of the processing table 510, i.e. one pad and then stopping the processing member 536. Alternatively, the processing member 536 may be wound onto the take-up roll 530 by the distance “a”, shown in FIG. 25, corresponding the distance from the end of the processing table 510 to the center of the substrate W located at the polishing position. Thus, a new processing member and a used processing member are simultaneously brought into connect with different regions in a radial direction of the substrate W for thereby imparting a processing (polishing) action equally to the entire surface of the substrate W.

The processing member 536 and the supply roll 522 may be integrally combined into a cartridge, so that they can be quickly installed and removed between the bearing 520 and the coupling 524. The supply roll motor 526 may be eliminated, and the processing member 536 may be supplied from the supply roll 522 toward the take-up roll 530 only by the take-up roll motor 534. The processing table 510 may be of a circular shape.

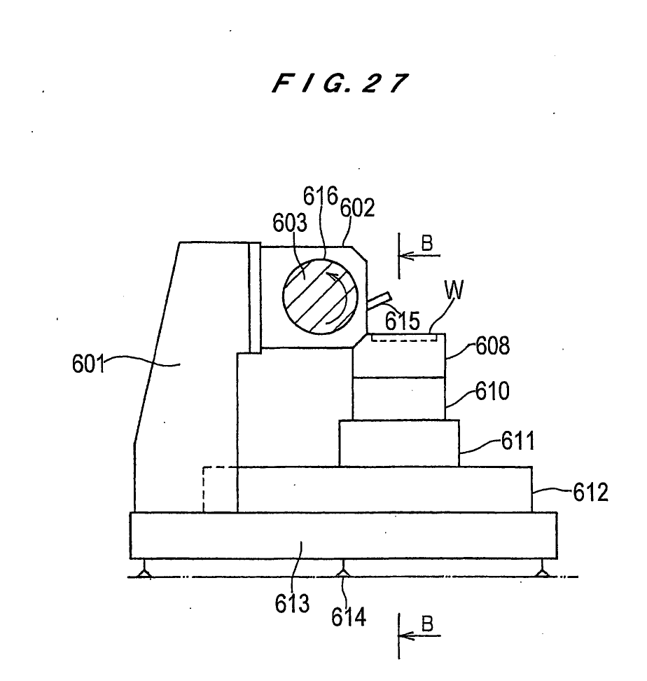

FIGS. 27 through 31 show yet another CMP or electrolytic processing apparatus. The processing apparatus includes a rotary drum 603 with a processing member 616, holding a processing liquid, mounted on the surface. A polishing pad, a fixed abrasive or an ion exchanger, for example, is used as the processing member 616. The rotating shaft of the drum 603 is supported by bearings 604, 605 in a drum head 602, and the drum 603 is rotationally driven by a drum motor 606. The drum head 602 is fixed to a base 613 by columns 601. A substrate W as a processing object is placed on a seat 608 and is fixed by vacuum attraction. The seat 608 is fixed to a Y-table 611 via a follow-up mechanism 610. The Y-table 611 is provided with a drive mechanism that moves the substrate W in a Y-direction (the same direction as the central axis of the drum). An X-table 612 is fixed on the base 612. The X-table 612 is provided with a drive mechanism that moves the substrate W in an X-direction (direction perpendicular to the central axis of the drum) over the full length of the processing object. The base 613 is fixed to the installation floor via levelers 614. The levelers 614 are used to keep the processing surface of the substrate W as a processing object horizontally. A processing liquid, such as a slurry containing abrasive grains, an electrolytic solution or pure water, is supplied from a processing liquid supply pipe 615 to the processing member 616 on the surface of the drum 603, and the processing liquid is held in the processing member 616. By rotating the drum 603, the substrate W is processed at the portion in contact with the drum 603.

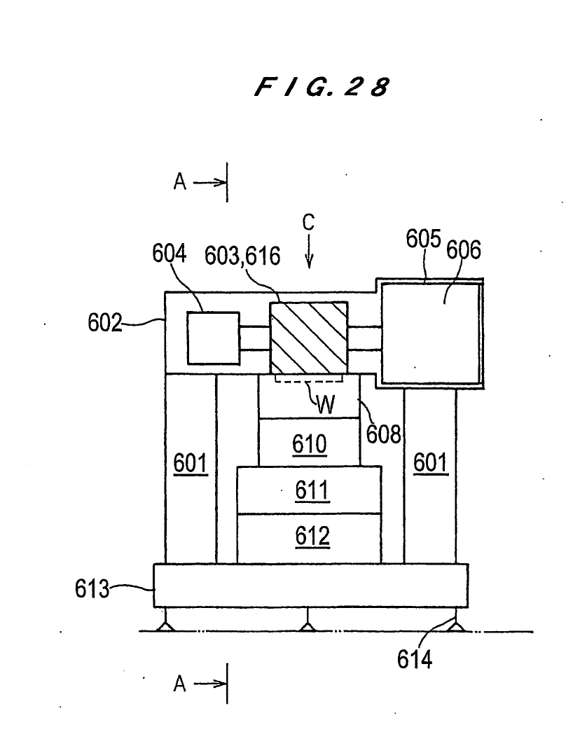

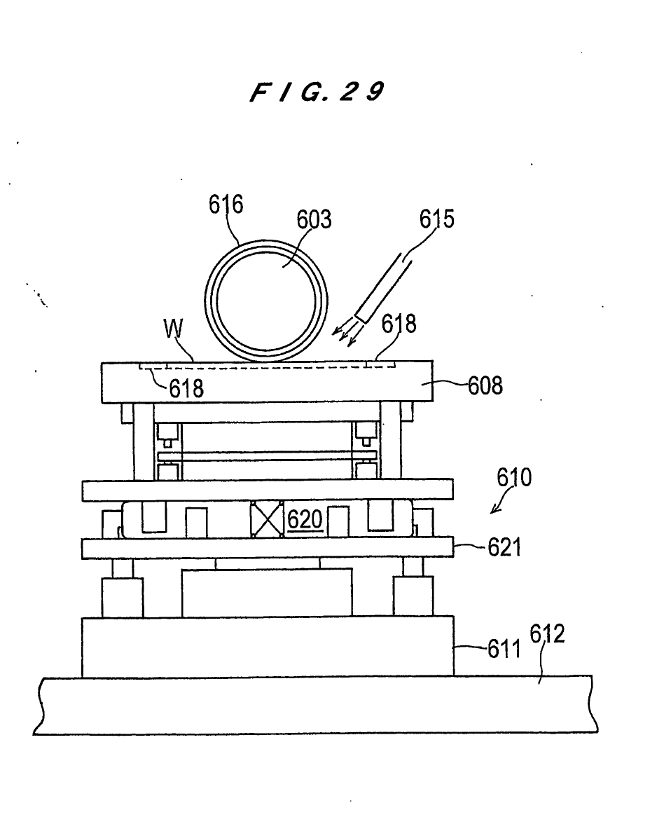

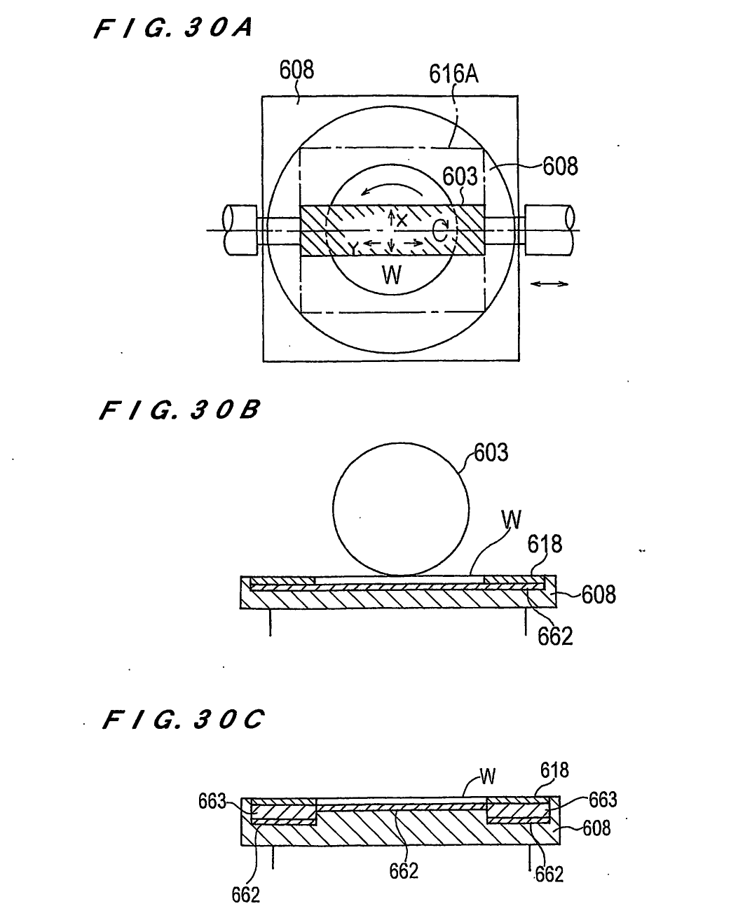

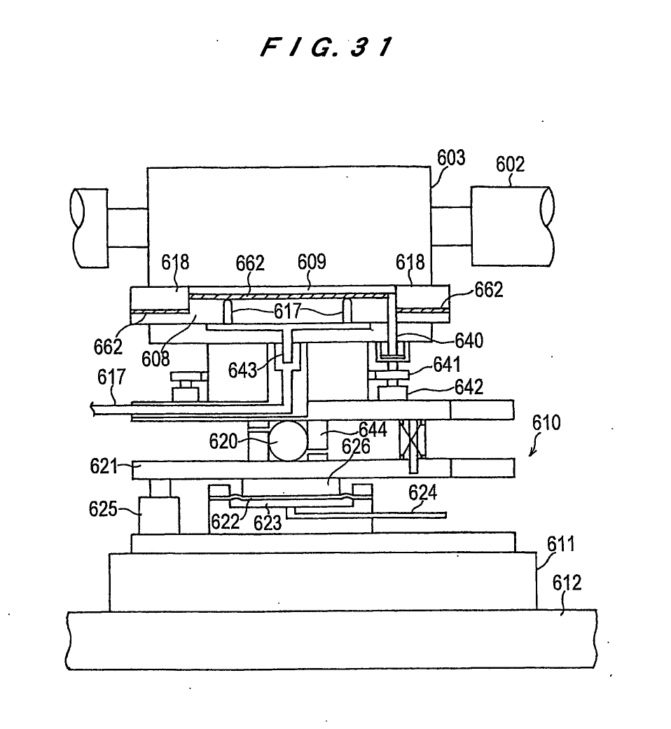

FIG. 29 is a cross-sectional view taken along the line A-A of FIG. 28, FIG. 30A shows the processing apparatus of FIG. 28 as viewed from arrow C, FIGS. 30B and 30C are sectional side views of FIG. 30A, and FIG. 31 is a cross-sectional view taken along the line B-B of FIG. 27.

As shown in FIGS. 30 and 31, the processing apparatus is provided with a sacrificial plate 618 for protecting the peripheral portion of a substrate W.

In processing a circular substrate W, such as a semiconductor wafer, by a processing apparatus that employs a rotary drum, when a processing member on the drum moves from the outside of the substrate W to the inside, the processing member passes the step at the peripheral end of the substrate W. Upon passing the step, the processing member receives a strong compressing force locally by the peripheral end of the substrate W, whereby a processing liquid or abrasive grains held on the surface or in the interior of the processing member are squeezed out and the surface conditions of the processing member can be changed, leading to non-uniform processing performance of the processing member and poor flatness of the processed surface.

The sacrificial plate 618 has a to-be-processed surface which is on the same level as or slightly lower than the to-be-processed surface of the substrate W, and is fixed to the peripheral end of the substrate W on the seat 608. A hardly polishable hard ceramic, glassy carbon, stainless steel, an electrically conductive material, etc. may be used as the material of the sacrificial plate 618. Upon processing of the surface of the substrate W, the pressure of the drum is also applied on the sacrificial plate 618, and the surface of the sacrificial plate 618 is processed simultaneously with processing of the peripheral end portion of the substrate. This solves the problem of excessive processing of only the peripheral end portion of the substrate W. The sacrificial plate 618 preferably has such a size as to fully cover the moving area 616A of the processing member in order to avoid a harmful influence of the peripheral end of the sacrificial plate 618 on the processing member.

FIG. 30B shows the case of mounting both the substrate W and the sacrificial plate 618 on the same plane on the seat 608. In case the sacrificial plate 618 has a low strength material and is easy to break when a pressure is applied, a reinforcing plate 663 made of e.g. plastic may be placed underneath the sacrificial plate 618 as shown in FIG. 30C.

As illustrated in the cross-sectional views of FIGS. 30B and 30C, an elastic member 662 of about 0.6 mm in thickness, made of e.g. rubber or backing film, is interposed between the seat 608 and both the substrate W and the sacrificial plate 618 (or the reinforcing plate 663). The thickness of the substrate W itself varies over several tens μm, and it is impossible to perfectly match the levels of the sacrificial plate 662 and the substrate W. A step created by such a small difference in the height between the sacrificial plate 662 and the substrate W is sufficient to adversely affect the processing member when the sacrificial plate 662 and the substrate W are placed directly on the seat 608, so that a flat processed surface cannot be obtained. This is especially true when a high processing pressure is employed during processing in order to increase the processing rate.

By inserting the elastic member 662 under the substrate W and the sacrificial plate 618, the effect of the step created by the height difference between the substrate W and the sacrificial plate 618 can be moderated to improve the flatness of the processed surface.

The substrate W as a processing object is held on or detached from the seat 608 by a vacuum/pressure pipe 617 shown in FIG. 31. During processing, the substrate W is held on the seat 608 by vacuum attraction, and when processing is completed the substrate W is detached from the seat 608 by use of pressurized air. The substrate W can be lifted by substrate push-up pins 640 fixed to a push-up ring 641 when the push-up ring 641 is lifted by a cylinder 642, thereby detaching the substrate W tightly held on the seat 608.

The seat 608 is designed to be rotatable by a rotary joint 643, and the substrate W can be rotated about its axis by a not-shown driving mechanism.

The processing apparatus of the embodiment is provided with two types of follow-up mechanisms to enable the substrate to be processed against the rotating drum at a uniform pressure. The first follow-up mechanism is shown in the cross-sectional view of FIG. 31, and comprises a rod-shaped support member 620, having a circular cross-section, supporting the seat 608 from below, disposed perpendicular to the drum axis and parallel to the surface of the seat 608. The follow-up mechanism operates when the parallelism between the drum axis and the substrate W as a processing object is lost for any reason. By rolling of the rod-shaped support member 620, the seat 608 rotates slightly to realign the to-be-processed surface of the substrate W parallel to the drum axis so as to equalize the pressure on the substrate W. Therefore, the substrate W can be pressed against the rotating drum 603 at a uniform pressure over the entire contact area. This enables a uniform mirror processing. Members 644 are used to prevent escape of the rod-shaped support member 620.

The second follow-up mechanism comprises a diaphragm 622, to which a bottom portion of an elevating seat 621 is fixed, and an air cushion supporting the diaphragm 622. The elevating seat 621 is vertically movable by a guide 625. The lower surface of the elevating seat 621 is fixed to the diaphragm 22 via a connecting member 626. A space 623 beneath of the diaphragm 622 serves as an air cushion with compressed air supplied from an air pipe 624. The air cushion provides a uniform pressure over the entire area of the diaphragm 622. Accordingly, through the elevating seat 621, a uniform pressure can be applied from the substrate W to the rotating drum 603. This enables uniform mirror processing over the entire surface of the processing object. The first follow-up mechanism device provides a line support parallel to the axis of the round rod-shaped member, while the second follow-up mechanism provides an a real support over the entire area of the diaphragm. The combination of the two mechanisms makes it possible to provide a uniform pressure on the entire surface of the processing object.

The elevating seat 621 can be moved up and down widely by a not-shown air cylinder. The vertical movement e.g. for a change of the substrate W as a processing object is effected by raising or lowering the diaphragm 622 by adjusting the air cushion 623. A wider movement e.g. for maintenance operations is effected by raising or lowering the elevating seat 621 by the not-shown cylinder.

The processing apparatus enables significant reduction of the overall size of the apparatus, because the installation space only needs to be large enough to accommodate the drum 603 and the moving mechanism for the seat 608 with the substrate W mounted thereon, as shown in FIG. 30. Further, the processing apparatus enables observation of the surface being processed from above the processing object, thus enabling checking of the film thickness removed or to be removed during polishing.

In this embodiment, the position of the rotary drum 603 is fixed, while the seat 608 with the substrate W mounted thereon is moved to mirror processing over the entire surface of the substrate W as a processing object. However, it is clear that the same objective of effecting uniform processing of the entire surface of the substrate can be achieved by moving the rotary drum while fixing the seat. It is also possible to provide the follow-up mechanisms on the rotary drum side. In the case of using the processing apparatus for electrolytic processing, the rotary drum 603 is connected to a power source, and a plurality of cathode electrodes and anode electrodes are disposed alternately on the rotary drum 603.

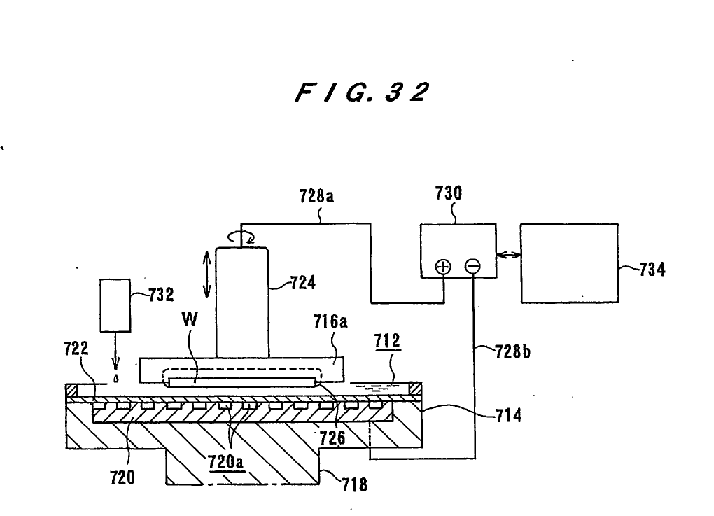

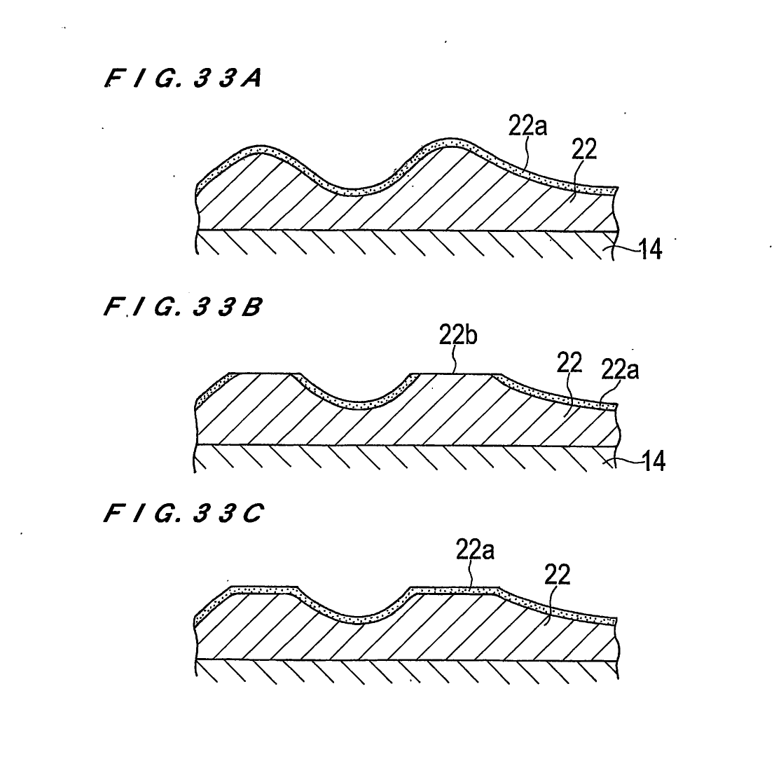

FIG. 32 shows a composite electrolytic processing apparatus. The composite electrolytic processing apparatus includes an upwardly-open bottomed cylindrical electrolytic bath 714 for holding an electrolytic solution 712 therein, and a substrate holder 716a, provided above the electrolytic bath 714, for detachably holding a substrate W with its front surface facing downward. The electrolytic solution 712 contains an oxidizing agent or chelating agent and abrasive grains.

The electrolytic bath 714 is directly coupled to a main shaft 718 that rotates by the actuation of a motor or the like, and is provided at the bottom with a horizontally-disposed tabular cathode plate 720 which is made of a metal that is stable to the electrolytic solution and is not passivated by electrolysis, such as SUS, Pt/Ti, Ir/Ti, Ti, Ta or Nb, and which is to be immersed in the electrolytic solution 712 and become a cathode. In the upper surface of the cathode plate 720, there are provided a lattice-form of long grooves 720a extending linearly and crosswise over the full length of the cathode plate 720. Further, a polishing tool 722, for example, a continuous-foam, hard polishing pad of a nonwoven fabric type (e.g. SUBA800 manufactured by Rodel Nitta Company) is attached to the upper surface of the cathode plate 720.

By rotation of the main shaft 718, the electrolytic bath 714 rotates together with the polishing tool 722. As the electrolytic solution 712 is supplied, the electrolytic solution 712 flows through the long grooves 720a, and products produced during electrolytic polishing, hydrogen gas, oxygen gas, etc. also pass through the long grooves 720a and are discharged out from between the substrate W and the polishing tool 722.

Though the electrolytic bath 714 is allowed to rotate according to this embodiment, it is also possible to allow the electrolytic bath 714 to make a scroll movement (translational rotation) or a reciprocating movement. The long grooves 720a are preferably arranged in a lattice form in the case where the electrolytic bath 714 makes a scroll movement, in order to prevent a current density difference between the central portion and the peripheral portion of the cathode plate 720 and allow the electrolytic solution, hydrogen gas, etc. to flow smoothly along the long grooves 720a. In the case where the electrolytic bath 714 makes a reciprocating movement, the grooves 720a are preferably arranged in parallel in the moving direction.

The substrate holder 716a is connected to the lower end of a support rod 724 which is provided with a rotating mechanism that can control rotational speed and a lifting mechanism that can adjust polishing pressure, and the substrate holder 724 attracts and holds the substrate W in a vacuum-attraction manner on its lower surface.

At a peripheral portion of the lower surface of the substrate holder 716a, there are provided electrical contacts 726 which, when the substrate W is attracted and held by the substrate holder 716a, contact a peripheral or bevel portion of the substrate W to make copper 22 (see FIG. 6A) deposited on the surface of the substrate W an anode. The electrical contacts 726 are connected, via a roll sliding connector built-in the support rod 724 and a wire 728a, to the anode terminal of an externally-disposed rectifier 730 as a direct-current and pulse-current power source, and the cathode plate 720 is connected via a wire 728b to the cathode terminal of the rectifier 730.

The rectifier 730 is e.g. of low-voltage design, and one with a capacity of about 15V×20 A may be used for an 8-inch wafer and one with a capacity of about 15V×30 A may be used for a 12-inch wafer. The frequency of pulse current may range from normal frequency to msec.

Further, positioned above the electrolytic bath 714, an electrolytic solution supply unit 732 for supplying the electrolytic solution 712 into the electrolytic bath is provided. The apparatus is also provided with a control unit 734 for adjusting and managing the devices and the overall operation, and with a safety device (not shown).

The processing (polishing) operation of the composite electrolytic processing apparatus will now be described.

The electrolytic solution 712 is supplied into the electrolytic bath 714 and the electrolytic solution 712 is allowed to overflow the electrolytic bath 714, while the electrolytic bath 714 is rotated together with the polishing tool 722 at a rotating speed of e.g. about 90 rpm. On the other hand, the substrate W, which has undergone plating such as copper plating, is attracted and held with its front surface facing downward by the substrate holder 716a. While rotating the substrate W in the opposite direction to the electrolytic bath 714 at a rotating speed of e.g. about 90 rpm, the substrate W is lowered so as to bring the surface (lower surface) of the substrate W into pressure contact with the surface of the polishing tool 722 at a constant pressure of e.g. about 300 g/cm² and, at the same time, a direct current, or a pulse current e.g. of a repetition of 10×10⁻³ second current passing and 10×10⁻³ second stoppage and creating a current density, per surface area of copper on the substrate, of e.g. about 1-4 A/dm², is passed between the cathode plate 720 and the electrical contacts 726 by the rectifier 730.

The copper 22 (see FIG. 6A) is effectively polished into flatness at a higher rate than the conventional technique. In this regard, when the copper 22 is electrolytically polished using the electrolytic solution 712 containing an oxidizing agent or chelating agent and abrasive grains, and utilizing the copper 22 as an anode, a passivated film (chelate film) 22a is formed in the surface of copper 22, as shown in FIG. 33A. The passivated film 22a is quite fragile mechanically and can be easily polished away with a rotating low-pressure polishing tool. Accordingly, when carrying out polishing using the polishing tool 722, the passivated film 22a formed in the surface of raised portions of copper 22 is mainly polished away as shown in FIG. 33B, and the copper 22 becomes exposed at the polished portions. The passivated film 22a has a relatively high electric resistance, and therefore passing of electric current to the portions covered with the passivated film 22a is inhibited and the electric current is likely to concentrate on the metal-exposed portions 22b. Accordingly, as shown in FIG. 33C, a new passivated film 22a immediately forms in the polished exposed surface of copper 22 and, as described above, the newly-formed passivated film 22a is mainly polished away. The surfaces of depressed portions of copper film 22, therefore, remain covered with the passivated film 22a, and polishing of such portions is inhibited. Accordingly, only the raised portions of copper 22 are selectively polished away.

The apparatus shown in FIG. 32 can be used for pure water electrolytic processing using a catalyst. In that case, a liquid having an electric conductivity of not more than 500 μS/cm, such as ultrapure water, may be used instead of the electrolytic solution 712, and an ion exchanger may be used instead of the polishing tool 722. The manner of operation is the same as the above-described composite electrolytic processing.

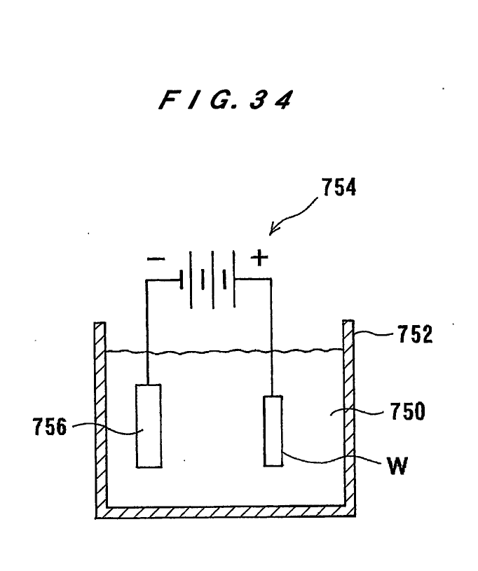

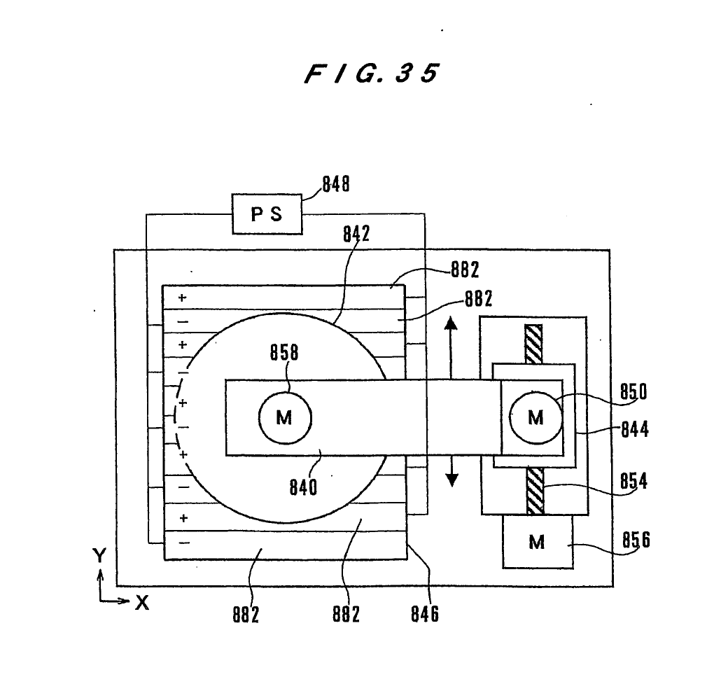

FIG. 34 schematically shows an electrolytic processing apparatus for carrying out a common electrolytic processing not involving contact between a substrate and a tool. The electrolytic processing apparatus includes a tank 752 for holding a liquid electrolyte 750, i.e., an aqueous solution of a salt. The anode of a power source 754 is connected to copper 22 (see FIG. 6A) of a substrate W as a processing object, while the cathode is connected to a cathode plate 756 disposed opposite the substrate W. When passing electricity between copper 22 of the substrate W and the cathode plate 756, the metal atoms of copper 22 are ionized by electricity and dissolved into the solution. The copper 22 is thus dissolved into the solution (electrolytic solution). The rate of dissolution is proportional to the current, according to Faraday's Law. Depending upon the chemical reaction between copper 22 and the salt, the metal ions from the anode (copper) is plated on the cathode plate 756, precipitated as a deposit, or remains as they are in the solution.

The cathode plate 756, which is a molded tool, is moved close to copper 22 of the substrate W as a processing object, while an electrolyte is supplied by a pump and passed through the space between the electrodes. The cathode plate 756 corresponds to a cutting blade of a machine tool. As the processing proceeds, the copper 22 of the substrate W resembles the figure of the cathode plate 756. The processing rate is proportional to the distance between the cathode plate 756 and the substrate W. Since the electrodes do not contact each other, the cathode plate 756 does not wear.

According to the electrolytic processing, removal of the metal (copper) is effected merely by moving slowly the cathode 756 close to the substrate W. The rate of dissolution of the metal (copper) reaches the maximum when the cathode plate 756 is closest to the substrate W, and decreases as the electrode spacing increases. This is due to the influence of the electric field.

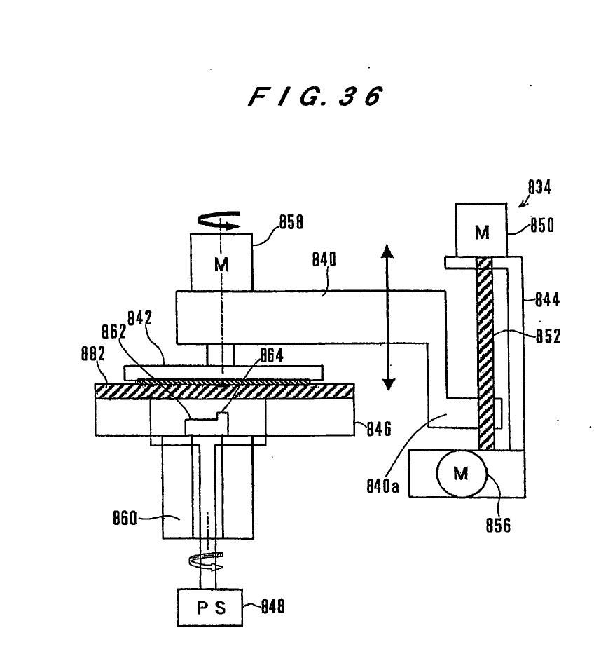

FIGS. 35 through 39 show an electrolytic processing apparatus which is replaceable with the substrate head 82 having the substrate holder 60 and with the electrolytic processing section 64, both shown in FIG. 3. As shown in FIGS. 35 and 36, the electrolytic processing apparatus includes an arm 840 which is movable vertically and pivotable horizontally, a substrate holder 842, mounted vertically to the free end of the arm 840, for attracting and holding a substrate W facing downward (face down), a movable frame 844 to which the arm 840 is mounted, a rectangular electrode section 846, and a power source 848 to be connected to the electrode section 846.

A vertical-movement motor 850 is mounted on the upper end of the moveable flame 844. A ball screw 852, which extends vertically, is connected to the vertical-movement motor 850. The base 840a of the arm 840, which moves up and down via a ball screw 852 by the actuation of the vertical-movement motor 850, is connected to the ball screw 852. The moveable flame 844, which itself moves back-and-forth in a horizontal plane with the arm 840 by the actuation of a reciprocating motor 856, is connected to a ball screw 854 that extends horizontally.

The substrate holder 842 is connected to a substrate-rotating motor 58 supported at the free end of the arm 840. The substrate holder 842 is rotated by the actuation of the substrate-rotating motor 858. The arm 840 can move vertically and make a reciprocation movement in the horizontal direction, as described above, the substrate holder 842 can move vertically and make a reciprocation movement in the horizontal direction integrated with the arm 840.

The hollow motor 860 is disposed below the electrode section 846. A drive end 864 is formed at the upper end portion of the main shaft 862 and arranged eccentrically position to the center of the main shaft 862. The electrode section 846 is rotatably coupled to the drive end 864 via a bearing (not shown) at the center portion thereof. Three or more of rotation-prevention mechanisms (not shown) are provided in the circumferential direction between the electrode section 846 and the hollow motor 860.

By the actuation of the hollow motor 860, the electrode section 846 makes a revolutionary movement with the distance between the center of the main shaft 862 and the drive end 864 as the radius, without rotation about its own axis, a so-called scroll movement (translational rotation).

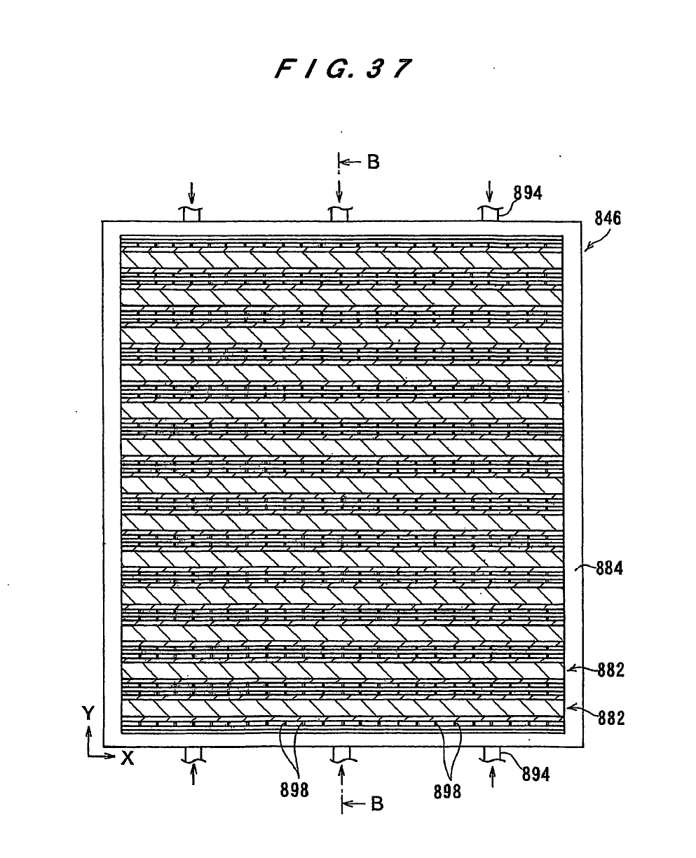

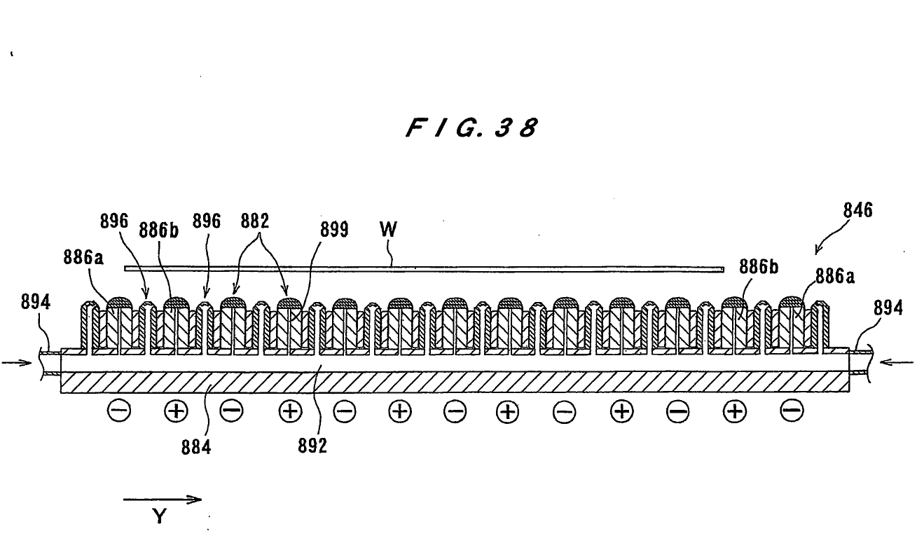

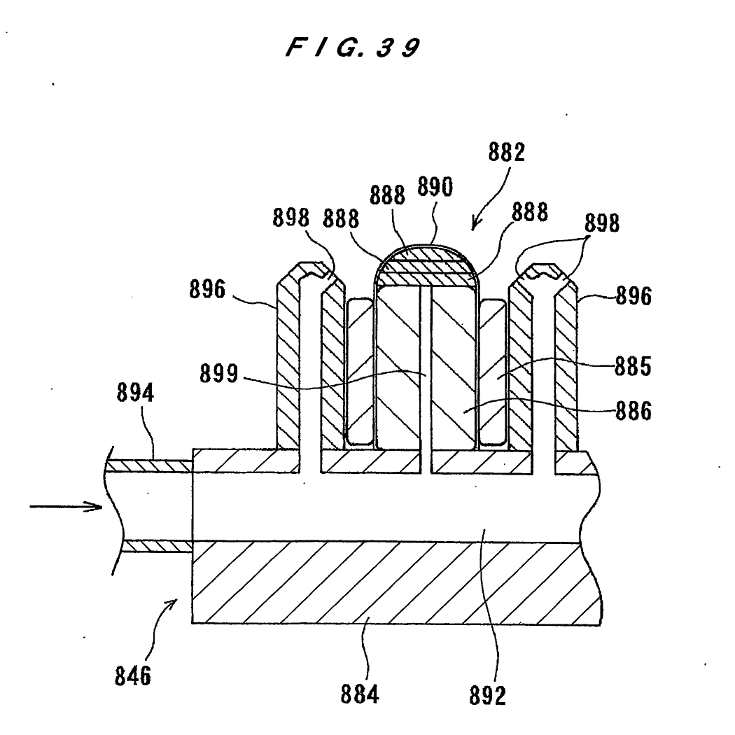

The electrode section 846 includes a plurality of electrode members 882. FIG. 37 is a plan view of the electrode section 846, FIG. 38 is a sectional view taken along the line B-B of FIG. 37, and FIG. 39 is an enlarged view of a portion of FIG. 38. As shown in FIGS. 37 and 38, the electrode section 846 includes a plurality of electrode members 882 extending in the X direction (see FIGS. 35 and 37), and the electrode members 882 are disposed in parallel on a tabular base 884.

As shown in FIG. 39, each electrode member 882 comprises an electrode 886 to be connected to the power source 848 (see FIG. 35), an ion exchanger 888 superimposed on the upper surface of the electrode 886, and an ion exchanger (ion exchange membrane) 890 covering the surfaces of the electrode 886 and the ion exchanger 888 integrally. The ion exchanger 890 is mounted to the electrode 886 by holding plates 885 disposed on both sides of the electrode 886.

It is preferred to use as the ion exchanger 888 an ion exchanger having a large ion exchange capacity. According to this embodiment, the ion exchanger 888 has a multi-layer structure of a laminate of three 1 mm-thick C membranes (nonwoven fabric ion exchangers), and thus has an increased total ion exchange capacity. The use of such an ion exchanger 888 can prevent the processing products (oxides and ions) produced by the electrolytic reaction from accumulating in the ion exchanger 888 in an amount exceeding the accumulation capacity of the ion exchanger 888. This can prevent the processing products accumulated in the ion exchanger 888 from changing their forms and adversely affecting the processing rate and its distribution. Further, an ion exchange capacity enough for treating a desired processing amount of a processing object can be secured. The ion exchanger 888 may be of a single membrane, when its ion exchange capacity is sufficiently high.

It is preferred that at least the ion exchanger 890 to be opposed to a processing object has a high hardness and a good surface smoothness. According to this embodiment, Nafion (trademark, DuPont Co.) with a thickness of 0.2 mm is employed. The term “high hardness” herein means high rigidity and low modulus of elasticity against compression. A material having a high hardness, when used in processing of a processing object having fine irregularities in the surface, such as a patterned wafer, hardly follows the irregularities and is likely to selectively remove the raised portions of the pattern. The expression “has a surface smoothness” herein means that the surface has few irregularities. An ion exchanger having a surface smoothness is less likely to contact the recesses in the surface of a processing object, such as a patterned wafer, and is more likely to selectively remove the raised portions of the pattern. By thus combing the ion exchanger 890 having a surface smoothness with the ion exchanger 888 having a large ion exchange capacity, the defect of small ion exchange capacity of the ion exchanger 890 can be compensated for by the ion exchanger 888.

It is preferable to use an ion exchanger having good water permeability as the ion exchanger 890. By allowing pure water or ultrapure water to flow within the ion exchanger 890, a sufficient amount of water can be supplied to a functional group (sulfonic acid group in the case of an ion exchanger carrying a strongly acidic cation-exchange group) thereby to increase the amount of dissociated water molecules, and the process product (including a gas) formed by the reaction with hydroxide ions (or OH radicals) can be removed by the flow of water, whereby the processing efficiency can be enhanced. The flow of pure water or ultrapure water is thus necessary, and the flow of water should desirably be constant and uniform. The constancy and uniformity of the flow of water lead to constancy and uniformity in the supply of ions and the removal of the process product, which in turn lead to constancy and uniformity in the processing.

Such the ion exchangers 888, 890 may be composed of a nonwoven fabric which has an anion-exchange group or a cation-exchange group. A cation exchanger preferably carries a strongly acidic cation-exchange group (sulfonic acid group); however, a cation exchanger carrying a weakly acidic cation-exchange group (carboxyl group) may also be used. Though an anion exchanger preferably carries a strongly basic anion-exchange group (quaternary ammonium group), an anion exchanger carrying a weakly basic anion-exchange group (tertiary or lower amino group) may also be used.

According to this embodiment, the electrodes 886 of adjacent electrode members 882 are connected alternately to the cathode and to the anode of the power source 848. For example, the electrode 886 to become a processing electrode 886a (see FIG. 38) is connected to the cathode of the power source 848, and the electrode 886 to become a feeding electrode 886b (see FIG. 38) is connected to the anode of the power source 848. When processing copper, for example, the electrolytic processing action occurs on the cathode side, and therefore the electrode 886 connected to the cathode becomes a processing electrode 886a, and the electrode 886 connected to the anode becomes a feeding electrode 886b. Thus, according to this embodiment, the processing electrodes 886a and the feeding electrodes 886b are disposed in parallel and alternately.

By thus providing the processing electrodes and the feeding electrodes alternately in the Y direction of the electrode section 846 (direction perpendicular to the long direction of the electrode members 882), provision of a feeding section for feeding electricity to the conductive layer 22 (to-be-processed material) (shown in FIG. 6A) of the substrate W is no longer necessary, and processing of the entire surface of the substrate becomes possible. Further, by changing the positive and negative of the voltage applied between the electrodes 886, 886 in a pulse form, it becomes possible to dissolve the electrolysis products, and improve the flatness of the processed surface through the multiplicity of repetition of processing.

As shown in FIG. 38, a flow passage 892 for supplying pure water, more preferably ultrapure water, to the to-be-processed surface is formed in the interior of the base 884 of the electrode section 846, and the flow passage 892 is connected to a pure water supply source (not shown) via a pure water supply pipe 894. On both sides of each electrode member 882, there are provided pure water jet nozzles 896 for jetting the pure water or ultrapure water supplied from the flow passage 892 to between the substrate W and the ion exchangers 890 of the electrode members 882. In each pure water jet nozzle 896, a plurality of jet orifices 898 are provided along the X direction (see FIG. 37) for jetting pure water or ultrapure water toward the to-be-processed surface of the substrate W facing the electrode members 882, i.e., the portion of the substrate W in contact with the ion exchangers 890. Pure water or ultrapure water in the flow passage 892 is supplied from the jet orifices 898 of the pure water jet nozzles 896 to the entire to-be-processed surface of the substrate W. As shown in FIG. 39, the height of each pure water jet nozzle 896 is lower than the height of the ion exchanger 890 of each electrode member 882, so that the top of the pure water jet nozzle 896 does not contact the substrate W upon contact of the substrate W with the ion exchanger 890 of the electrode member 882.

Through-holes 899, which extend to the ion exchangers 888 from the flow passage 892, are formed in the interior of the electrodes 886 of the electrode members 882. With such a construction, pure water or ultrapure water in the flow passage 892 is supplied to the ion exchangers 888 through the through-holes 899.

Next, substrate processing (electrolytic processing) by using the electrolytic processing apparatus of this embodiment will be described. First, the arm 840 is moved to move the substrate holder 842 holding the substrate W to a processing position right above the electrode section 846. Next, the vertical-movement motor 850 is driven to lower the substrate holder 842 so as to bring the substrate W held by the substrate holder 842 close to or into contact with the surface of the ion exchangers 890 of the electrode section 846. Thereafter, the substrate-rotating motor 858 is driven to rotate the substrate W and, at the same time, the hollow motor 860 is driven to allow the electrode section 846 to make a scroll movement, while pure water or ultrapure water is jetted from the jet orifices 898 of the pure water jet nozzles 896 to between the substrate W and the electrode members 882 and, at the same time, pure water or ultrapure water is passed through the through-holes 899 of the electrode section 846 to the ion exchangers 888, thereby impregnating the ion exchangers 888 with pure water or ultrapure water. According to this embodiment, the pure water or ultrapure water supplied to the ion exchangers 888 is discharged from the ends in the long direction of each electrode member 882.

A given voltage is applied from the power source 848 to between the processing electrodes and the feeding electrodes, and electrolytic processing of the conductive layer (copper film 22) in the surface of the substrate W is carried out at the processing electrodes (cathodes) through the action of hydrogen ions and hydroxide ions produced by the ion exchangers 888, 890. According to this embodiment, the reciprocating motor 856 is driven to move the arm 840 and the substrate holder 842 in the Y direction during electrolytic processing. Thus, according to this embodiment, the processing is carried out while allowing the electrode section 846 to make a scroll movement and allowing the substrate W to move in a direction perpendicular to the long direction of the electrode members 882. It is, however, possible to allow the substrate W to make a scroll movement while moving the electrode 846 in a direction perpendicular to the long direction of the electrode members 882. Further, instead of the scroll movement, it is possible to employ a translatory reciprocating movement in the Y direction.

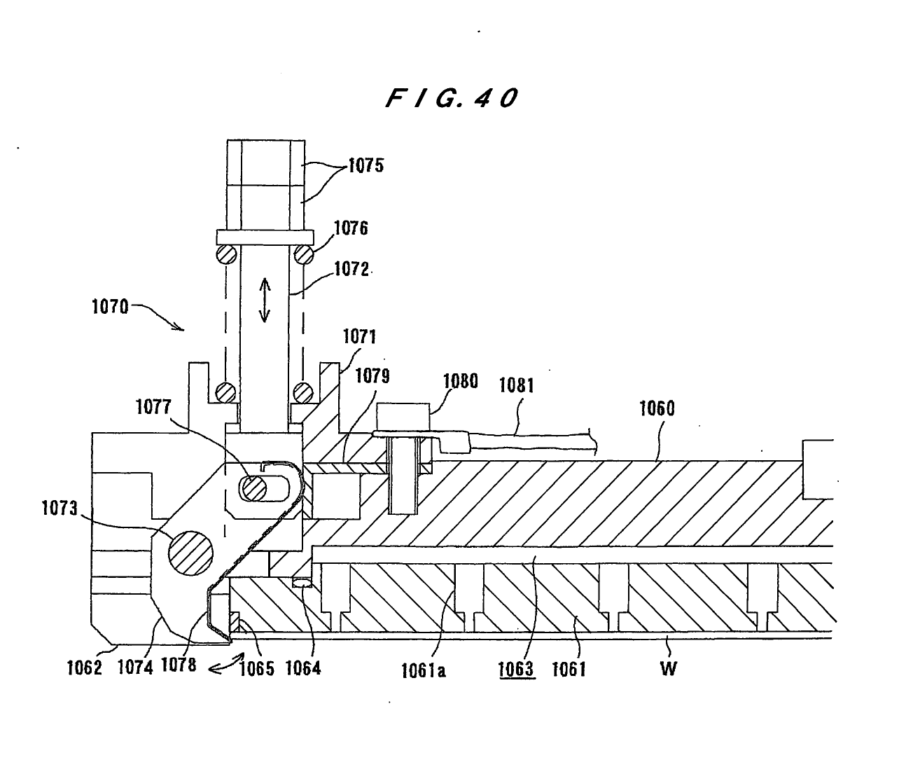

FIGS. 40 and 41 show a substrate holder 1048, for holding a substrate W, includes a feeding mechanism for feeding electricity to copper 22 (see FIG. 6A) of the substrate W. As shown in FIGS. 40 and 41, a space 1063, communicating with suction holes 1061a of a attracting plate 1061, is formed between a flange portion 1060 of the substrate holder 1048 and a attracting plate 1061. An O-ring 1064 is disposed between the flange portion 1060 and the attracting plate 1061. The space 1063 is hermetically sealed with the O-ring 1064. Further, a soft seal ring 1065 is disposed in the circumferential surface of the attracting plate 1061, i.e., between the attracting plate 1061 and a guide ring 1062. The seal ring 1065 contacts the peripheral portion of the back surface of the substrate W when it is attracted and held on the attracting plate 1061.

Six chuck mechanisms 1070 are provided in the substrate holder 1048 at regular intervals in the circumferential direction. As shown in FIG. 40, each chuck mechanism 1070 includes a pedestal 1071 mounted on the upper surface of the flange portion 1060, a vertically movable rod 1072, and a feeding contact member 1074 that is rotatable about a support shaft 1073. A nut 1075 is mounted on the upper end of the rod 1072, and a helical compression spring 1076 is interposed between the nut 1075 and the pedestal 1071.

As shown in FIG. 40, the feeding contact member 1074 and the rod 1072 are coupled via a horizontally movable pin 1077. The feeding contact member 1074 is so designed that as the rod 1072 moves upwardly, the feeding contact member 1074 rotates about the support shaft 1073 and closes inwardly, while as the rod 1072 moves downwardly, the feeding contact member 1074 rotates about the support shaft 1073 and opens outwardly. Thus, when the rods 1072 move downwardly against the pressing force of the helical compression springs 1076, the feeding contact members 1074 rotate about the supports 1073 and opens outwardly. On the other hand, when the pressure against the rods 1072 is released, the rods 1072 move up by the elastic force of the helical compression springs 1076, whereby the feeding contact members 1074 rotate about the support shafts 1073 and close inwardly. By the chuck mechanisms 1070 provided at six locations, the substrate W is positioned and held at its peripheral portions by the feeding contact members 1074, and is held stably on the lower surface of the substrate holder 1048.

As shown in FIG. 40, a conductive feeding member 1078 is mounted on the inner surface of each feeding contact member 1074. The feeding members 1078 contact conductive feeding plates 1079. The feeding plates 1079 are electrically connected to power cables 1081 via bolts 1080, and the power cables 1081 are connected to a power source (not shown). When the feeding contact members 1074 close inwardly and hold peripheral portions of the substrate W, the feeding members 1078 of the feeding contact members 1074 contact the peripheral portions of the substrate W and feed electricity to the substrate W.

When the substrate holder 1048 shown in FIGS. 40 and 41 is used, electricity is fed to a substrate through the feeding member 1078 of the feeding claw member 1074. Accordingly, the electrodes 886 shown in FIGS. 38 and 39 can all be utilized as processing electrodes. Since electricity is fed from the chuck mechanism 1070 directly to a substrate, the contact portion between the substrate and the feeding electrode can be made small, leading to a decreased generation of gas bubbles from the feeding electrode. Further, since the number of processing electrodes can be doubled, the number of processing electrodes passing over the substrate increases, thereby improving the uniformity of the processed surface of the substrate and increasing the processing rate.

The apparatus shown in FIGS. 35 through 41 can also be used for electrolytic processing using an electrolytic solution or composite electrolytic polishing involving abrasive polishing. In that case, instead of pure water as a processing liquid, an electrolytic solution containing a chelating agent or an abrasive-containing electrolytic solution may be used. Further, instead of the ion exchangers 888, 890, a scrubbing member or a polishing pad may be used.

Using the substrate head 82, having the substrate holder 60 and the CMP section 62, both shown in FIG. 3, or the above-described various CMP apparatuses, CMP processing with an abrasive-free chemical can be carried out. In that case, a polishing liquid containing a metal oxidizing agent, a metal oxide dissolving agent, a protective film forming agent, a water-soluble polymer and water may be used. Examples of the metal oxidizing agent includes hydrogen peroxide, nitric acid, potassium periodate, hypochlorous acid, and ozone water. Examples of the metal oxide dissolving agent include an organic acid, an organic acid ester, an ammonium salt of an organic acid, and sulfuric acid. Examples of the protective film forming agent include benzotriazole and its derivatives. Further, examples of the water-soluble polymer include polyacrylic acid and its salts.

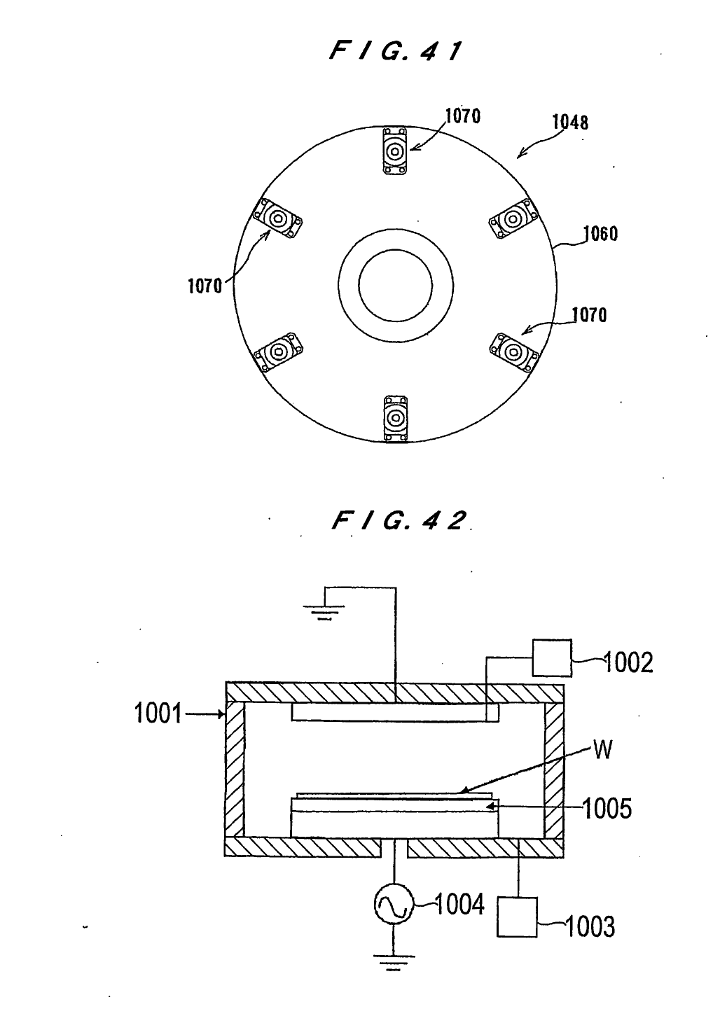

FIG. 42 shows a dry etching apparatus. The dry etching apparatus includes a vacuum vessel 1001, a gas supply device 1002 for supplying a gas into the vacuum vessel 1001, a vacuum pump 1003, and a lower electrode 1005 connected to a high-frequency power source 1004 for an electrode. In operation, a predetermined gas is introduced from the gas supply device 1002 into the vacuum vessel 1001 while the vacuum vessel 1001 is evacuated by the vacuum pump 1003 as an evacuator so as to keep the interior of the vacuum vessel 1001 at a predetermined pressure. Under such conditions, a high-frequency power is supplied from the high-frequency power source 1004 to the lower electrode 1005 to thereby generate a plasma in the vacuum vessel 1001, thereby carrying out etching of a substrate W placed on the lower electrode 1005.

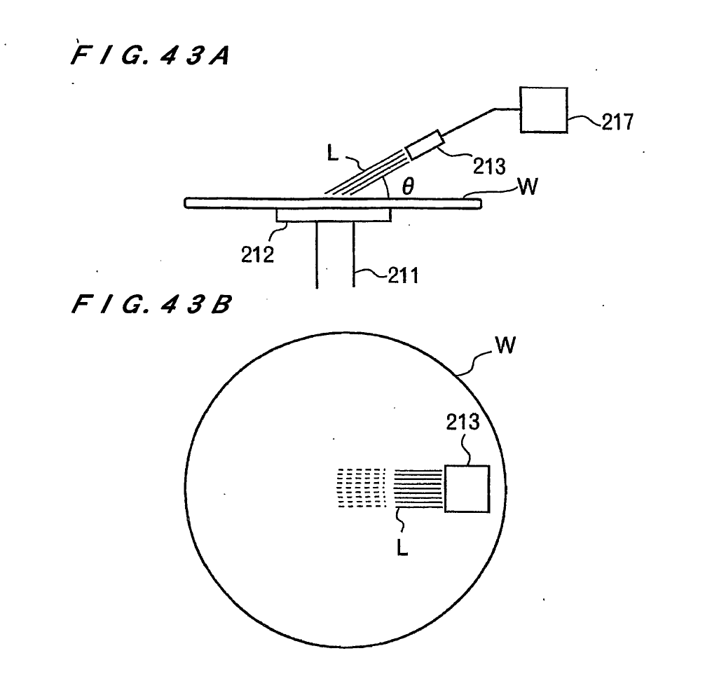

FIGS. 43A and 43B show a chemical etching apparatus. The etching apparatus includes a rotary holding mechanism, comprised of a main shaft 211 and a table 212, for holding a substrate W, such as a semiconductor wafer, horizontally and rotating it. The table 212 holds the substrate W fixedly by, for example, vacuum attraction. An etching liquid ejection nozzle 213 is disposed in the vicinity of the substrate surface, and the outlet of the etching liquid ejection nozzle 213 is oriented toward the center of the substrate W. An etching liquid L is ejected from the outlet of the etching liquid ejection nozzle 213 at the elevation angle Θ from the substrate surface of within 45°.

The etching liquid L is supplied from a supply device 217 including an etching liquid supply tank, and ejected from the etching liquid ejection nozzle 213 at an adjusted flow velocity. A chemical liquid suited for the intended etching is used as the etching liquid L.

When the etching liquid L is ejected toward the necessary etching region of the substrate at the elevation angle from the substrate surface of not more than 45°, the horizontal velocity of the etching liquid L is higher than the vertical velocity. Thus, the etching liquid L is supplied in the direction toward the center of the substrate with a relatively high horizontal flow velocity. Accordingly, the etching liquid L can be supplied quickly to the target etching region.

If the vertical velocity of the etching liquid L entering the substrate W is high, the etching liquid L can scatter upon hitting against the substrate W. By making the incident angle of the etching liquid L with respect to the substrate W not more than 45°, the vertical velocity of the etching liquid L upon hitting against the substrate W can be made low, thereby preventing splashing of the etching liquid L on the substrate surface. From the above viewpoints, the incident angle (elevation angle) of the etching liquid L with respect to the substrate surface is preferably as small as possible, in particular, not more than 30°, more preferably not more than 15°.

The above-described various processing apparatuses shown in FIG. 5 and FIGS. 8 through 43 may be properly disposed in the CMP section 62, the electrolytic processing section 64, or in the various units such as the cleaning machines 42, 44, shown in FIG. 3, for use in the substrate processing apparatus. If necessary, the number of processing units in the areas C and D shown in FIG. 3 may be increased.

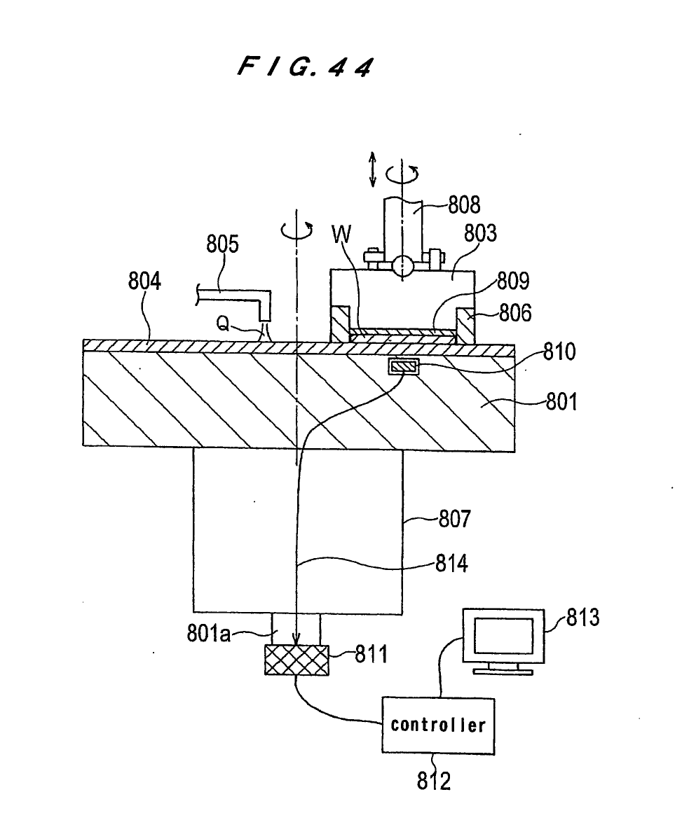

FIGS. 44 through 46B show a CMP apparatus including an eddy-current film thickness sensor (eddy-current sensor). The CMP apparatus has a turntable 801, and a top ring 803 for holding a substrate W and pressing the substrate W against the turntable 801. The turntable 801 is coupled to a motor 807, and is rotatable about its own axis, as indicated by the arrow. A polishing cloth 804 is mounted on an upper surface of the turntable 801.

The top ring 803 is coupled to a motor (not shown) and connected to a lifting/lowering cylinder (not shown). Therefore, the top ring 803 is vertically movable and rotatable about its own axis, as indicated by the arrows, and can press the substrate W against the polishing cloth 804 under a desired pressure. The top ring 803 is connected to a top ring shaft 808, and supports on its lower surface an elastic pad 809 of polyurethane or the like. A guide ring 806 is provided around an outer circumferential edge of the top ring 803 for preventing the substrate W from being dislodged from the top ring 803 while the substrate W is being polished.

A polishing liquid supply nozzle 805 is disposed above the turntable 801 for supplying a polishing liquid Q to the polishing cloth 804 mounted on the turntable 801.

As shown in FIG. 44, the turntable 801 houses therein an eddy-current sensor 810 which is electrically connected to a controller 812 by a wire 814 extending through the turntable 801, a turntable support shaft 801a, and a rotary connector or slip ring 811 mounted on a lower end of the turntable support shaft 801a. The controller 812 is connected to a display unit 813.

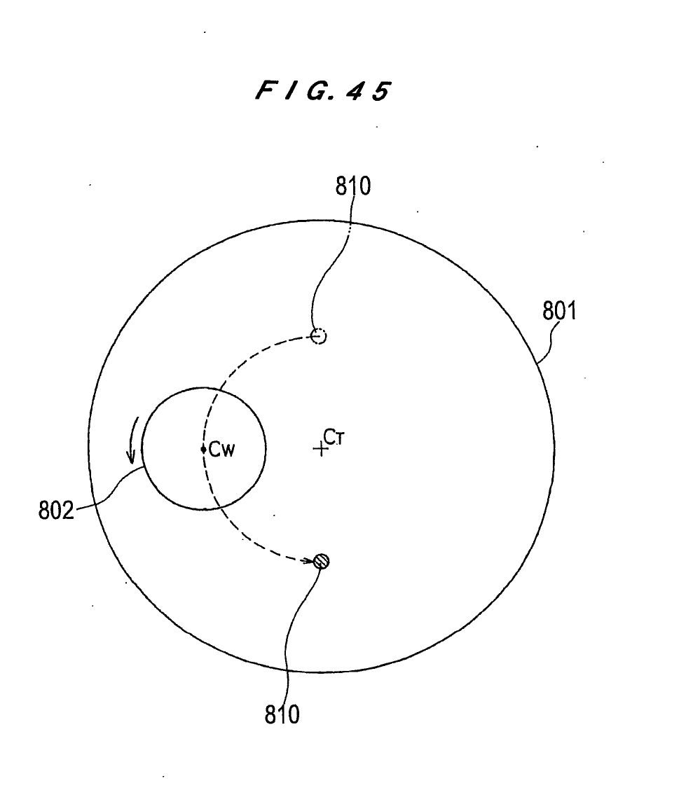

FIG. 45 shows a plane view of the turntable 801 shown in FIG. 44. As shown in FIG. 45, the eddy-current sensor 810 is positioned so as to pass through the center C_{W} of the substrate W held by the top ring 803 while the substrate W is being polished, when the turntable 801 rotates about its own axis C_{T}. While the eddy-current sensor 810 passes along an arcuate path beneath the substrate W, the eddy-current sensor 810 continuously detects the thickness of a conductive layer such as copper on the substrate W.

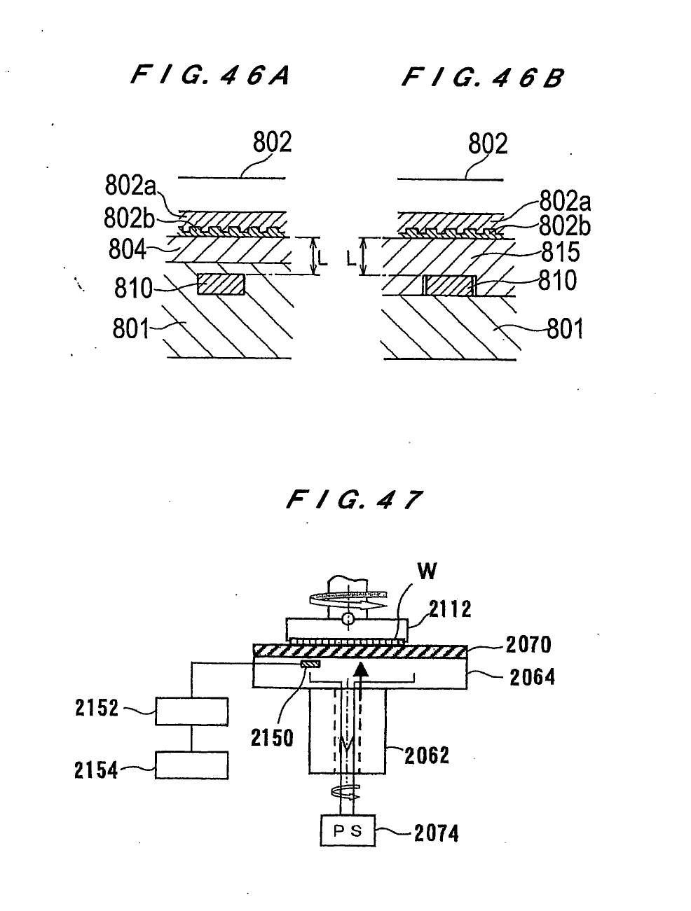

FIGS. 46A and 46B are enlarged sectional views of the eddy-current sensor 810 mounted in the turntable 801. FIG. 46A shows the eddy-current sensor 810 mounted in the turntable 801 with the polishing cloth 804 attached thereto, and FIG. 46B shows the eddy-current sensor 810 mounted on the turntable 801 with a fixed abrasive plate 815 attached thereto. If the polishing cloth 804 is mounted on the turntable 801 as shown in FIG. 46A, then the eddy-current sensor 810 is mounted in the turntable 801. If the fixed abrasive plate 815 is mounted on the turntable 801 as shown in FIG. 46B, then the eddy-current sensor 810 is mounted on the turntable 801 and provided in the fixed abrasive plate 815.

In each of the structures shown in FIGS. 46A and 46B, the upper surface, i.e. the polishing surface of the polishing cloth 804 or the fixed abrasive plate 815 (the polished surface of the substrate W) may be spaced from the upper surface of the eddy-current sensor 810 by a distance L of 1.3 mm or more. As shown in FIGS. 46A and 46B, the substrate W comprises an oxide film 802a of SiO₂, and a conductive layer 802b of copper or aluminum provided on the oxide film 802a.

The polishing cloth comprises a nonwoven fabric such as Politex manufactured by Rodel Products Corporation, or foamed polyurethane such as IC1000. The fixed abrasive plate 815 comprises a disk of fine abrasive particles of, for example, CeO₂ having a particle size of several μm or less and bonded together by a binder of resin.

Also in the case of an electrolytic processing apparatus, as with the above-described CMP apparatus, it is possible to provide an eddy-current sensor at an appropriate position in a processing table to measure the thickness of a conductive layer for use as an indicator of a shift of process step.

FIG. 47 shows the main portion of an electrolytic processing apparatus provided with an eddy-current sensor. This electrolytic processing apparatus is designed to detect a change, with the progress of processing, in an eddy current generated within an interconnect material, such as copper, thereby detecting the end point of processing. In. particular, the apparatus includes a substrate holder 2112 for holding a substrate W, and a processing table 2064 having an ion exchanger 2070 attached to the surface (upper surface), disposed below the substrate holder 2112. In the processing table 2064 is embedded an eddy-current sensor 2150 that generates an eddy current within an interconnect material (conductive layer), such as copper, deposited on the surface of the substrate W and detects the amount of the eddy current. A detected signal from the eddy-current sensor 2150 is inputted to a signal processing device 2152 as an end point detection section, and the processed signal from the signal processing device 2152 is inputted to a control section 2154. The processing table 2064 is connected directly to a hollow motor 1062. Further, a predetermined voltage is applied from a power source 2074 to between a processing electrode and a feeding electrode (not shown) disposed in the processing table 2064. The other construction is almost the same as the preceding embodiment.

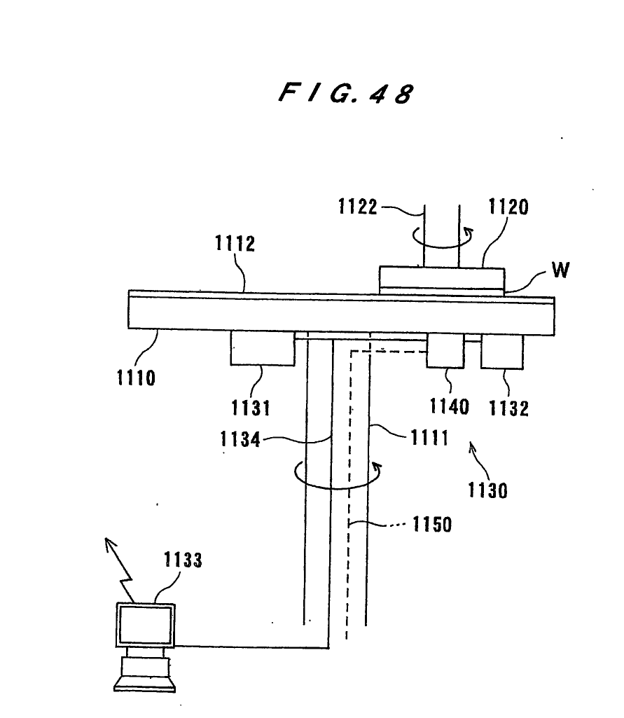

FIGS. 48 through 50 show yet another CMP apparatus provided with a film thickness monitor. As shown in FIG. 48, the CMP apparatus includes a bed 1110 that rotates about a shaft 1111, a substrate support 1120 that holds a substrate W, such as a semiconductor wafer, and rotates about a shaft 1122, and a monitor section 1130. The monitor section 1130 includes a sensor section 1140, a spectroscope 1131, a light source 1132, and a personal computer 1133 for data processing, etc.

A polishing material 1112, such as a fixed abrasive (abrasive wheel) or a polishing pad, is attached to the upper surface of the bed 1110. Polishing of the to-be-processed surface of the substrate W is effected through a relative movement between the polishing material 1112 and the substrate W. The sensor section 1140 irradiates a light from the light source 1132 onto the to-be-processed surface of the substrate W and receives the reflected light, as will be described in detail later. The spectroscope 1131 disperses the reflected light received in the sensor 1140 to obtain information on the to-be-processed surface of the substrate W. The personal computer 1133 for data processing receives the information on the to-be-processed surface from the spectroscope 1131 via an electrical signal system 1134, processes the data to obtain information on the film thickness of the to-be-processed surface, and transmits the information to a not-shown controller of the CMP apparatus. The controller of the CMP apparatus, based on the information on the film thickness, effects various controls of the CMP apparatus, including continuation of polishing and stop of polishing. The apparatus is also provided with a liquid supply/discharge system 1150 for supplying/discharging a transparent liquid to/from the sensor section 1140.

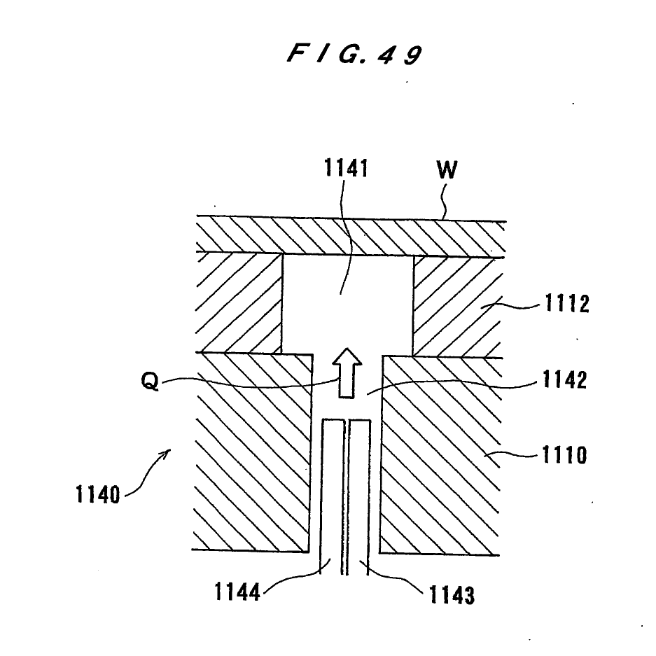

FIG. 49 schematically shows the construction of the sensor section 1140. As shown in FIG. 49, a through-hole 1141 is provided in the polishing material 1112, such as a fixed abrasive or a polishing pad, attached to the upper surface of the bed 1110, while a liquid supply hole 1142, communicating with the through-hole 1141, is provided in the bed 1110. During polishing of the substrate W, the top opening of the through-hole 1141 is closed with the substrate W, and a transparent liquid (liquid permeable to light) Q is supplied from the liquid supply hole 1142 to fill the through-hole 1141 with the transparent liquid Q. The transparent liquid Q is discharged from the gap between the polishing material 1112 and the to-be-processed surface.

The liquid supply hole 1142 is provided in the bed 1110 such that the center line of the hole 1142 is perpendicular to the to-be-processed surface of the substrate W so that the transparent liquid Q supplied creates a vertical flow toward the to-be-processed surface of the substrate W. An optical fiber 1143 for irradiating light onto the to-be-processed surface of the substrate W and an optical fiber 1144 for receiving the reflected light are disposed in the liquid supply hole 1142 such that their center lines are parallel to the center line of the liquid supply hole 1142.

With such a construction of the sensor section 1140, the transparent liquid Q, ejected from the liquid supply hole 1142, creates a vertical flow toward the to-be-processed surface of the substrate W, as described above. An irradiating light from the optical fiber 1143 passes through the vertical flow of transparent liquid Q and reaches the to-be-processed surface of the substrate W, and the reflected light from the to-be-processed surface passes through the vertical flow of transparent liquid Q and reaches the optical fiber 1144. The vertical flow of transparent liquid Q toward the to-be-processed surface of the substrate W functions to clean the to-be-processed surface and, in addition, prevents intrusion of particles, such as particle polishing material in the polishing liquid, shavings of the polishing material 1112 and shavings of the substrate W, present in the gap between the to-be-processed surface and the polishing material 1112, serving as a good light path for the irradiating and reflected lights. Accordingly, the film of the to-be-processed surface can be monitored stably with accuracy.

It is possible to provide a solenoid valve in a not-shown liquid flow passage connected to the liquid supply hole 1142 and control the solenoid valve so as to stop or reduce the supply of the transparent liquid Q when the through-hole 1141 is not closed with the substrate W, thereby reducing the influence of the liquid on polishing properties. The sensor section 1140 having the above construction is effective also in cases where the through-hole 1141 is always closed with a substrate, or the bed 1110 does not rotate about an axis but makes such a translational movement that every point in the bed makes a circular movement with the same radius.

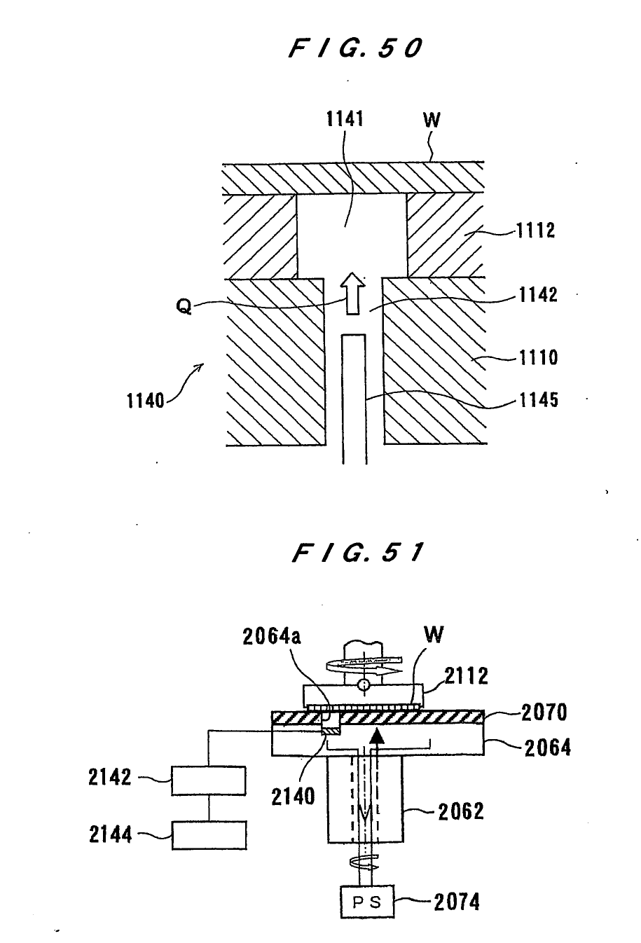

FIG. 50 is a schematic diagram illustrating another construction of the sensor section 1140. The sensor section 1140 of FIG. 50 differs from the sensor section of FIG. 49 in that one optical fiber 1145 is used for transmitting both an irradiating light and the reflected light. The other construction is substantially the same as that of FIG. 49. Such a construction produces the same effect as the sensor section 1140 of FIG. 49.

Though the provision of the through-hole 1141 is shown in FIGS. 48 through 50, it is possible to cover the open end of the through-hole 1141 with a light-permeable lid such that the upper surface of the lid is flush with the upper surface of the polishing material 1112. This prevents contact of the transparent liquid Q with the substrate W, thus preventing a change in the composition of the polishing liquid on the polishing surface.

While the detection of film thickness in the CMP apparatus shown in FIGS. 48 through 50 has been described, the film thickness detection is applicable also to an electrolytic processing apparatus.

FIG. 51 shows the main portion of such an electrolytic processing apparatus. Thus, the electrolytic processing apparatus is designed to irradiate a light onto the surface of an interconnect material (conductive layer), such as copper, and detect a change, with the progress of processing, in the intensity of the reflected light from the surface to. thereby detect the end point of processing. In particular, the processing apparatus includes a processing table 2064 having an upwardly-open recess 2064a. An optical sensor 2140 having a light-emitting element and a light-sensitive element is provided in the recess 2064a. A detected signal from the optical sensor 2140 is inputted to a signal processing device 2142 as an end point detection section, and the processed signal from the signal processing device 2142 is inputted to a control section 2144. The other construction is almost the same as that shown in FIG. 47.

As described hereinabove, the present invention makes it possible to revise the currently-practiced interconnect formation process steps so that the process steps may be divided according to purposes, select a preferable processing method for a particular purpose and carry out the overall processing with a combination of selected processing methods, enabling improved processing and flattening in the formation of interconnects.

### INDUSTRIAL APPLICABILITY

The present invention relates to a substrate processing method and a substrate processing apparatus useful for flattening a surface of an electrical conductive material embedded in interconnect recesses provided in a surface of a substrate thereby forming embedded interconnects.

1. A substrate processing method for removing unnecessary interconnect material and barrier material on a substrate and flattening a surface of the substrate, wherein said interconnect material is embedded in interconnect recesses, said interconnect recesses being formed on a surface of an insulating material and having a film of said barrier material formed on the surface of an insulating material, said method comprising:
eliminating a level difference in the surface of the interconnect material to flatten the surface;
removing the interconnect material until the interconnect material present in the non-interconnect region of the substrate becomes a thin film or remains partly on the barrier material while applying a first pressure to the substrate;
removing the interconnect material in the form of the thin film or remaining partly on the barrier material while applying a second pressure, which is lower than the first pressure, to the substrate, thereby exposing the barrier material or further processing the barrier material;
simultaneously removing the unnecessary interconnect material and the barrier material until the barrier material present in the non-interconnect region becomes a thin film or remains partly while applying a third pressure to the substrate; and
removing the unnecessary interconnect material and the barrier material present in the non-interconnect region while applying a fourth pressure, which is lower than the third pressure, to the substrate, thereby exposing the insulating material in the non-interconnect region or further processing the insulating material.

2. The substrate processing method according to claim 1 further comprising simultaneously removing the unnecessary interconnect material, the barrier material and the insulating material.

3. A substrate processing method for removing unnecessary interconnect material and barrier material on a substrate and flattening a surface of the substrate, wherein said interconnect material is embedded in interconnect recesses, said interconnect recesses being formed on a surface of an insulating material and having a film of said barrier material formed on the surface of an insulating material, said method comprising:
a first step of eliminating a level difference in the surface of the interconnect material to flatten the surface;
a second step of removing the interconnect material until the interconnect material present in the non-interconnect region of the substrate becomes a thin film or remains partly on the barrier material while applying a first pressure to the substrate;
a third step of removing the interconnect material in the form of the thin film or remaining partly on the barrier material while applying a second pressure, which is lower than the first pressure, to the substrate, thereby exposing the barrier material or further processing the barrier material;
a fourth step of simultaneously removing the unnecessary interconnect material and the barrier material until the barrier material present in the non-interconnect region becomes a thin film or remains partly while applying a third pressure to the substrate; and
a fifth step of removing the unnecessary interconnect material and the barrier material present in the non-interconnect region while applying a fourth pressure, which is lower than the third pressure, to the substrate, thereby exposing the insulating material in the non-interconnect region or further processing the insulating material.

4. The substrate processing method according to claim 3 further comprising a sixth step of simultaneously removing the unnecessary interconnect material, the barrier material and the insulating material.

5. The substrate processing method according to claim 1, wherein the step of eliminating a level difference in the surface of the interconnect material to flatten the surface is carried out by cutting or grinding.

6. The substrate processing method according to claim 1, wherein the step of eliminating a level difference in the surface of the interconnect material is carried out by CMP.

7. The substrate processing method according to claim 1, wherein the step of eliminating a level difference in the surface of the interconnect material is carried out by electrolytic processing, composite electrolytic processing or abrasive processing utilizing an electrostatic or magnetic force.

8. The substrate processing method according to claim 1, wherein the step of eliminating a level difference in the surface of the interconnect material is carried out by electrolytic processing utilizing a catalyst.

9. The substrate processing method according to claim 1, wherein the step of removing the interconnect material until the interconnect material present in the non-interconnect region of the substrate becomes a thin film or remains partly on the barrier material is carried out by CMP.

10. The substrate processing method according to claim 1, wherein the step of removing the interconnect material until the interconnect material present in the non-interconnect region of the substrate becomes a thin film or remains partly on the barrier material is carried out by electrolytic processing or composite electrolytic processing.

11. The substrate processing method according to claim 1, wherein the step of removing the interconnect material until the interconnect material present in the non-interconnect region of the substrate becomes a thin film or remains partly on the barrier material is carried out by electrolytic processing utilizing a catalyst.

12. The substrate processing method according to claim 1, wherein the step of removing the interconnect material until the interconnect material present in the non-interconnect region of the substrate becomes a thin film or remains partly on the barrier material is carried out by abrasive processing utilizing an electrostatic or magnetic force.

13. The substrate processing method according to claim 1, wherein the step of removing the interconnect material until the interconnect material present in the non-interconnect region of the substrate becomes a thin film or remains partly on the barrier material is carried out by dry etching or chemical etching.

14. The substrate processing method according to claim 1, wherein the step of removing the interconnect material present in the non-interconnect region or remaining partly on the barrier material is carried out by CMP.

15. The substrate processing method according to claim 1, wherein the step of removing the interconnect material present in the non-interconnect region or remaining partly on the barrier material is carried out by electrolytic processing or composite electrolytic processing.

16. The substrate processing method according to claim 1, wherein the step of removing the interconnect material present in the non-interconnect region or remaining partly on the barrier material is carried out by electrolytic processing utilizing a catalyst.

17. The substrate processing method according to claim 1, wherein the step of removing the interconnect material present in the non-interconnect region or remaining partly on the barrier material is carried out by dry etching or chemical etching.

18. The substrate processing method according to claim 1, wherein the step of simultaneously removing the unnecessary interconnect material and the barrier material until the barrier material present in the non-interconnect region becomes a thin film or remains partly is carried out by CMP.

19. The substrate processing method according to claim 1, wherein the step of simultaneously removing the unnecessary interconnect material and the barrier material until the barrier material present in the non-interconnect region becomes a thin film or remains partly is carried out by composite electrolytic processing or a common electrolytic processing.

20. The substrate processing method according to claim 1, wherein the step of simultaneously removing the unnecessary interconnect material and the barrier material until the barrier material present in the non-interconnect region becomes a thin film or remains partly is carried out by electrolytic processing utilizing a catalyst.

21. The substrate processing method according to claim 1, wherein the step of simultaneously removing the unnecessary interconnect material and the barrier material until the barrier material present in the non-interconnect region becomes a thin film or remains partly is carried out by dry etching or chemical etching.

22. The substrate processing method according to claim 1, wherein the step of simultaneously removing the unnecessary interconnect material and the barrier material until the barrier material present in the non-interconnect region becomes a thin film or remains partly is carried out by independent processings of the interconnect material and of the barrier material.

23. The substrate processing method according to claim 1, wherein the step of removing the unnecessary interconnect material and the barrier material present in the non-interconnect region is carried out by CMP.

24. The substrate processing method according to claim 1, wherein the step of removing the unnecessary interconnect material and the barrier material present in the non-interconnect region is carried out by electrolytic processing or composite electrolytic processing.

25. The substrate processing method according to claim 1, wherein the step of removing the unnecessary interconnect material and the barrier material present in the non-interconnect region is carried out by electrolytic processing utilizing a catalyst.

26. The substrate processing method according to claim 1, wherein the step of removing the unnecessary interconnect material and the barrier material present in the non-interconnect region is carried out by dry etching or chemical etching.

27. The substrate processing method according to claim 2, wherein the step of simultaneously removing the unnecessary interconnect material, the barrier material and the insulating material is carried out by CMP.

28. The substrate processing method according to claim 2, wherein the step of simultaneously removing the unnecessary interconnect material, the barrier material and the insulating material is carried out by dry etching or chemical etching.

29. A substrate processing method for removing unnecessary interconnect material and barrier material on a substrate and flattening a surface of the substrate, wherein said interconnect material is embedded in interconnect recesses, said interconnect recesses being formed on a surface of an insulating material and having a film of said barrier material formed on the surface of an insulating material, said method comprising:
removing the interconnect material until the interconnect material present in the non-interconnect region of the substrate becomes a thin film or remains partly while applying a first pressure to the substrate; and then
completely removing the interconnect material, present in the non-interconnect region, in the form of the thin film or remaining partly while applying a second pressure, which is lower than the first pressure, to the substrate, thereby exposing an underlying material present under the interconnect material in the non-interconnect region.

30. The substrate processing method according to claim 29, wherein the step of removing the interconnect material until the interconnect material present in the non-interconnect region of the substrate becomes a thin film or remains partly comprises an additional step of eliminating a level difference in the surface of the interconnect material.

31. The substrate processing method according to claim 29, wherein the step of removing the interconnect material until the interconnect material present in the non-interconnect region of the substrate becomes a thin film or remains partly is terminated when the film thickness of the interconnect material present in the non-interconnect region has reached a value of not more than 300 nm.

32. The substrate processing method according to claim 31, wherein the film thickness of the interconnect material present in the non-interconnect region is detected with an eddy current-type or optical film thickness measuring means.

33. The substrate processing method according to claim 29, wherein the processing rate of the interconnect material in the step of completely removing the interconnect material, present in the non-interconnect region, in the form of the thin film or remaining partly is lower than the processing rate of the interconnect material in the step of removing the interconnect material until the interconnect material present in the non-interconnect region of the substrate becomes a thin film or remains partly.

34. The substrate processing method according to claim 29, wherein the step of completely removing the interconnect material, present in the non-interconnect region, in the form of the thin film or remaining partly is carried out by using a processing liquid or a chemical liquid.

35. (canceled)

36. The substrate processing method according to claim 29 further comprising removing the underlying material present in the non-interconnect region until a material present under the underlying material becomes exposed.

37. The substrate processing method according to claim 36, wherein the step of removing the underlying material comprises a step of removing the underlying material until the underlying material becomes a thin film or remains partly, and a step of removing the underlying material in the non-interconnect region until the material present under the underlying material becomes exposed.

38. A substrate processing method for removing unnecessary interconnect material and barrier material on a substrate and flattening a surface of the substrate, wherein said interconnect material is embedded in interconnect recesses, said interconnect recesses being formed on a surface of an insulating material and having a film of said barrier material formed on the surface of an insulating material, said method comprising:
simultaneously removing the unnecessary interconnect material and barrier material until the barrier material present in the non-interconnect region of the substrate becomes a thin film or remains partly while applying a first pressure to the substrate; and then
removing the unnecessary interconnect material and the barrier material in the form of the thin film or remaining partly while applying a second pressure, which is lower than the first pressure to the substrate, thereby exposing an underlying material present under the barrier material in the non-interconnect region.

39. (canceled)

40. A substrate processing apparatus for performing the substrate processing method according to claim 1, comprising:
an electrolytic processing section, provided with an end point detection device, for carrying out electrolytic processing of a substrate held by a substrate holder;
a CMP section, provided with an end point detection device, for carrying out chemical mechanical polishing of the substrate held by a substrate holder; and
a substrate transfer device for transferring the substrate;
wherein the substrate is processed both in the electrolytic processing section and in the CMP section.

41. The substrate processing apparatus according to claim 40, wherein the electrolytic processing includes composite electrolytic processing, electrolytic processing using an electrolytic solution, electrolytic processing utilizing a catalyst, and a common electrolytic processing.

42. The substrate processing method according to claim 3, wherein the step of eliminating a level difference in the surface of the interconnect material to flatten the surface is carried out by cutting or grinding.

43. The substrate processing method according to claim 3, wherein the step of eliminating a level difference in the surface of the interconnect material is carried out by CMP.

44. The substrate processing method according to claim 3, wherein the step of eliminating a level difference in the surface of the interconnect material is carried out by electrolytic processing, composite electrolytic processing or abrasive processing utilizing an electrostatic or magnetic force.

45. The substrate processing method according to claim 3, wherein the step of eliminating a level difference in the surface of the interconnect material is carried out by electrolytic processing utilizing a catalyst.

46. The substrate processing method according to claim 3, wherein the step of removing the interconnect material until the interconnect material present in the non-interconnect region of the substrate becomes a thin film or remains partly on the barrier material is carried out by CMP.

47. The substrate processing method according to claim 3, wherein the step of removing the interconnect material until the interconnect material present in the non-interconnect region of the substrate becomes a thin film or remains partly on the barrier material is carried out by electrolytic processing or composite electrolytic processing.

48. The substrate processing method according to claim 3, wherein the step of removing the interconnect material until the interconnect material present in the non-interconnect region of the substrate becomes a thin film or remains partly on the barrier material is carried out by electrolytic processing utilizing a catalyst.

49. The substrate processing method according to claim 3, wherein the step of removing the interconnect material until the interconnect material present in the non-interconnect region of the substrate becomes a thin film or remains partly on the barrier material is carried out by abrasive processing utilizing an electrostatic or magnetic force.

50. The substrate processing method according to claim 3, wherein the step of removing the interconnect material until the interconnect material present in the non-interconnect region of the substrate becomes a thin film or remains partly on the barrier material is carried out by dry etching or chemical etching.

51. The substrate processing method according to claim 3, wherein the step of removing the interconnect material present in the non-interconnect region or remaining partly on the barrier material is carried out by CMP.

52. The substrate processing method according to claim 3, wherein the step of removing the interconnect material present in the non-interconnect region or remaining partly on the barrier material is carried out by electrolytic processing or composite electrolytic processing.

53. The substrate processing method according to claim 2, wherein the step of removing the interconnect material present in the non-interconnect region or remaining partly on the barrier material is carried out by electrolytic processing utilizing a catalyst.

54. The substrate processing method according to claim 3, wherein the step of removing the interconnect material present in the non-interconnect region or remaining partly on the barrier material is carried out by dry etching or chemical etching.

55. The substrate processing method according to claim 3, wherein the step of simultaneously removing the unnecessary interconnect material and the barrier material until the barrier material present in the non-interconnect region becomes a thin film or remains partly is carried out by CMP.

56. The substrate processing method according to claim 3, wherein the step of simultaneously removing the unnecessary interconnect material and the barrier material until the barrier material present in the non-interconnect region becomes a thin film or remains partly is carried out by composite electrolytic processing or a common electrolytic processing.

57. The substrate processing method according to claim 3, wherein the step of simultaneously removing the unnecessary interconnect material and the barrier material until the barrier material present in the non-interconnect region becomes a thin film or remains partly is carried out by electrolytic processing utilizing a catalyst.

58. The substrate processing method according to claim 3, wherein the step of simultaneously removing the unnecessary interconnect material and the barrier material until the barrier material present in the non-interconnect region becomes a thin film or remains partly is carried out by dry etching or chemical etching.

59. The substrate processing method according to claim 3, wherein the step of simultaneously removing the unnecessary interconnect material and the barrier material until the barrier material present in the non-interconnect region becomes a thin film or remains partly is carried out by independent processings of the interconnect material and of the barrier material.

60. The substrate processing method according to claim 3, wherein the step of removing the unnecessary interconnect material and the barrier material present in the non-interconnect region is carried out by CMP.

61. The substrate processing method according to claim 3, wherein the step of removing the unnecessary interconnect material and the barrier material present in the non-interconnect region is carried out by electrolytic processing or composite electrolytic processing.

62. The substrate processing method according to claim 3, wherein the step of removing the unnecessary interconnect material and the barrier material present in the non-interconnect region is carried out by electrolytic processing utilizing a catalyst.

63. The substrate processing method according to claim 3, wherein the step of removing the unnecessary interconnect material and the barrier material present in the non-interconnect region is carried out by dry etching or chemical etching.

64. The substrate processing method according to claim 4, wherein the step of simultaneously removing the unnecessary interconnect material, the barrier material and the insulating material is carried out by CMP.

65. The substrate processing method according to claim 4, wherein the step of simultaneously removing the unnecessary interconnect material, the barrier material and the insulating material is carried out by dry etching or chemical etching.
